(19) United States
(12) Patent Application Publication
(10) Pub. No.: US 2024/0371789 A1
(43) Pub. Date: Nov. 7, 2024

(54) THREE-DIMENSIONAL MEMORY DEVICE CONTAINING TRENCH SUPPORT BRIDGE STRUCTURES AND METHODS FOR MANUFACTURING THE SAME

(71) Applicant: WESTERN DIGITAL TECHNOLOGIES, INC.,, SAN JOSE, CA (US)

(72) Inventors: Koichi MATSUNO, Fremont, CA (US); Johann ALSMEIER, San Jose, CA (US)

(21) Appl. No.: 18/357,781

(22) Filed: Jul. 24, 2023

Related U.S. Application Data
(60) Provisional application No. 63/500,371, filed on May 5, 2023.

(51) Int. Cl. H01L 23/00; H10B 43/27

(52) U.S. Cl. CPC H01L 23/562; H10B 43/27

(57) ABSTRACT

A memory device includes layer stacks, each including a respective alternating stack of respective insulating layers and respective electrically conductive layers and a respective contact-level dielectric layer, memory openings vertically extending through a respective one of the alternating stacks. memory opening fill structures located in a respective one of the memory openings and including a respective vertical stack of memory elements and a respective vertical semiconductor channel, and dielectric bridges structures located within access trenches that laterally separate the layer stacks. Each of the dielectric bridge structures includes a respective pair of contoured sidewalls. Each contoured sidewall of the dielectric bridge structures includes at least two vertically-straight and horizontally-convex surface segments that are adjoined by a vertically-extending edge. Access trench fill structures are located in the access trenches and each access trench fill structure embed a respective subset of the dielectric bridge structures.

### FIELD

The present disclosure relates generally to the field of semiconductor devices, and particularly to a three-dimensional memory device including trench support bridge structures and methods for manufacturing the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a memory device is provided, which comprises: layer stacks that laterally extend along a first horizontal direction and laterally spaced apart from each other by access trenches, wherein each of the layer stacks comprises a respective alternating stack of respective insulating layers and respective electrically conductive layers, and further comprises a respective contact-level dielectric layer that overlies the respective alternating stack; memory openings vertically extending through a respective one of the alternating stacks; memory opening fill structures located in a respective one of the memory openings and comprising a respective vertical stack of memory elements and a respective vertical semiconductor channel; dielectric bridges structures located within a respective one of the access trenches, wherein each of the dielectric bridge structures comprises a respective pair of contoured sidewalls, wherein each contoured sidewall of the dielectric bridge structures comprises at least two vertically-straight and horizontally-convex surface segments that are adjoined by a vertically-extending edge; and access trench fill structures located in the access trenches and embedding a respective subset of the dielectric bridge structures.

According to another aspect of the present disclosure, a method of forming a semiconductor structure is provided. The method comprises: forming an alternating stack of insulating layers and sacrificial material layers over a substrate; forming memory openings through the alternating stack; forming memory opening fill structures in the memory openings; forming a contact-level dielectric layer over the alternating stack and the memory opening fill structures; forming pillar cavities vertically extending through the contact-level dielectric layer and the alternating stack; forming sacrificial pillar structures in the pillar cavities; forming dielectric bridge structures in upper portions of the sacrificial pillar structures; forming access trenches by removing portions of the alternating stack located between neighboring pairs of the sacrificial pillar structures that are laterally spaced apart from each other along a first horizontal direction and by removing the sacrificial pillar structures; replacing remaining portions of the sacrificial material layers with electrically conductive layers; and forming access trench fill structures in the access trenches.

### BRIEF DESCRIPTION OF THE DRAWINGS

FIG. 1 is a schematic vertical cross-sectional view of an exemplary structure after formation of a first alternating stack of first insulating layers and first sacrificial material layers and first dielectric material portions over a carrier substrate according to an embodiment of the present disclosure.

FIG. 2 is a schematic vertical cross-sectional view of the exemplary structure after formation of a first stepped dielectric material portion according to an embodiment of the present disclosure.

FIG. 3A is a schematic vertical cross-sectional view of the exemplary structure after formation of first-tier openings according to an embodiment of the present disclosure.

FIG. 3B is a top-down view of the exemplary structure of FIG. 3A. The vertical plane A-A′ is the cut plane of the schematic vertical cross-sectional view of FIG. 3A.

FIG. 3C is a schematic vertical cross-sectional view along the vertical plane C-C′ of FIG. 3B.

FIG. 3D is a schematic vertical cross-sectional view along the vertical plane D-D′ of FIG. 3B.

FIG. 4A is a schematic vertical cross-sectional view of the exemplary structure after formation of first-tier sacrificial opening fill structures according to an embodiment of the present disclosure.

FIG. 4B is a top-down view of the exemplary structure of FIG. 4A. The vertical plane A-A′ is the cut plane of the schematic vertical cross-sectional view of FIG. 4A.

FIG. 4C is a schematic vertical cross-sectional view along the vertical plane C-C′ of FIG. 4B.

FIG. 4D is a schematic vertical cross-sectional view along the vertical plane D-D′ of FIG. 4B.

FIG. 5 is a schematic vertical cross-sectional view of the exemplary structure after formation of a second alternating stack of second insulating layers and second sacrificial material layers according to an embodiment of the present disclosure.

FIG. 6 is a schematic vertical cross-sectional view of the exemplary structure after formation of a second stepped dielectric material portion according to an embodiment of the present disclosure.

FIG. 7A is a schematic vertical cross-sectional view of the exemplary structure after formation of second-tier openings according to an embodiment of the present disclosure.

FIG. 7B is a top-down view of the exemplary structure of FIG. 7A. The vertical plane A-A′ is the cut plane of the schematic vertical cross-sectional view of FIG. 7A.

FIG. 7C is a schematic vertical cross-sectional view of the exemplary structure along the vertical plane C-C′ of FIG. 7B.

FIG. 7D is a schematic vertical cross-sectional view of the exemplary structure along the vertical plane D-D′ of FIG. 7B.

FIG. 8A is a schematic vertical cross-sectional view of the exemplary structure after formation of second-tier sacrificial opening fill structures according to an embodiment of the present disclosure.

FIG. 8B is a top-down view of the exemplary structure of FIG. 8A. The vertical plane A-A′ is the cut plane of the schematic vertical cross-sectional view of FIG. 8A.

FIG. 8C is a schematic vertical cross-sectional view of the exemplary structure along the vertical plane C-C′ of FIG. 8B.

FIG. 8D is a schematic vertical cross-sectional view of the exemplary structure along the vertical plane D-D′ of FIG. 8B.

FIG. 9A is a schematic vertical cross-sectional view of the exemplary structure after formation of inter-tier memory openings according to an embodiment of the present disclosure.

FIG. 9B is a top-down view of the exemplary structure of FIG. 9A. The vertical plane A-A′ is the cut plane of the schematic vertical cross-sectional view of FIG. 9A.

FIG. 9C is a schematic vertical cross-sectional view of the exemplary structure along the vertical plane C-C′ of FIG. 9B.

FIG. 9D is a schematic vertical cross-sectional view of the exemplary structure along the vertical plane D-D′ of FIG. 9B.

FIGS. 10A-10F are sequential schematic vertical cross-sectional views of a memory opening during formation of a memory opening fill structure according to an embodiments of the present disclosure.

FIG. 11A is a schematic vertical cross-sectional view of the exemplary structure after formation of memory opening fill structures according to an embodiment of the present disclosure.

FIG. 11B is a top-down view of the exemplary structure of FIG. 11A. The vertical plane A-A′ is the cut plane of the schematic vertical cross-sectional view of FIG. 11A.

FIG. 11C is a schematic vertical cross-sectional view of the exemplary structure along the vertical plane C-C′ of FIG. 11B.

FIG. 11D is a schematic vertical cross-sectional view of the exemplary structure along the vertical plane D-D′ of FIG. 11B.

FIG. 12A is a schematic vertical cross-sectional view of the exemplary structure after replacement of sacrificial support opening fill structures with support pillar structures and after formation of a contact-level dielectric layer according to an embodiment of the present disclosure.

FIG. 12B is a top-down view of the exemplary structure of FIG. 12A. The vertical plane A-A′ is the cut plane of the schematic vertical cross-sectional view of FIG. 12A.

FIG. 12C is a schematic vertical cross-sectional view of the exemplary structure along the vertical plane C-C′ of FIG. 12B.

FIG. 12D is a schematic vertical cross-sectional view of the exemplary structure along the vertical plane D-D′ of FIG. 12B.

FIG. 13A is a schematic vertical cross-sectional view of the exemplary structure after formation of connection via cavities according to an embodiment of the present disclosure.

FIG. 13B is a top-down view of the exemplary structure of FIG. 13A. The vertical plane A-A′ is the cut plane of the schematic vertical cross-sectional view of FIG. 13A.

FIG. 13C is a schematic vertical cross-sectional view of the exemplary structure along the vertical plane C-C′ of FIG. 13B.

FIG. 13D is a schematic vertical cross-sectional view of the exemplary structure along the vertical plane D-D′ of FIG. 13B.

FIG. 14A is a schematic vertical cross-sectional view of the exemplary structure after formation of inter-tier access openings according to an embodiment of the present disclosure.

FIG. 14B is a top-down view of the exemplary structure of FIG. 14A. The vertical plane A-A′ is the cut plane of the schematic vertical cross-sectional view of FIG. 14A.

FIG. 14C is a schematic vertical cross-sectional view of the exemplary structure along the vertical plane C-C′ of FIG. 14B.

FIG. 14D is a schematic vertical cross-sectional view of the exemplary structure along the vertical plane D-D′ of FIG. 14B.

FIG. 15A is a schematic vertical cross-sectional view of the exemplary structure after formation of sacrificial access-via-fill structures according to an embodiment of the present disclosure.

FIG. 15B is a top-down view of the exemplary structure of FIG. 15A. The vertical plane A-A′ is the cut plane of the schematic vertical cross-sectional view of FIG. 15A.

FIG. 15C is a schematic vertical cross-sectional view of the exemplary structure along the vertical plane C-C′ of FIG. 15B.

FIG. 15D is a schematic vertical cross-sectional view of the exemplary structure along the vertical plane D-D′ of FIG. 15B.

FIG. 16A is a schematic vertical cross-sectional view of the exemplary structure after formation of first access via cavities by removal of a first subset of the sacrificial access-via-fill structures according to an embodiment of the present disclosure.

FIG. 16B is a top-down view of the exemplary structure of FIG. 16A. The vertical plane A-A′ is the cut plane of the schematic vertical cross-sectional view of FIG. 16A.

FIG. 16C is a schematic vertical cross-sectional view of the exemplary structure along the vertical plane C-C′ of FIG. 16B.

FIG. 16D is a schematic vertical cross-sectional view of the exemplary structure along the vertical plane D-D′ of FIG. 16B.

FIG. 17A is a schematic vertical cross-sectional view of the exemplary structure after formation of pillar cavities by lateral expansion and merging of the first access via cavities according to an embodiment of the present disclosure.

FIG. 17B is a top-down view of the exemplary structure of FIG. 17A. The vertical plane A-A′ is the cut plane of the schematic vertical cross-sectional view of FIG. 17A.

FIG. 17C is a schematic vertical cross-sectional view of the exemplary structure along the vertical plane C-C′ of FIG. 17B.

FIG. 17D is a schematic vertical cross-sectional view of the exemplary structure along the vertical plane D-D′ of FIG. 17B.

FIG. 17E is a horizontal cross-sectional view of the exemplary structure along the horizontal plane E-C′ of FIGS. 17A, 17C, and 17D.

FIG. 18A is a schematic vertical cross-sectional view of the exemplary structure after formation of sacrificial pillar structures according to an embodiment of the present disclosure.

FIG. 18B is a top-down view of the exemplary structure of FIG. 18A. The vertical plane A-A′ is the cut plane of the schematic vertical cross-sectional view of FIG. 18A.

FIG. 18C is a schematic vertical cross-sectional view of the exemplary structure along the vertical plane C-C′ of FIG. 18B.

FIG. 18D is a schematic vertical cross-sectional view of the exemplary structure along the vertical plane D-D′ of FIG. 18B.

FIG. 18E is a horizontal cross-sectional view of the exemplary structure along the horizontal plane E-C′ of FIGS. 18A, 18C, and 18D.

FIG. 19A is a schematic vertical cross-sectional view of the exemplary structure after formation recess regions in upper portions of the sacrificial pillar structures according to an embodiment of the present disclosure.

FIG. 19B is a top-down view of the exemplary structure of FIG. 19A. The vertical plane A-A′ is the cut plane of the schematic vertical cross-sectional view of FIG. 19A.

FIG. 19C is a schematic vertical cross-sectional view of the exemplary structure along the vertical plane C-C′ of FIG. 19B.

FIG. 19D is a schematic vertical cross-sectional view of the exemplary structure along the vertical plane D-D′ of FIG. 19B.

FIG. 19E is a horizontal cross-sectional view of the exemplary structure along the horizontal plane E-C′ of FIGS. 19A, 19C, and 19D.

FIG. 20A is a schematic vertical cross-sectional view of the exemplary structure after formation of dielectric bridge structures according to an embodiment of the present disclosure.

FIG. 20B is a top-down view of the exemplary structure of FIG. 20A. The vertical plane A-A′ is the cut plane of the schematic vertical cross-sectional view of FIG. 20A.

FIG. 20C is a schematic vertical cross-sectional view of the exemplary structure along the vertical plane C-C′ of FIG. 20B.

FIG. 20D is a schematic vertical cross-sectional view of the exemplary structure along the vertical plane D-D′ of FIG. 20B.

FIG. 20E is a horizontal cross-sectional view of the exemplary structure along the horizontal plane E-C′ of FIGS. 20A, 20C, and 20D.

FIG. 21A is a schematic vertical cross-sectional view of the exemplary structure after formation of an etch mask layer and openings therethrough such that top surfaces of a second subset of the sacrificial access-via-fill structures are exposed according to an embodiment of the present disclosure.

FIG. 21B is a top-down view of the exemplary structure of FIG. 21A. The vertical plane A-A′ is the cut plane of the schematic vertical cross-sectional view of FIG. 21A.

FIG. 21C is a schematic vertical cross-sectional view of the exemplary structure along the vertical plane C-C′ of FIG. 21B.

FIG. 21D is a schematic vertical cross-sectional view of the exemplary structure along the vertical plane D-D′ of FIG. 21B.

FIG. 21E is a horizontal cross-sectional view of the exemplary structure along the horizontal plane E-C′ of FIGS. 21A, 21C, and 21D.

FIG. 22A is a schematic vertical cross-sectional view of the exemplary structure after formation of second access via cavities according to an embodiment of the present disclosure.

FIG. 22B is a top-down view of the exemplary structure of FIG. 22A. The vertical plane A-A′ is the cut plane of the schematic vertical cross-sectional view of FIG. 22A.

FIG. 22C is a schematic vertical cross-sectional view of the exemplary structure along the vertical plane C-C′ of FIG. 22B.

FIG. 22D is a schematic vertical cross-sectional view of the exemplary structure along the vertical plane D-D′ of FIG. 22B.

FIG. 22E is a horizontal cross-sectional view of the exemplary structure along the horizontal plane E-C′ of FIGS. 22A, 22C, and 22D.

FIG. 23A is a schematic vertical cross-sectional view of the exemplary structure after formation of in-process access trenches according to an embodiment of the present disclosure.

FIG. 23B is a top-down view of the exemplary structure of FIG. 23A. The vertical plane A-A′ is the cut plane of the schematic vertical cross-sectional view of FIG. 23A.

FIG. 23C is a schematic vertical cross-sectional view of the exemplary structure along the vertical plane C-C′ of FIG. 23B.

FIG. 23D is a schematic vertical cross-sectional view of the exemplary structure along the vertical plane D-D′ of FIG. 23B.

FIG. 23E is a horizontal cross-sectional view of the exemplary structure along the horizontal plane E-C′ of FIGS. 23A, 23C, and 23D.

FIG. 24A is a schematic vertical cross-sectional view of the exemplary structure after formation of access trenches according to an embodiment of the present disclosure.

FIG. 24B is a top-down view of the exemplary structure of FIG. 24A. The vertical plane A-A′ is the cut plane of the schematic vertical cross-sectional view of FIG. 24A.

FIG. 24C is a schematic vertical cross-sectional view of the exemplary structure along the vertical plane C-C′ of FIG. 24B.

FIG. 24D is a schematic vertical cross-sectional view of the exemplary structure along the vertical plane D-D′ of FIG. 24B.

FIG. 24E is a horizontal cross-sectional view of the exemplary structure along the horizontal plane E-C′ of FIGS. 24A, 24C, and 24D.

FIG. 25A is a schematic vertical cross-sectional view of the exemplary structure after formation of lateral recesses according to an embodiment of the present disclosure.

FIG. 25B is a top-down view of the exemplary structure of FIG. 25A. The vertical plane A-A′ is the cut plane of the schematic vertical cross-sectional view of FIG. 25A.

FIG. 25C is a schematic vertical cross-sectional view of the exemplary structure along the vertical plane C-C′ of FIG. 25B.

FIG. 25D is a schematic vertical cross-sectional view of the exemplary structure along the vertical plane D-D′ of FIG. 25B.

FIG. 25E is a horizontal cross-sectional view of the exemplary structure along the horizontal plane E-C′ of FIGS. 25A, 25C, and 25D.

FIG. 26A is a schematic vertical cross-sectional view of the exemplary structure after formation of electrically conductive layers according to an embodiment of the present disclosure.

FIG. 26B is a top-down view of the exemplary structure of FIG. 26A. The vertical plane A-A′ is the cut plane of the schematic vertical cross-sectional view of FIG. 26A.

FIG. 26C is a schematic vertical cross-sectional view of the exemplary structure along the vertical plane C-C′ of FIG. 26B.

FIG. 26D is a schematic vertical cross-sectional view of the exemplary structure along the vertical plane D-D′ of FIG. 26B.

FIG. 26E is a horizontal cross-sectional view of the exemplary structure along the horizontal plane E-C′ of FIGS. 26A, 26C, and 26D.

FIG. 27A is a schematic vertical cross-sectional view of the exemplary structure after formation of access trench fill structures according to an embodiment of the present disclosure.

FIG. 27B is a top-down view of the exemplary structure of FIG. 27A. The vertical plane A-A′ is the cut plane of the schematic vertical cross-sectional view of FIG. 27A.

FIG. 27C is a schematic vertical cross-sectional view of the exemplary structure along the vertical plane C-C′ of FIG. 27B.

FIG. 27D is a schematic vertical cross-sectional view of the exemplary structure along the vertical plane D-D′ of FIG. 27B.

FIG. 27E is a horizontal cross-sectional view of the exemplary structure along the horizontal plane E-C′ of FIGS. 27A, 27C, and 27D.

FIG. 28A is a schematic vertical cross-sectional view of the exemplary structure after formation of contact via structures according to an embodiment of the present disclosure.

FIG. 28B is a top-down view of the exemplary structure of FIG. 28A. The vertical plane A-A′ is the cut plane of the schematic vertical cross-sectional view of FIG. 28A.

FIG. 28C is a schematic vertical cross-sectional view of the exemplary structure along the vertical plane C-C′ of FIG. 28B.

FIG. 28D is a schematic vertical cross-sectional view of the exemplary structure along the vertical plane D-D′ of FIG. 28B.

FIG. 28E is a horizontal cross-sectional view of the exemplary structure along the horizontal plane E-C′ of FIGS. 28A, 28C, and 28D.

### DETAILED DESCRIPTION

As discussed above, embodiments of the present disclosure are directed to a three-dimensional memory device including trench support bridge structures and methods for manufacturing the same, the various aspects of which are described below.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single clement and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor die or a semiconductor package can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased by in a single erase operation. Each block contains a number of pages, which are the smallest unit that can be programmed, i.e., a smallest unit on which a read operation can be performed.

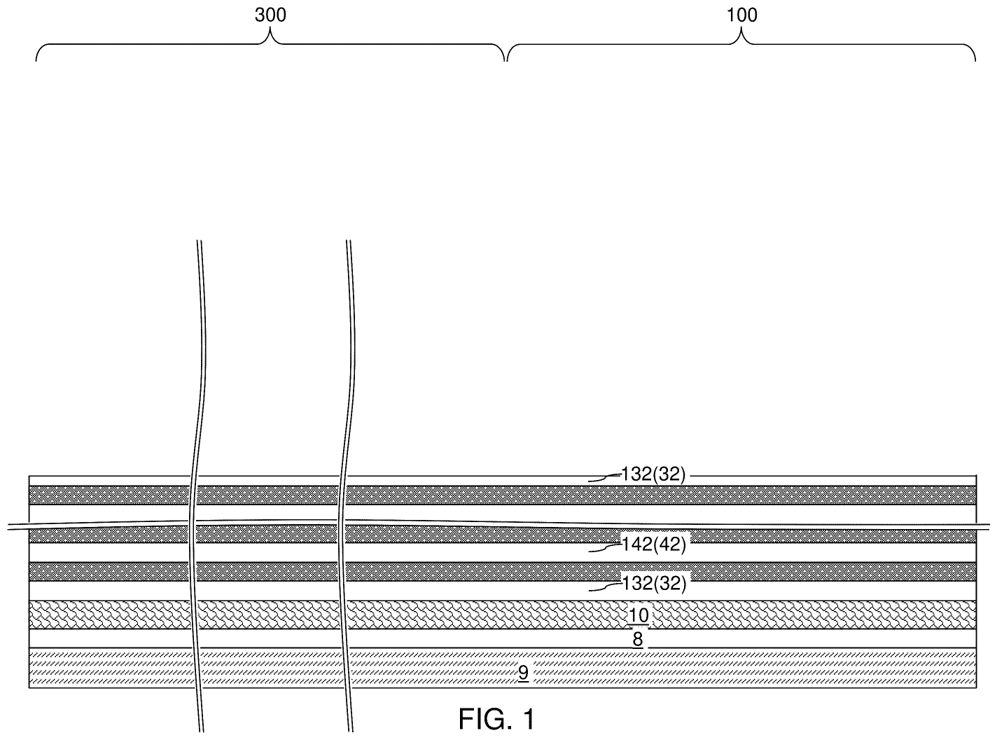

Referring to FIG. 1, an exemplary structure according to an embodiment of the present disclosure is illustrated, which comprises a substrate 9, at least one optional dielectric material layer 8, and an optional semiconductor material layer 10. The substrate 9 may comprise any substrate that can be employed to provide structural support during formation of a memory die thereupon. For example, the substrate 9 may comprise a semiconductor substrate, an insulating substate, a conductive substrate, or a combination thereof. In one embodiment, the substrate 9 may comprise a commercially available single crystalline silicon wafer. Optionally, semiconductor devices (not shown), such as field effect transistors may be formed on the top surface of the substrate to provide a semiconductor circuit, which as a peripheral circuit that may be employed to operate a three-dimensional memory array to be subsequently formed over the semiconductor material layer 10.

The at least one optional dielectric material layer 8 is optional, and may be employed as at least one dielectric matrix layer for embedding metal interconnect structures (such as metal line structures and metal via structures) which may be electrically connected to the semiconductor devices, if present, on the top surface of the substrate 9. Alternatively, in case the substrate 9 is employed as a carrier substrate that is subsequently removed, the at least one optional dielectric material layer 8 may be employed as an etch stop layer and/or a protective pad layer during subsequent removal of the substrate 9. In an illustrative example, the at least one optional dielectric material layer 8 may comprise silicon oxide, and may have a thickness in a range from 50 nm to 5,000 nm, although lesser and greater thicknesses may also be employed.

The optional semiconductor material layer 10 comprises a semiconductor material (such as polysilicon, a silicon-germanium alloy, or a III-V compound semiconductor material). The thickness of the semiconductor material layer 10 may be in a range from 100 nm to 500 nm, although lesser and greater thicknesses may also be employed. In one embodiment, the semiconductor material layer 10 may be employed as a horizontal semiconductor channel layer having a doping of a same conductivity type as vertical semiconductor channels to be subsequently formed. For example, if the vertical semiconductor channels have a doping of a first conductivity type, the semiconductor material layer 10 may having a doping of the first conductivity type. In this case, the atomic concentration of dopants of the first conductivity type in the semiconductor material layer 10 may be in a range from 1.0×10¹³/cm³ to 3.0×10¹⁷/cm³, such as from 1.0×10^{14/}cm³ to 1.0×10¹⁷/cm³, although lesser and greater atomic concentrations may also be employed. Alternatively, the semiconductor material layer 10 may be employed as a source layer having a doping of an opposite conductivity type relative to the conductivity type of dopants in the vertical semiconductor channels. For example, if the vertical semiconductor channels have a doping of a first conductivity type, the semiconductor material layer 10 may have a doping of a second conductivity type that is the opposite of the first conductivity type. In this case, the atomic concentration of dopants of the second conductivity type in the semiconductor material layer 10 may be in a range from 5.0×10¹⁹/cm³ to 2.0×10²¹/cm³, such as from 1.0×10²⁰/cm³ to 1.0×10²¹/cm³, although lesser and greater atomic concentrations may also be employed.

A first alternating stack of first insulating layers 132 and first spacer material layers can be formed over the substrate 9. In one embodiment, the first spacer material layers may comprise first sacrificial material layers 142. In this case, a first alternating stack (132, 142) of first insulating layers 132 and first sacrificial material layers 142 can be formed over the carrier substrate 9. The first insulating layers 132 comprise an insulating material such as undoped silicate glass or a doped silicate glass, and the first sacrificial material layers 142 comprise a sacrificial material such as silicon nitride or a silicon-germanium alloy. The first alternating stack (132, 142) may comprise multiple repetitions of a unit layer stack including a first insulating layer 132 and a first sacrificial material layer 142. The total number of repetitions of the unit layer stack within the first alternating stack (132, 142) may be, for example, in a range from 8 to 1,024, such as from 32 to 256, although lesser and greater number of repetitions may also be employed.

Each of the first insulating layers 132 other than the topmost first insulating layer 132 may have a thickness in a range from 20 nm to 100 nm, such as from 30 nm to 60 nm, although lesser and greater thicknesses may also be employed. Each of the first sacrificial material layers 142 may have a thickness in a range from 20 nm to 100 nm, such as from 30 nm to 60 nm, although lesser and greater thicknesses may also be employed. In one embodiment, the topmost first insulating layer 132 may have a thickness of about one half of the thickness of other first insulating layers 132. The exemplary structure may comprise a memory array region 100 in which memory stack structures are subsequently formed, and a contact region 300 in which contact via structures and support pillar structures are subsequently formed.

While an embodiment is described in which the first spacer material layers are formed as first sacrificial material layers 142, the first spacer material layers may be formed as electrically conductive layers in an alternative embodiment. Generally, spacer material layers of the present disclosure may be formed as, or may be subsequently replaced at least partly with, electrically conductive layers. Such variations of embodiments of the present disclosure are expressly contemplated herein.

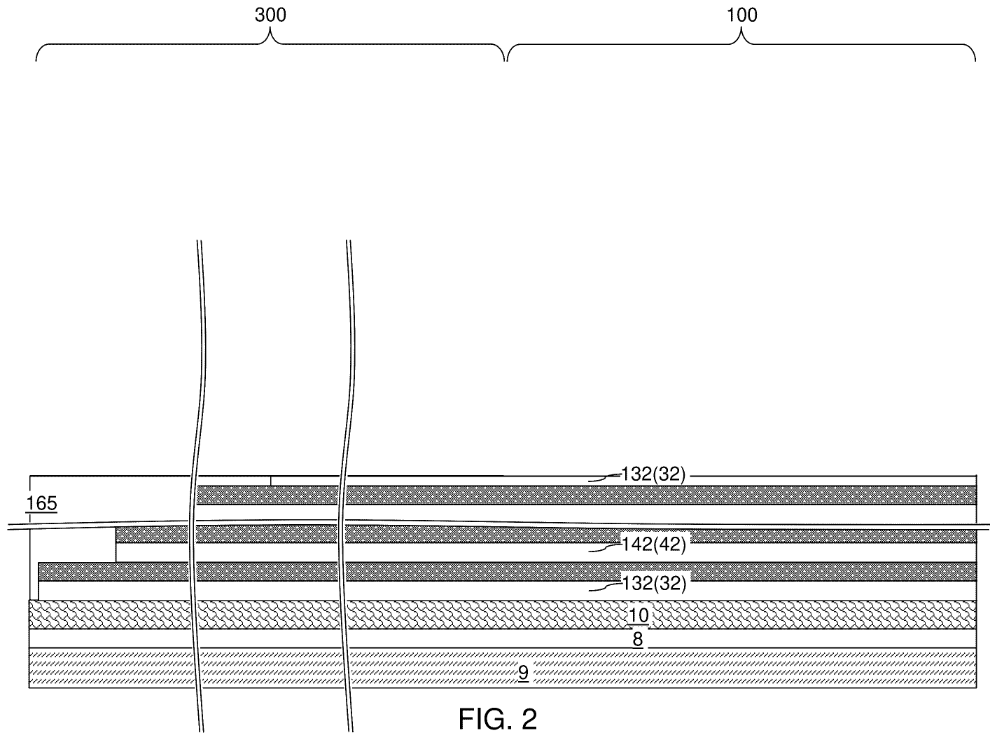

Referring to FIG. 2, optional first stepped surfaces may be formed in the contact region 300 by patterning one side of the first alternating stack (132, 142). A dielectric fill material such as undoped silicate glass or a doped silicate glass can be deposited over the stepped surfaces of the first alternating stack (132, 142), and excess portions of the dielectric fill material may be removed from above the horizontal plane including the top surface of the topmost first insulating layer 132 by a planarization process, which may employ a chemical mechanical polishing process and/or a recess etch process. A first stepped dielectric material portion 165 may be formed over the first stepped surfaces.

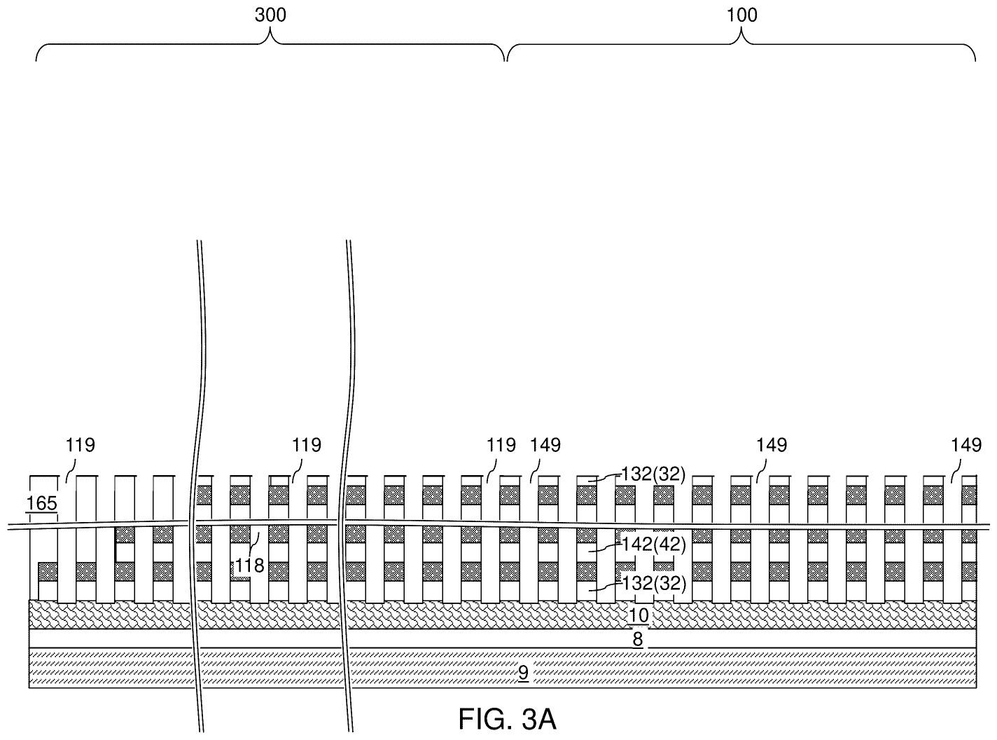

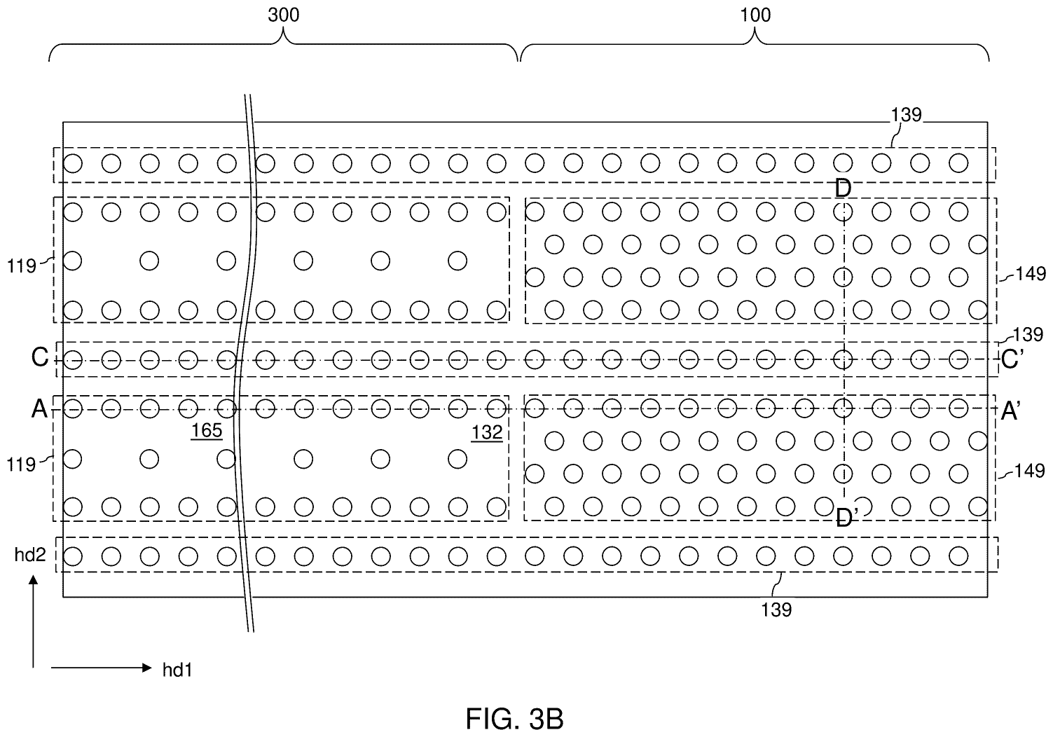

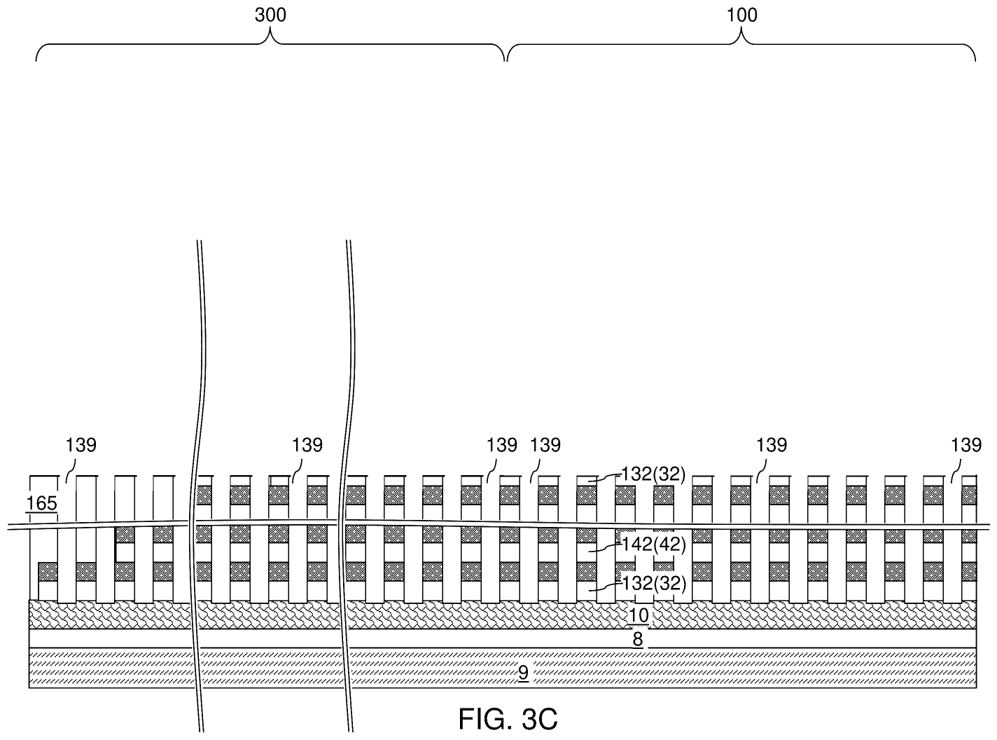

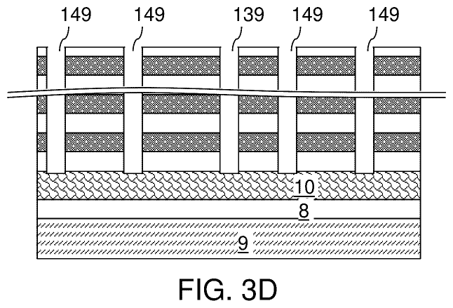

Referring to FIGS. 3A-3D, an etch mask layer (not shown) can be formed over the first alternating stack (132, 142), and can be lithographically patterned to form various openings therein. An anisotropic etch process can be performed to transfer the pattern of the openings in the etch mask layer through the first alternating stack (132, 142). First-tier openings (149, 119, 139) can be formed through the first alternating stack (132, 142). The first-tier openings (149, 119, 139) may comprise first-tier memory openings 149 that are formed in the memory array region 100 through each layer within the first alternating stack (132, 142), first-tier support openings 119 that are formed in the contact region 300 and are subsequently employed to form support pillar structures therein, and first-tier access openings 139 that are formed in rows that laterally extend along a first horizontal direction (e.g. word line direction) hd1 that is perpendicular to a boundary between the memory array region 100 and the contact region 300 and are subsequently employed to form access trenches. In one embodiment, the first-tier memory openings 149 may be formed in rows that laterally extend along the first horizontal direction hd1. Each row of first-tier access openings 139 may be formed between neighboring clusters of first-tier memory openings 149 and between neighboring clusters of first-tier support openings 119. The etch mask layer can be subsequently removed.

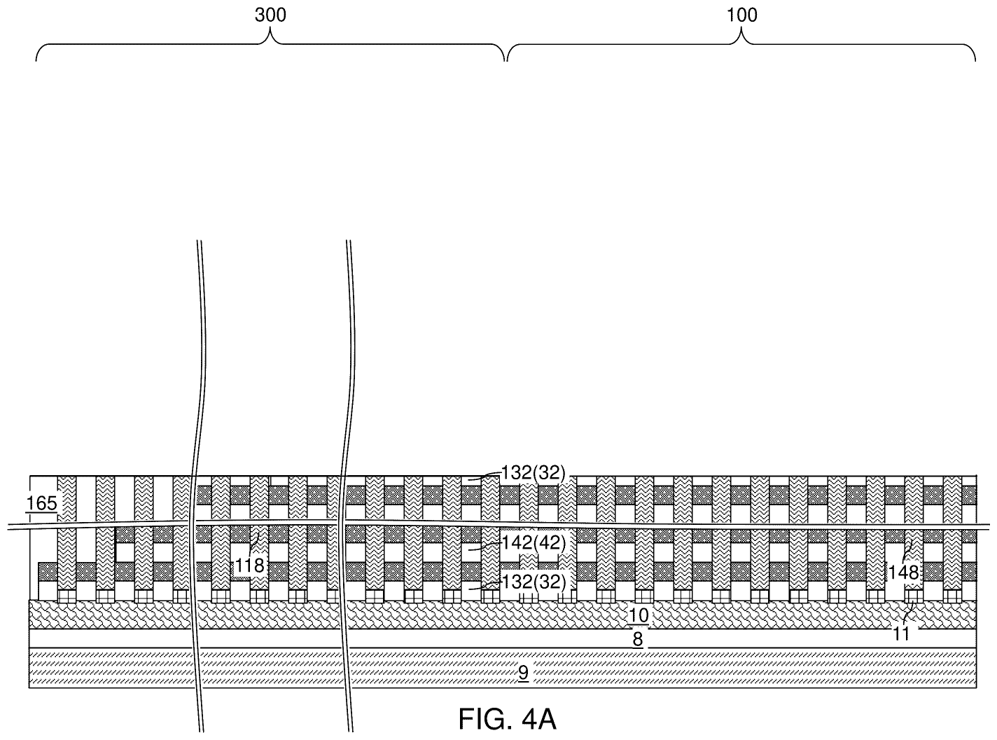

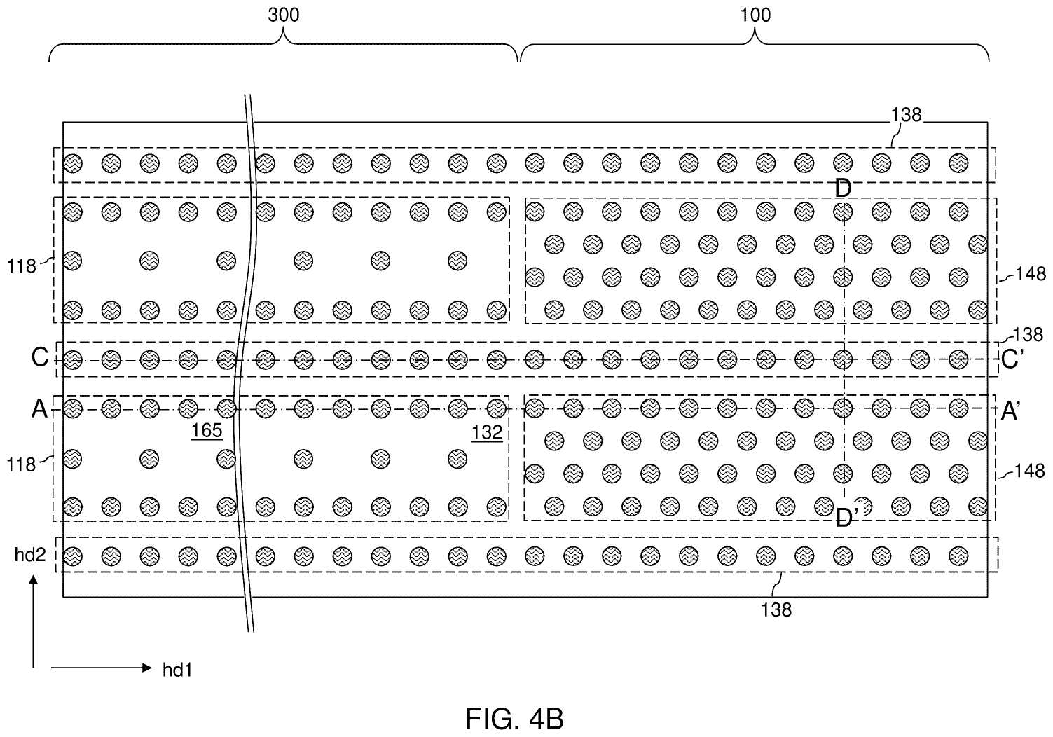

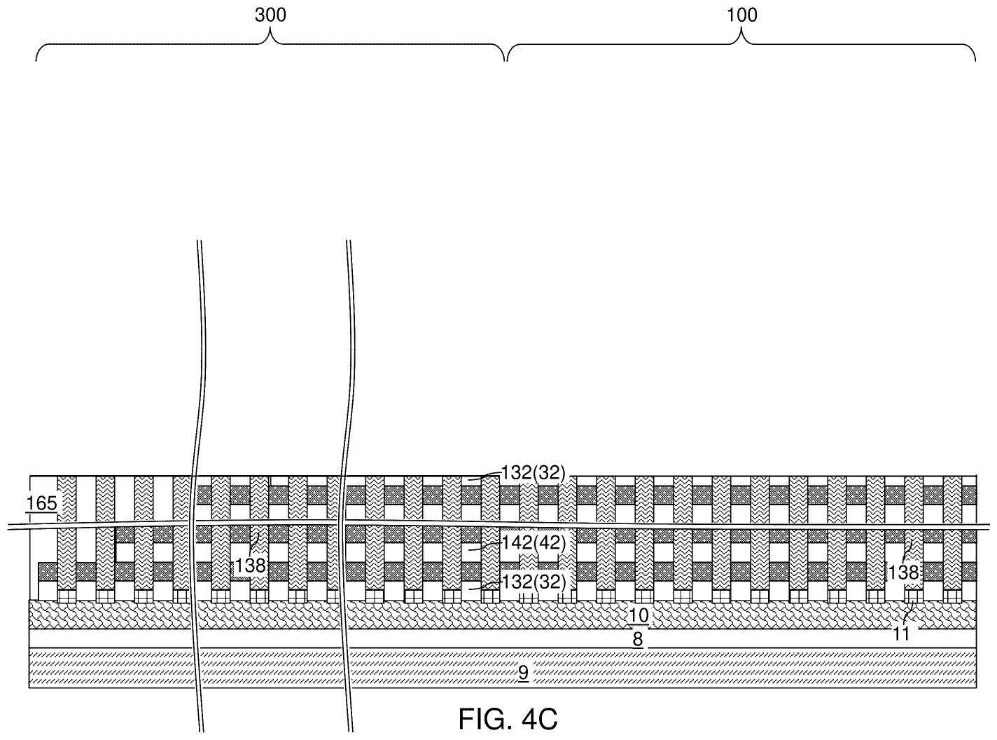

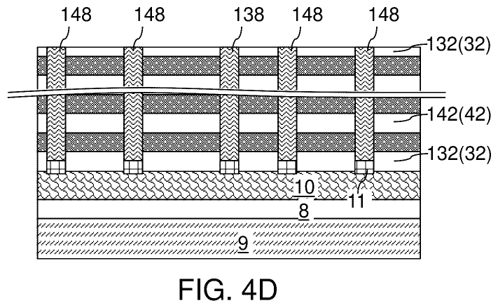

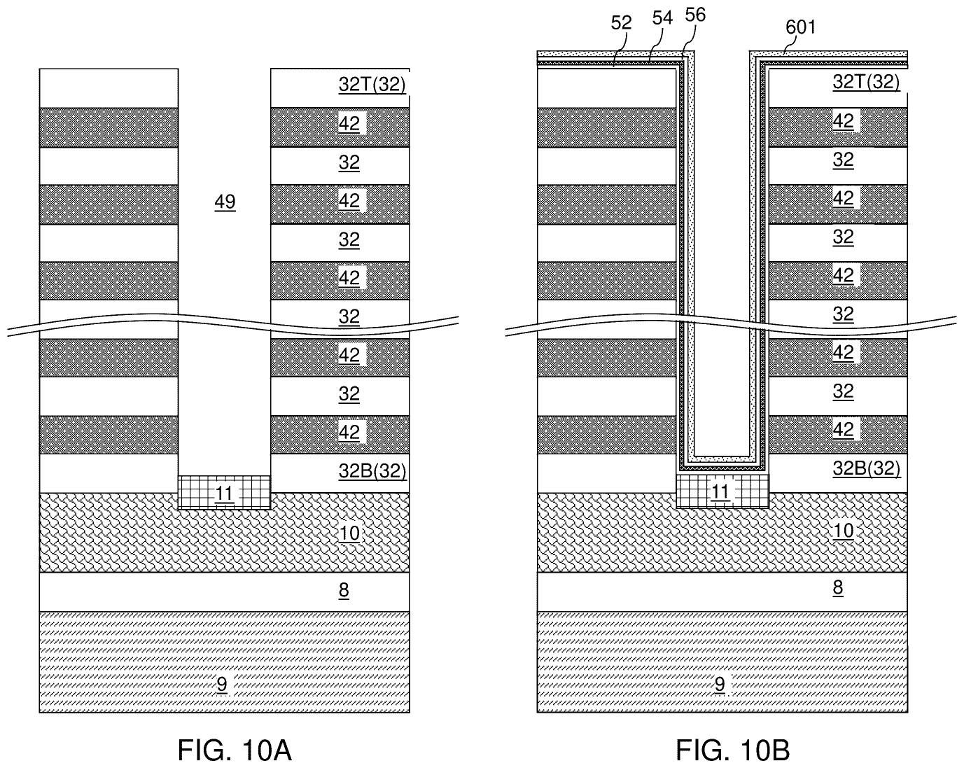

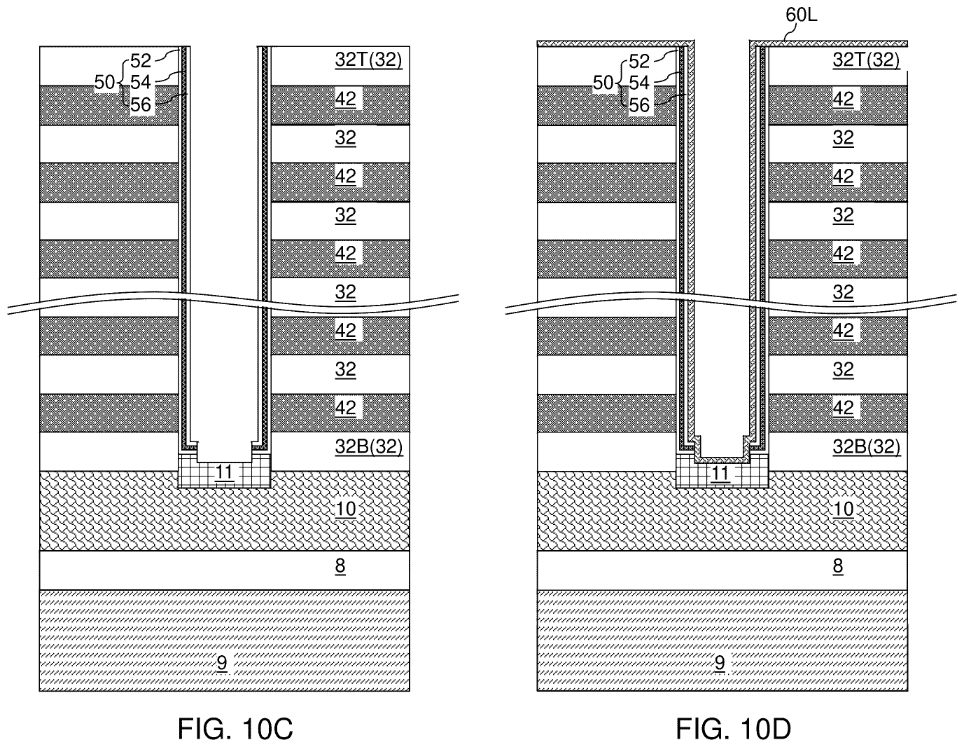

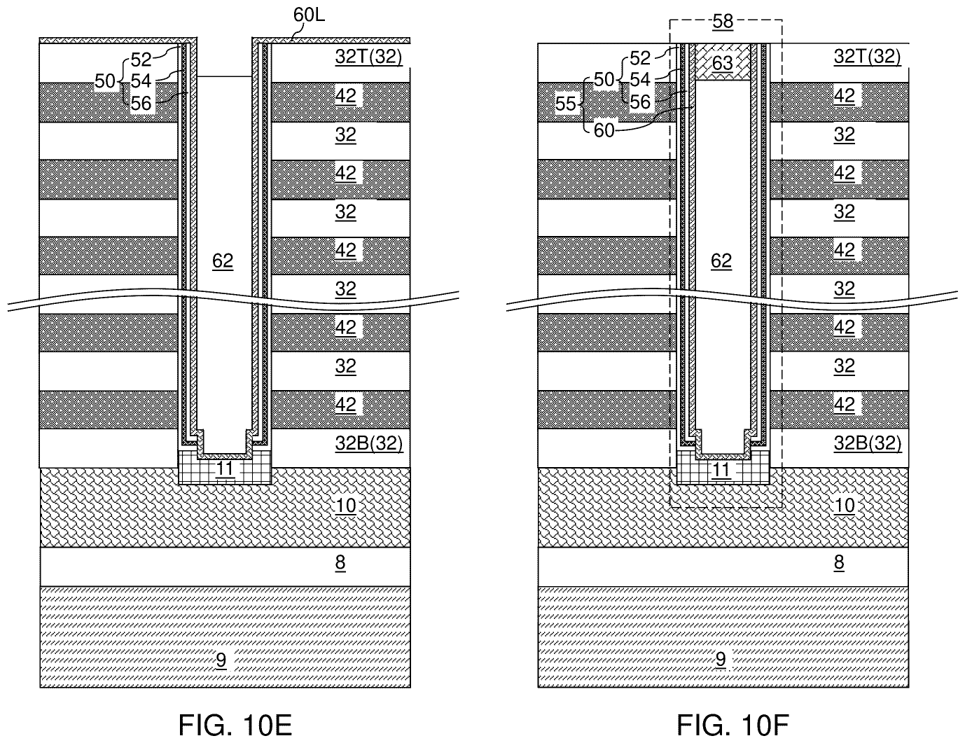

Referring to FIGS. 4A-4D, optional pedestal channel portions 11 can be formed at the bottom of each of the first-tier openings (149, 119, 139). The pedestal channel portions 11 may comprise a semiconductor material, and can be formed by selective growth of the semiconductor material from physically exposed surfaces of the semiconductor material layer 10. A selective semiconductor deposition process such as a selective epitaxy process may be employed to form the pedestal channel portions 11. Alternatively, the pedestal channel portions 11 may be omitted or formed during the step described below with respect to FIG. 10A.

A first sacrificial fill material may be deposited in the remaining unfilled volumes of the first-tier openings (149, 119, 139). Excess portions of the first sacrificial fill material can be removed from above the horizontal plane including the top surface of the topmost first insulating layer 132 by performing a planarization process. Each remaining portion of the first sacrificial fill material constitutes a first-tier sacrificial opening fill structure (148, 118, 138). The first-tier sacrificial opening fill structure (148, 118, 138) comprises first-tier sacrificial memory opening fill structures 148 that are formed in the first-tier memory openings 149, first-tier sacrificial support opening fill structures 118 that are formed in the first-tier support openings 119, and first-tier sacrificial access opening fill structures 138 that are formed in the first-tier access openings 139. The first sacrificial fill material may comprise carbon (e.g., amorphous carbon or diamond-like carbon), a semiconductor material (e.g., amorphous silicon), organosilicate glass, a polymer material, or any other material that can be subsequently removed selective to materials of the first alternating stack (132, 142) and the pedestal channel portions 11.

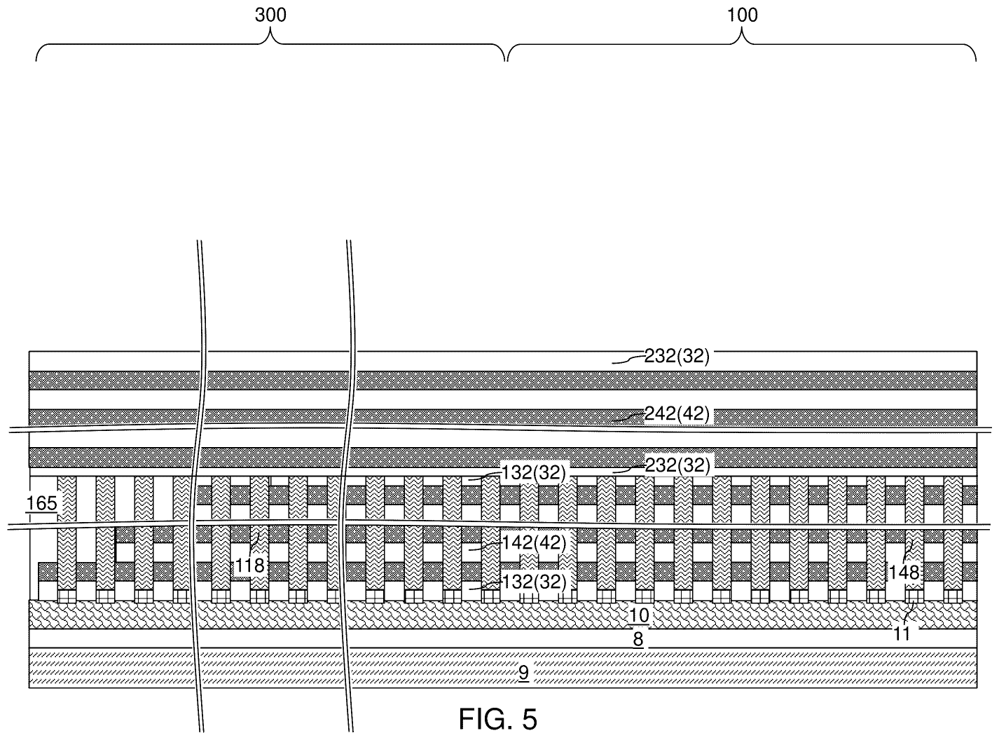

Referring to FIG. 5, a second alternating stack (232, 242) of second insulating layers 232 and second sacrificial material layers 242 can be formed over the first alternating stack (132, 232). The second insulating layers 232 comprise an insulating material such as undoped silicate glass or a doped silicate glass, and the second sacrificial material layers 242 comprise a sacrificial material such as silicon nitride or a silicon-germanium alloy. The second alternating stack (232, 242) may comprise multiple repetitions of a unit layer stack including a second insulating layer 2502 and a second sacrificial material layer 242. The total number of repetitions of the unit layer stack within the second alternating stack (232, 242) may be, for example, in a range from 8 to 2,024, such as from 32 to 256, although lesser and greater number of repetitions may also be employed.

Each of the second insulating layers 232 other than the bottommost second insulating layer may have a thickness in a range from 20 nm to 200 nm, such as from 30 nm to 60 nm, although lesser and greater thicknesses may also be employed. Each of the second sacrificial material layers 242 may have a thickness in a range from 20 nm to 200 nm, such as from 30 nm to 60 nm, although lesser and greater thicknesses may also be employed. In one embodiment, the bottommost second insulating layer may have a thickness of about one half of the thickness of other second insulating layers 232.

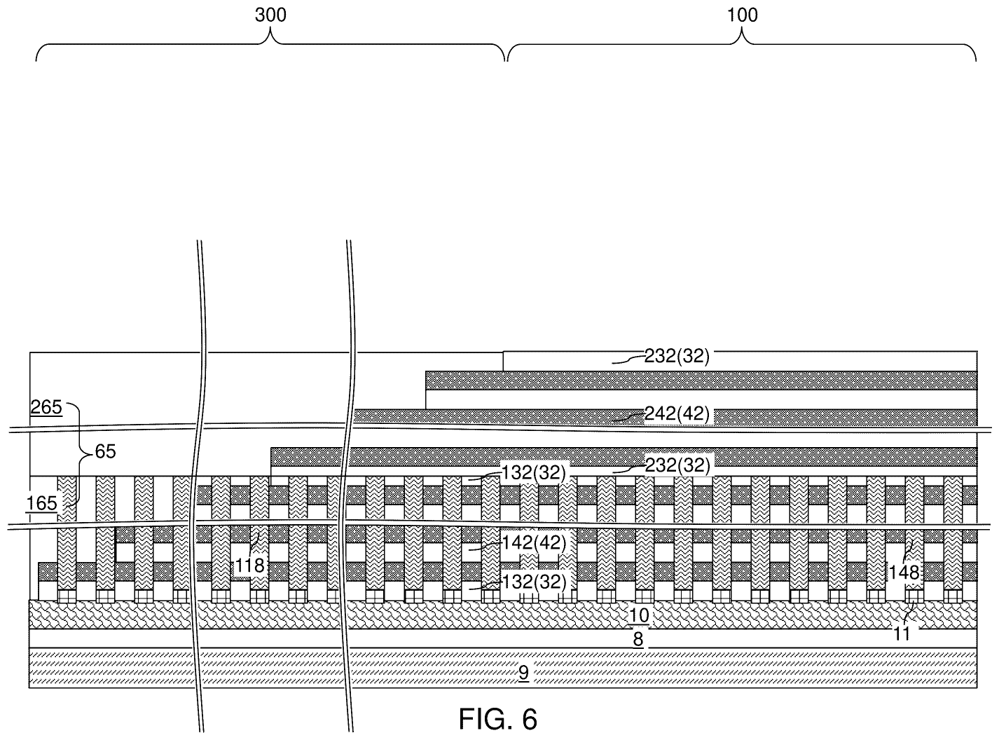

Referring to FIG. 6, optional second stepped surfaces may be formed by patterning a side of the second alternating stack (232, 242) that is adjacent to the first stepped surfaces. Another side of the second alternating stack (232, 242) may be removed to provide a straight sidewall that extends from a bottommost surface to a topmost surface of the second alternating stack (232, 242). A dielectric fill material such as undoped silicate glass or a doped silicate glass can be deposited over the second alternating stack (232, 242), and excess portions of the dielectric fill material may be removed from above the horizontal plane including the top surface of the topmost second insulating layer 2502 by a planarization process, which may employ a chemical mechanical polishing process and/or a recess etch process. A second stepped dielectric material portion 265 may be formed over the second stepped surfaces.

The first insulating layers 132 and the second insulating layers 232 are hereafter collectively referred to as insulating layers 32. The topmost one of the insulating layers 32 is hereafter referred to as a topmost insulating layer 32. The first sacrificial material layers 142 and the second sacrificial material layers 242 are hereafter collectively referred to as sacrificial material layers 42. The first stepped dielectric material portion 165 and the second stepped dielectric material portion 265 are hereafter collectively referred to as a stepped dielectric material portion 65.

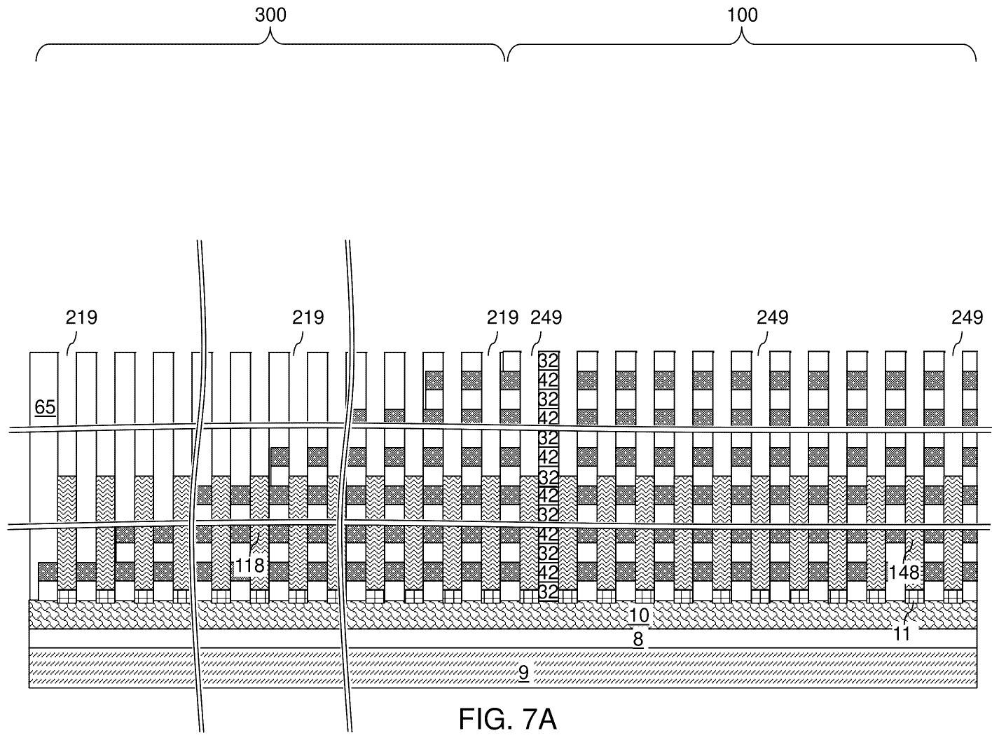

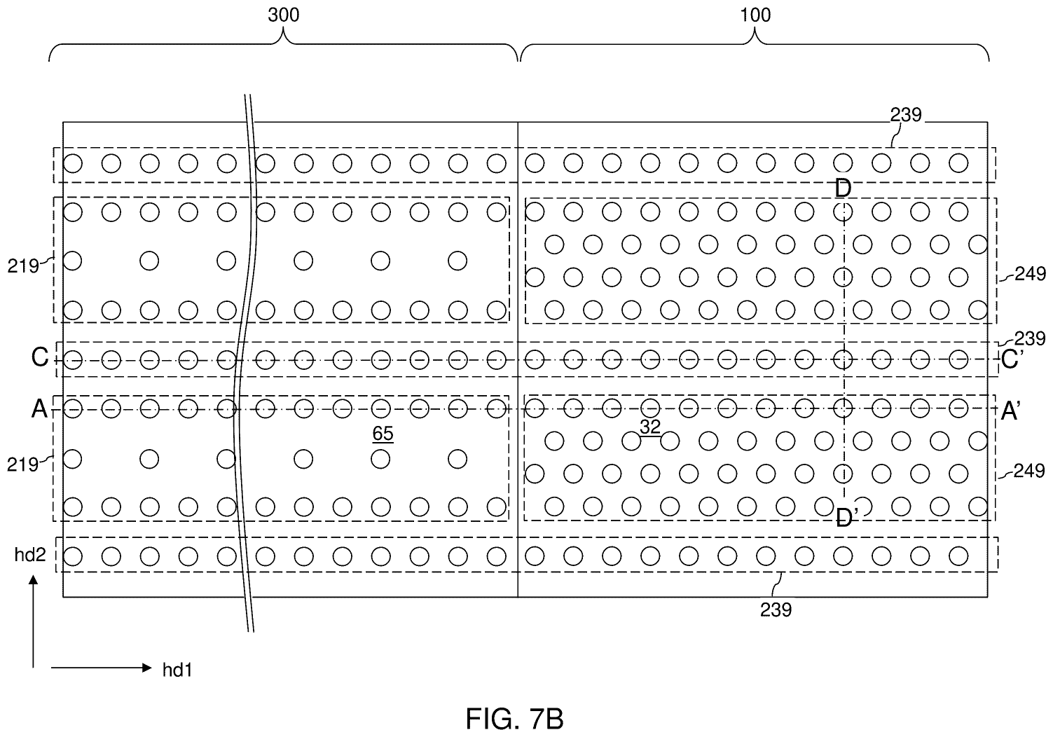

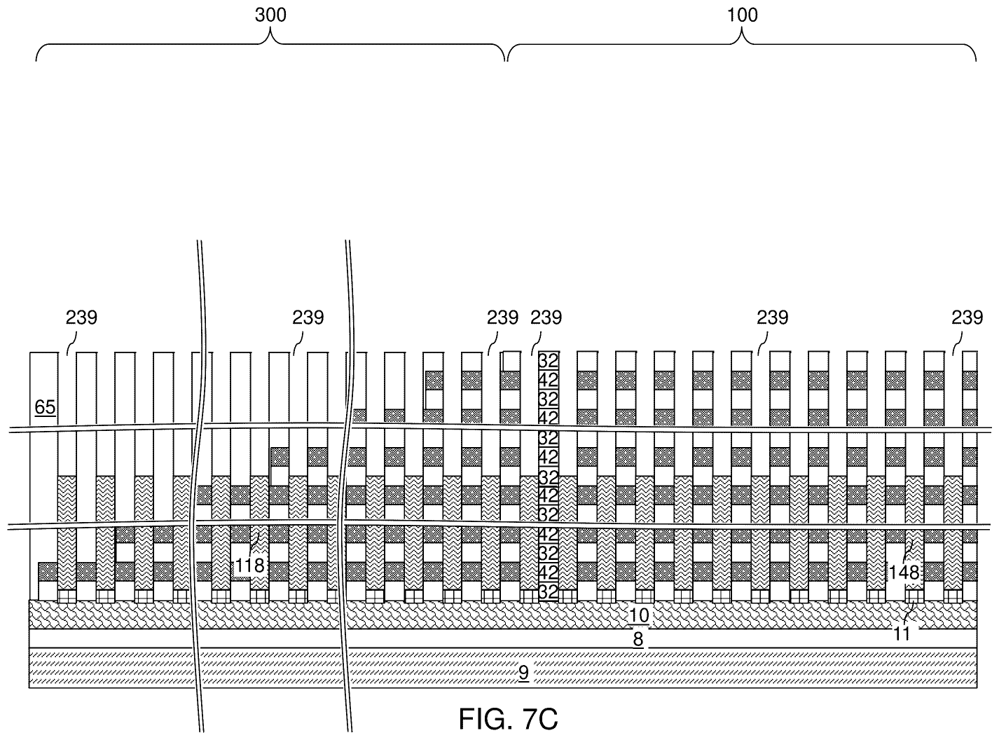

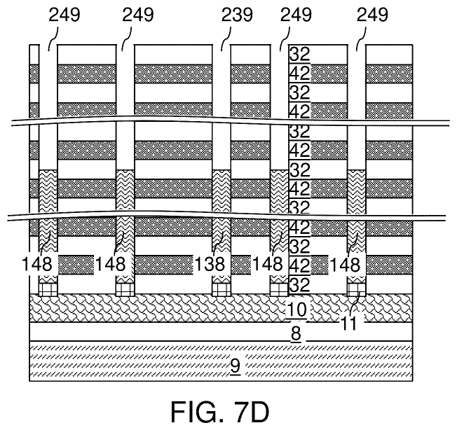

Referring to FIGS. 7A-7D, an etch mask layer (not shown) can be formed over the second alternating stack (232, 242), and can be lithographically patterned to form various openings therein. An anisotropic etch process can be performed to transfer the pattern of the openings in the etch mask layer through the second alternating stack (232, 242). Second-tier openings (249, 219, 239) can be formed through the second alternating stack (232, 242). The second-tier openings (249, 219, 239) may comprise second-tier memory openings 249 that are formed in the memory array region 100 through each layer within the second alternating stack (232, 242) directly on a top surface of a respective one of the first-tier sacrificial memory opening fill structures 148, second-tier support openings 219 that are formed in the contact region 300 directly on a top surface of a respective one of the first-tier sacrificial support opening fill structures 118, and second-tier access opening 239 that are formed through the second alternating stack (232, 242) in the memory array region 100 and in the contact region 300 directly on a top surface of a respective one of the first-tier sacrificial access opening fill structure 138. The etch mask layer can be subsequently removed.

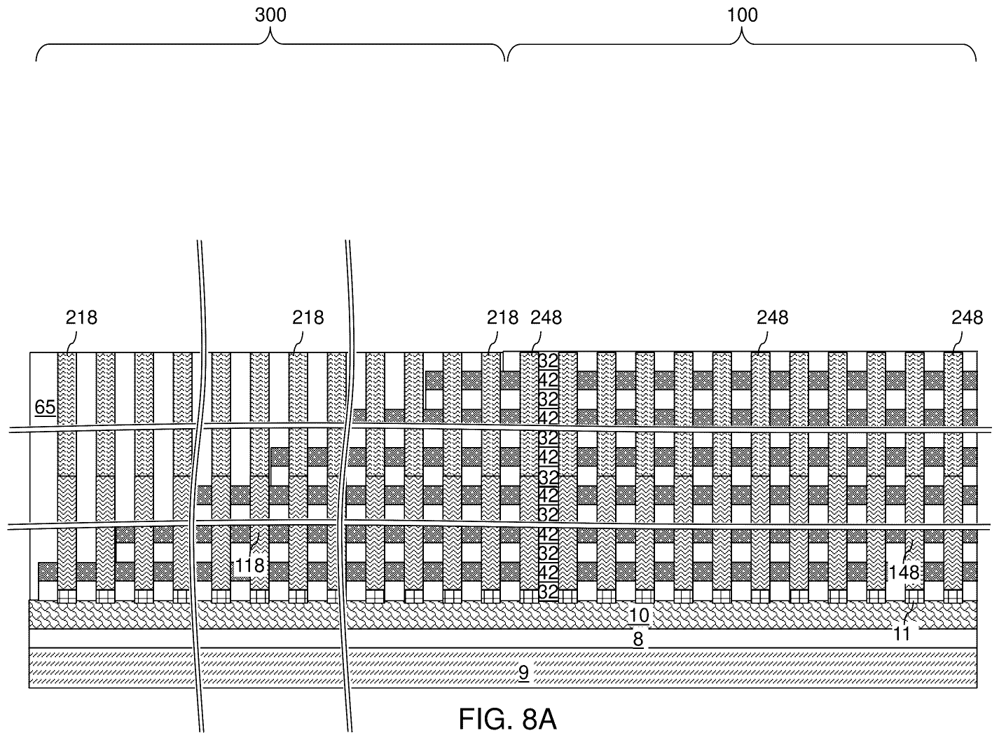

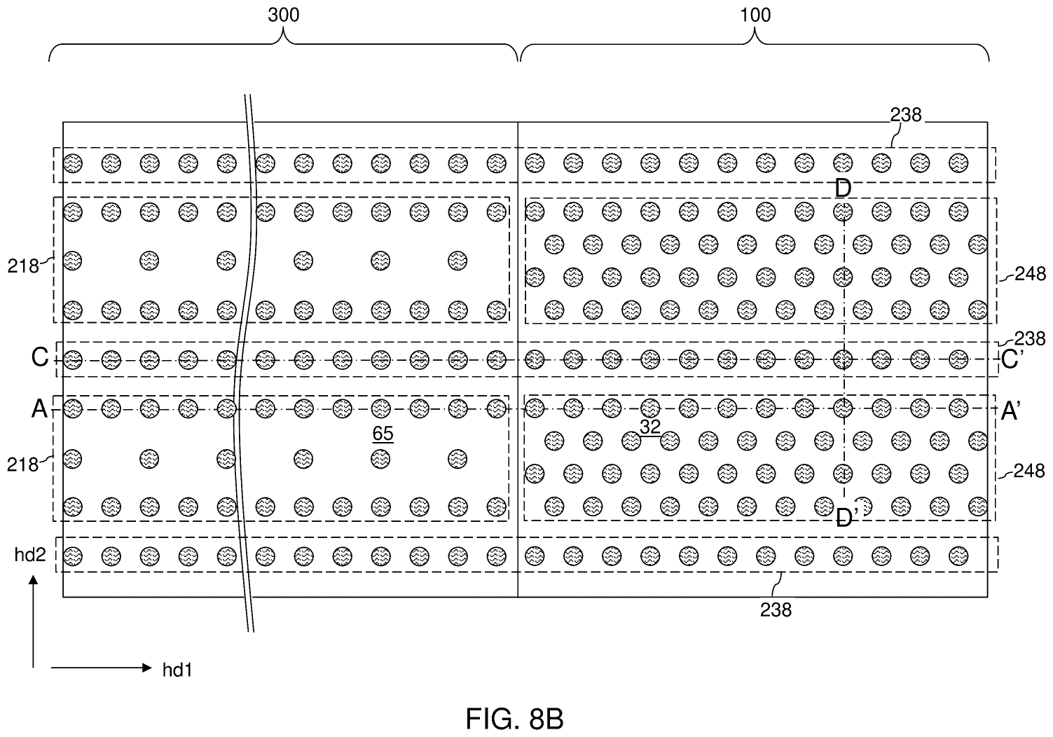

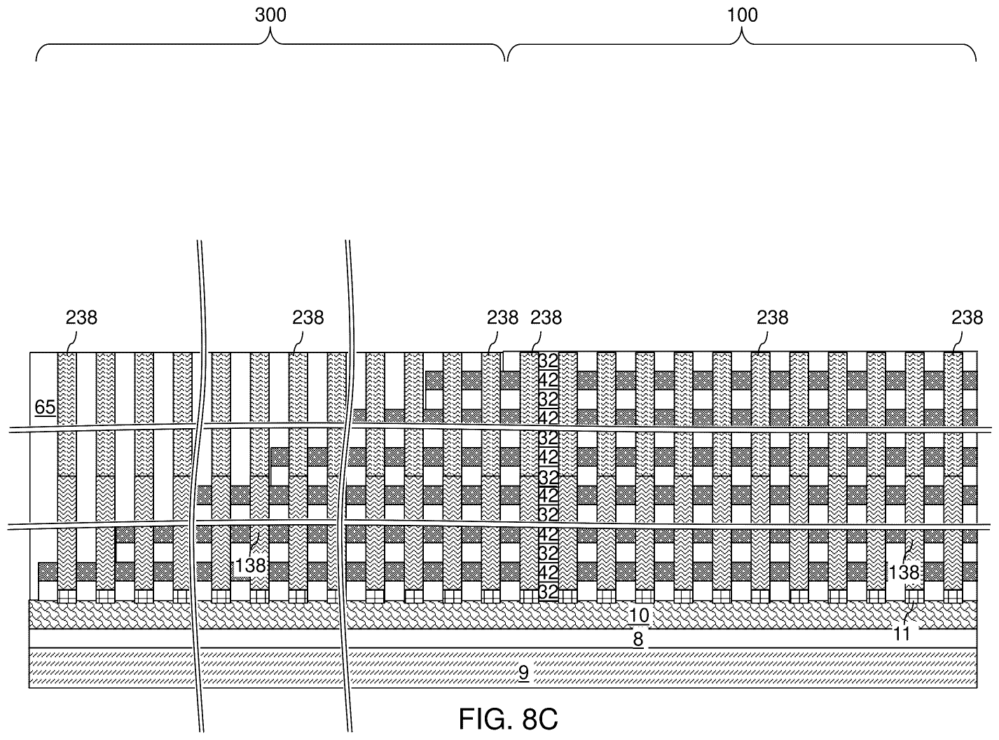

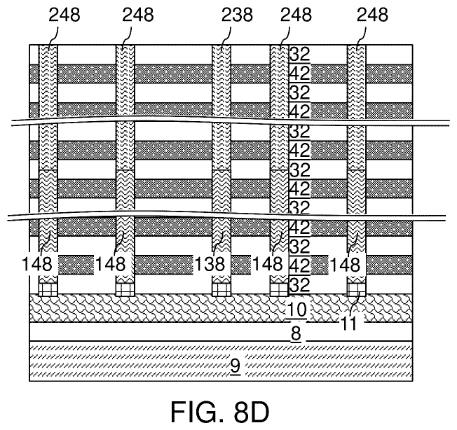

Referring to FIGS. 8A-8D, a second sacrificial fill material may be deposited in the second-tier openings (249, 219, 239). Excess portions of the second sacrificial fill material can be removed from above the horizontal plane including the top surface of the topmost insulating layer 32 by performing a planarization process. Each remaining portion of the second sacrificial fill material constitutes a second-tier sacrificial opening fill structure (248, 238). The second-tier sacrificial opening fill structure (248, 238) comprises second-tier sacrificial memory opening fill structures 248 that are formed in the second-tier memory openings 249 and directly on a respective one of the first-tier sacrificial memory opening fill structures 148, second-tier sacrificial support opening fill structures 218 that are formed in the second-tier support openings 219 and directly on a respective one of the first-tier sacrificial support opening fill structures 118, and second-tier sacrificial access opening fill structures 238 that are formed in the second-tier access openings 239 and directly on a respective one of the first-tier sacrificial access opening fill structures 138. The second sacrificial fill material may comprise carbon (e.g., amorphous carbon or diamond-like carbon), a semiconductor material (e.g., amorphous silicon), organosilicate glass, a polymer material, or any other material that can be subsequently removed selective to materials of the second alternating stack (232, 242) and the pedestal channel portions 11. The second sacrificial fill material may be the same as the first sacrificial fill material.

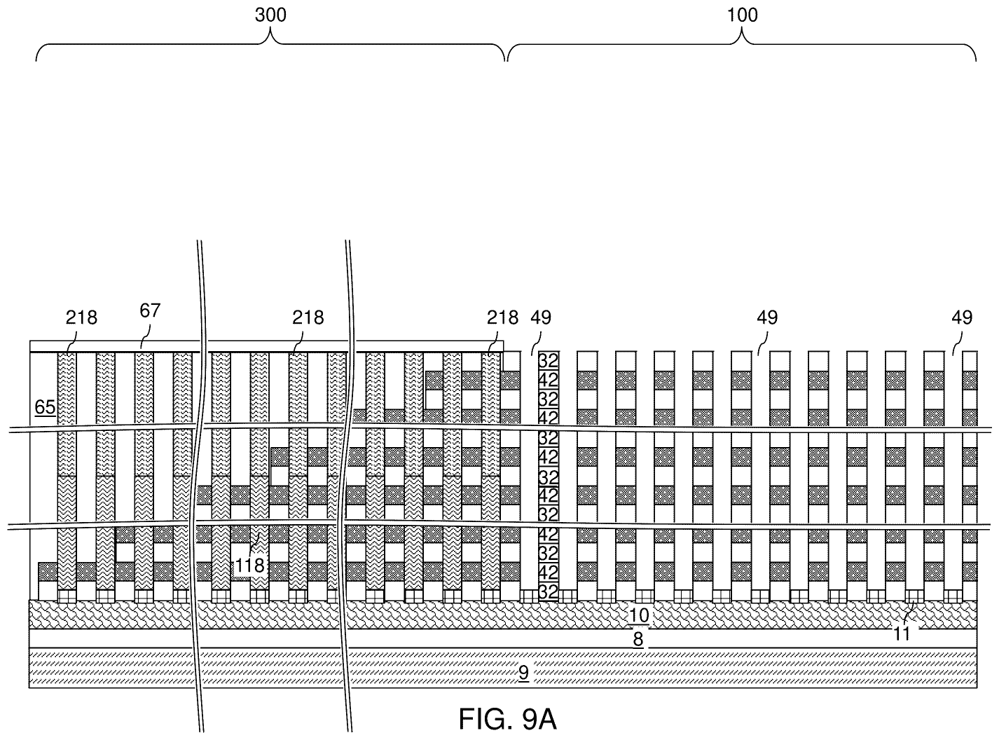

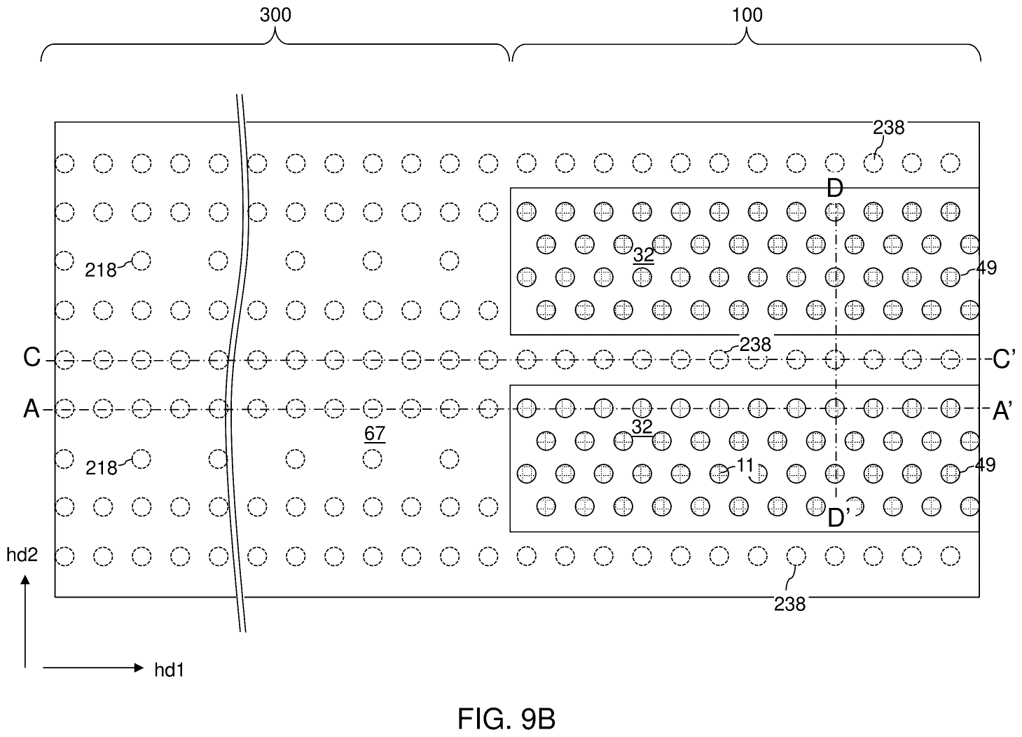

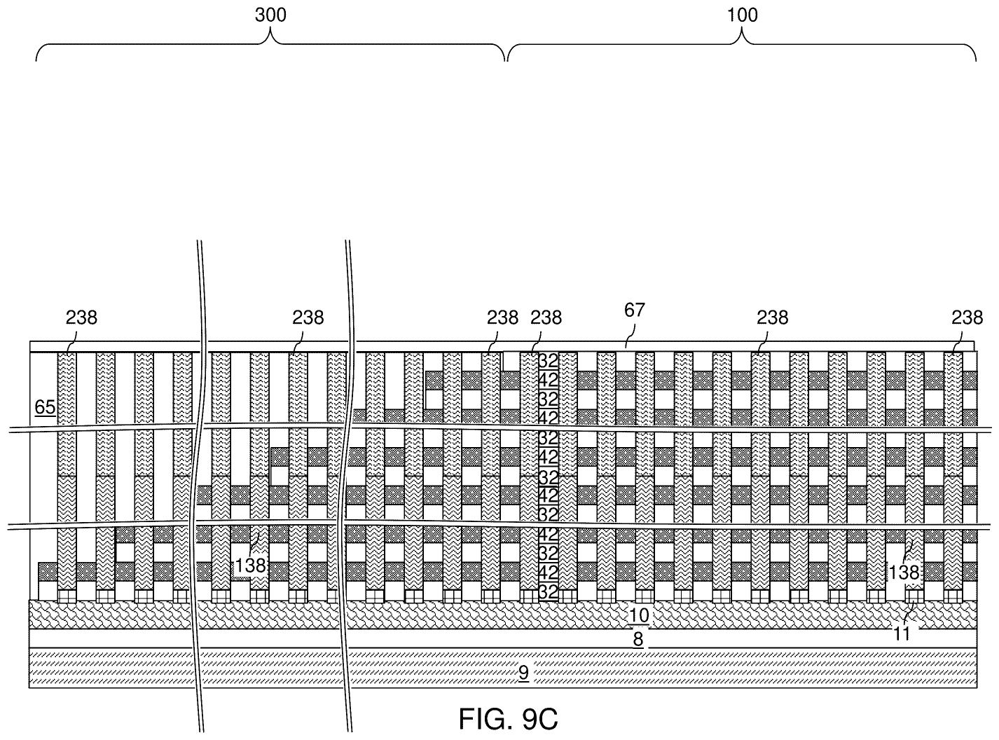

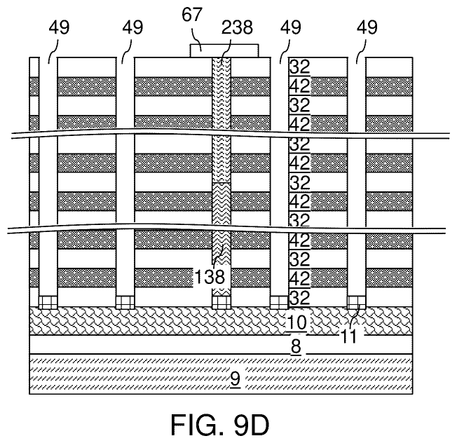

Referring to FIGS. 9A-9D, a sacrificial masking material layer 67 can be applied over the alternating stack (32, 42). The sacrificial masking material layer 67 comprises a material that is different from the second sacrificial fill material and the first sacrificial fill material, and can protect the second sacrificial fill material and the first sacrificial fill material during a subsequent removal process. For example, the sacrificial masking material layer 67 may comprise a silicate glass, silicon nitride, a dielectric metal oxide, and/or a metallic material. The thickness of the sacrificial masking material layer 67 may be in a range from 5 nm to 50 nm, although lesser and greater thicknesses may also be employed. A photoresist layer (not shown) can be applied over the sacrificial masking material layer 67, and can be lithographically patterned to cover the areas of the second-tier sacrificial access opening fill structures 238 and the second-tier sacrificial support opening fill structures 218 without covering the areas of the second-tier sacrificial memory opening fill structures 248.

An etch process can be performed to transfer the pattern in the photoresist layer though the sacrificial masking material layer 67, and to physically expose the second-tier sacrificial memory opening fill structures 248. The sacrificial fill materials of the second-tier sacrificial memory opening fill structures 248 and the first-tier sacrificial memory opening fill structures 148 can be removed selective to the materials of the alternating stacks (32, 42) and the pedestal channel portions 11 while the sacrificial masking material layer 67 covers, and protects, the second-tier sacrificial access opening fill structures 238 and the second-tier sacrificial support opening fill structures 218. Memory openings 49, which are also referred to inter-tier memory openings 49, can be formed in volumes from which the second-tier sacrificial memory opening fill structures 248 and the first-tier sacrificial memory opening fill structures 148 are removed. The photoresist layer can be subsequently removed, for example, by ashing. The sacrificial masking material layer 67 may be collaterally removed during formation of memory opening fill structures in the inter-tier memory openings 49 during subsequent processing steps.

FIGS. 10A-10F are sequential schematic vertical cross-sectional views of a memory opening 49 during formation of a memory opening fill structure 58 according to an embodiments of the present disclosure.

Referring to FIG. 10A, a memory opening 49 in the exemplary structure is illustrated after the processing steps of FIGS. 9A-9D. The topmost one of the insulating layers 32 is herein referred to as a topmost insulating layer 32T. A top surface of each pedestal channel portion 11 may have a periphery contacting a respective cylindrical sidewall of the bottommost insulating layer 32B, which is the bottommost one of the insulating layers 32 that contacts the semiconductor material layer 10. Alternatively, if the pedestal channel portions 11 are not formed during the step illustrated in FIGS. 4A-4D, then they may be formed in the memory openings during the step shown in FIG. 10D.

Referring to FIG. 10B, a layer stack including a memory material layer 54 can be conformally deposited. In an illustrative example, the layer stack may comprise an optional blocking dielectric layer 52, the memory material layer 54, an optional dielectric liner 56, and an optional sacrificial cover layer 601. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprises a charge storage material, the optional dielectric liner 56 may comprise a tunneling dielectric layer. The sacrificial cover layer 601, if present, comprises a material that can protect the dielectric liner 56 or the memory material layer 54 during a subsequent anisotropic etch process. The sacrificial cover layer 601 comprises a sacrificial cover material such as amorphous silicon, polysilicon, or a carbon-based material (such as amorphous carbon or diamond-like carbon) which is different from the material of the remaining sacrificial structures (118, 218, 138, 238).

Referring to FIG. 10C, an anisotropic etch process can be performed to remove horizontally-extending portions of the optional sacrificial cover layer 601, the optional dielectric liner 56, the memory material layer 54, and the blocking dielectric layer 52. Each combination of remaining portions of the optional dielectric liner 56, the memory material layer 54, and the blocking dielectric layer 52 in a respective memory opening 49 constitutes a memory film 50. The optional sacrificial cover layer 601, if employed, can be subsequently removed selective to the optional dielectric liner 56 and/or the memory material layer 54. A top surface of a pedestal channel portion 11 can be physically exposed at the bottom of each memory opening 49.

Referring to FIG. 10D, a semiconductor channel material layer 60L can be deposited over each memory film 50 and directly on each pedestal channel portion 11 by performing a conformal deposition process. If the semiconductor channel material layer 60L is doped, the semiconductor channel material layer 60L may have a doping of a first conductivity type, which may be p-type or n-type. The semiconductor channel material layer 60L may comprise amorphous silicon or polysilicon.

Referring to FIG. 10E, a dielectric core layer comprising a dielectric fill material can be deposited in remaining volumes of the memory openings 49. The dielectric core layer can be vertically recessed such that each remaining portion of the dielectric core layer has a top surface at, or about, the horizontal plane including the bottom surface of the topmost insulating layer 32T. Each remaining portion of the dielectric core layer constitutes a dielectric core 62.

Referring to FIG. 10F, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon or amorphous silicon.

Excess portions of the deposited semiconductor material having a doping of the second conductivity type and a horizontal portion of the semiconductor channel layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a pedestal channel portion 11 if present), a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers.

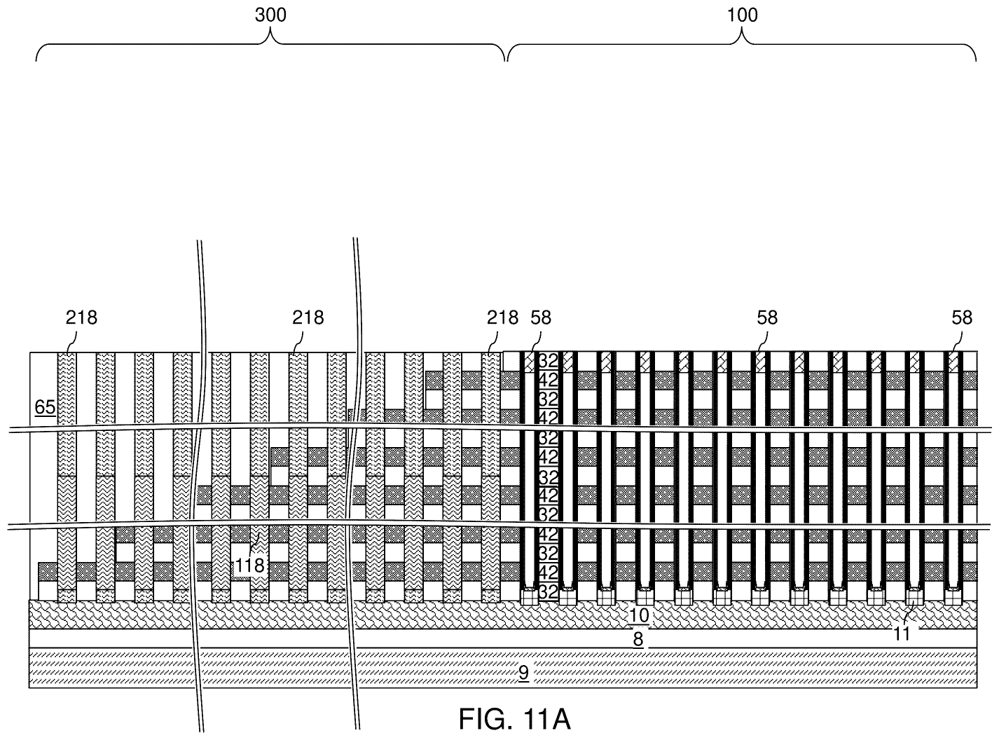

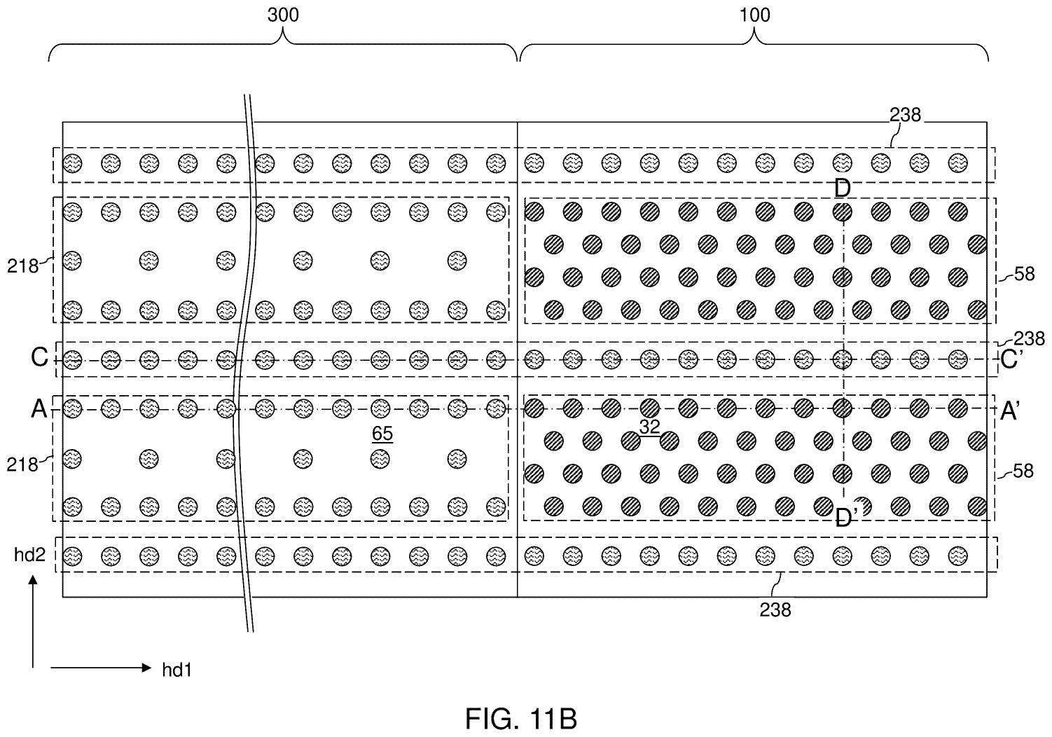

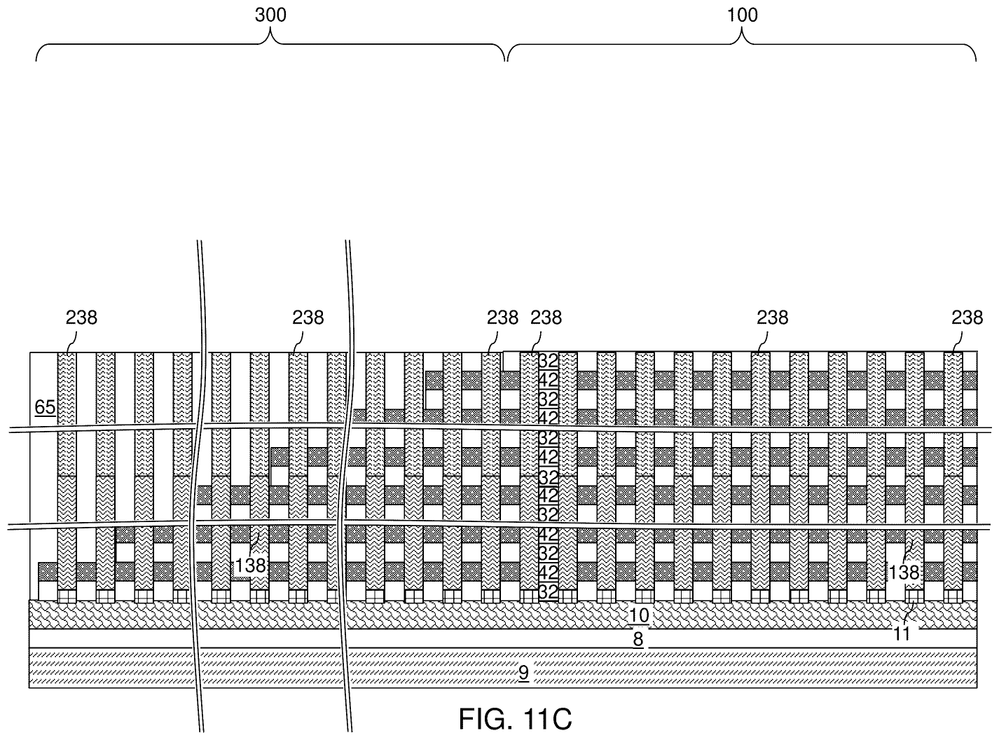

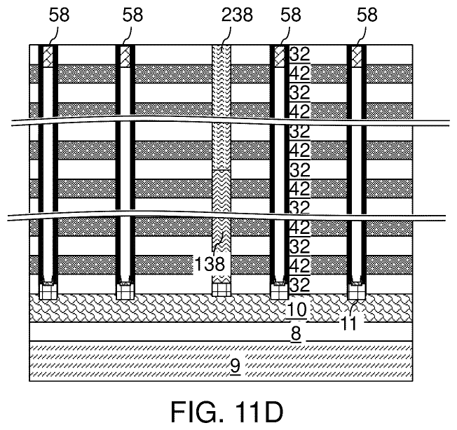

Referring to FIGS. 11A-11D, the exemplary structure is illustrated after formation of memory opening fill structures 58 within the memory openings 49.

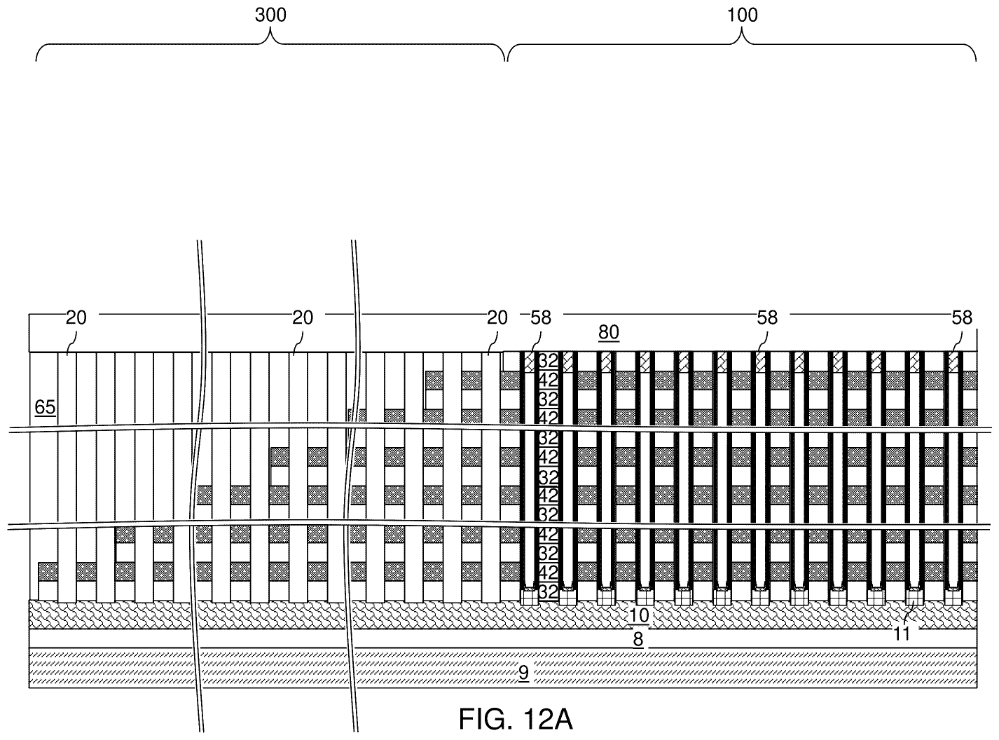

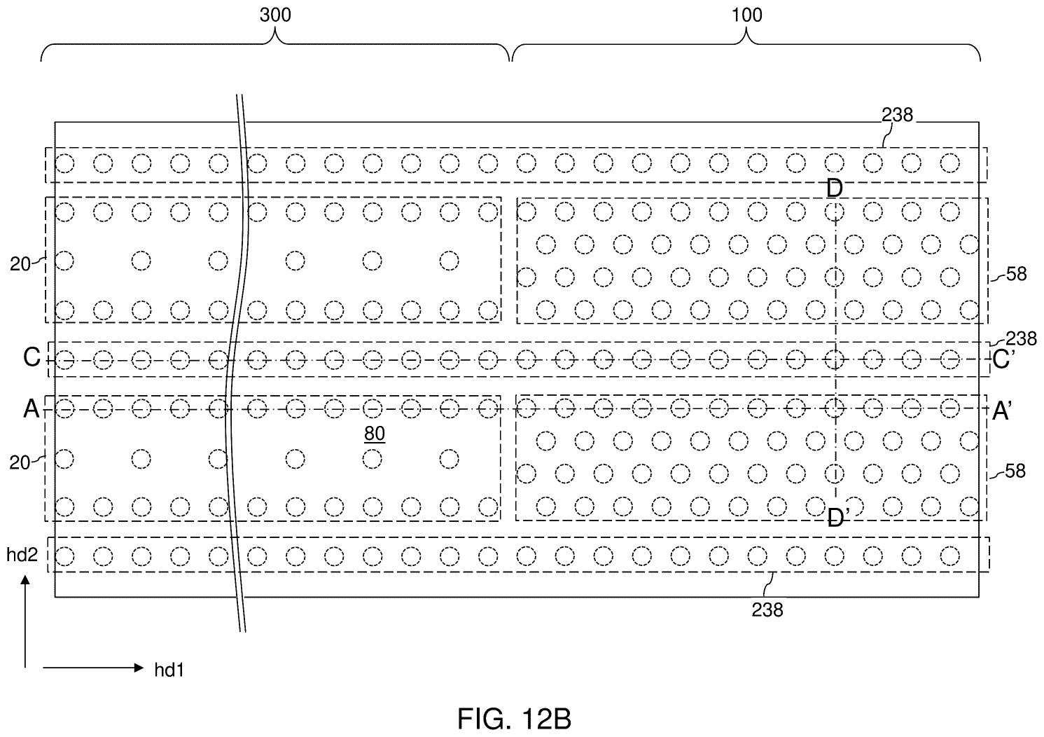

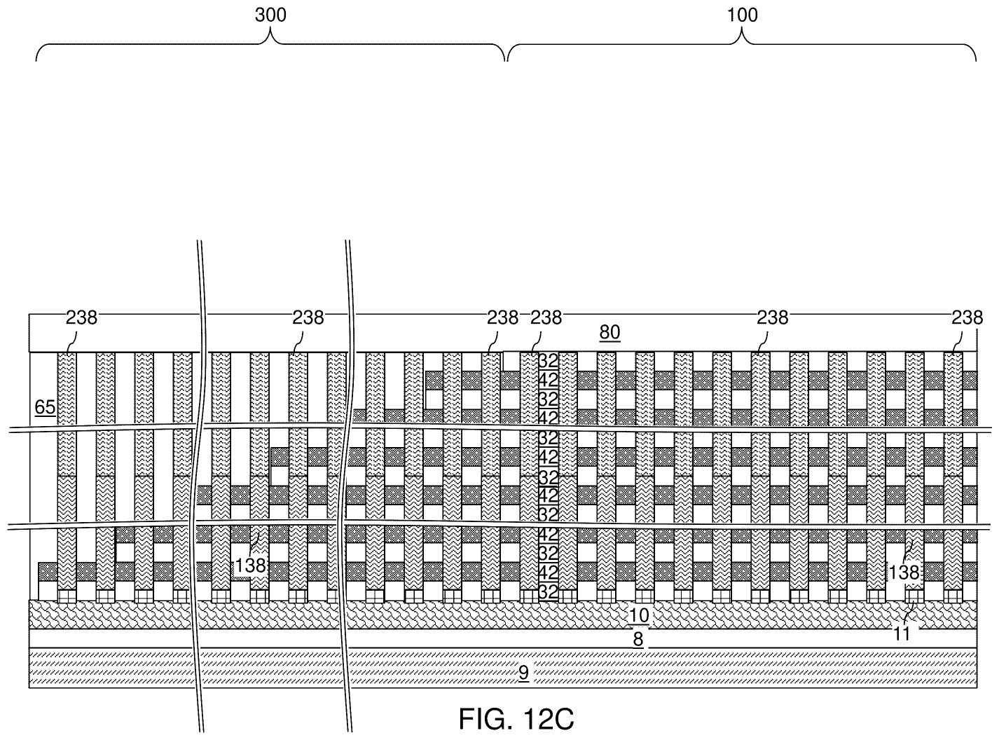

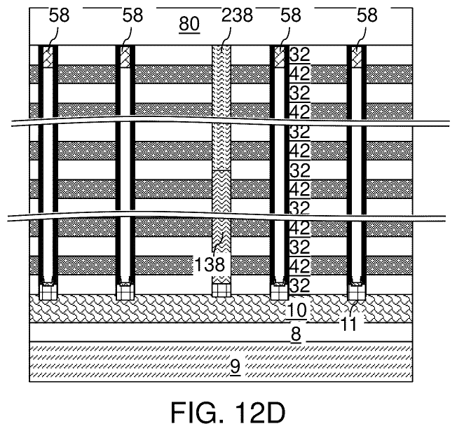

Referring to FIGS. 12A-12D, a photoresist layer (not shown) can be applied over the alternating stack (32, 42), and can be lithographically patterned to cover the second-tier sacrificial access opening fill structures 238 and the memory opening fill structures 58 without covering the second-tier sacrificial support opening fill structures 218. The sacrificial fill materials of the second-tier sacrificial support opening fill structures 218 and the first-tier sacrificial support opening fill structures 118 can be removed. If present, then the underlying pedestal channel portions 11 may also be removed. Support openings 19, which are also referred to inter-tier support openings 19, can be formed in volumes from which the second-tier sacrificial support opening fill structures 218, the first-tier sacrificial support opening fill structures 148, and the pedestal channel portions 11 are removed. The photoresist layer can be subsequently removed, for example, by ashing.

A dielectric fill material, such as silicon oxide, can be deposited in the inter-tier support openings. Each portion of the dielectric fill material that fills a respective inter-tier support openings 19 constitutes a support pillar structure 20. A horizontally-extending portion of the deposited dielectric fill material that is formed above the topmost insulating layer 32T constitutes a contact-level dielectric layer 80. The thickness of the contact-level dielectric layer 80 may be in a range from 100 nm to 1,000 nm, although lesser and greater thicknesses may also be employed. The sacrificial access opening fill structures (138, 238) are present in the access openings (139, 239), and the contact-level dielectric layer 80 can be formed over the sacrificial access opening fill structures (138, 238).

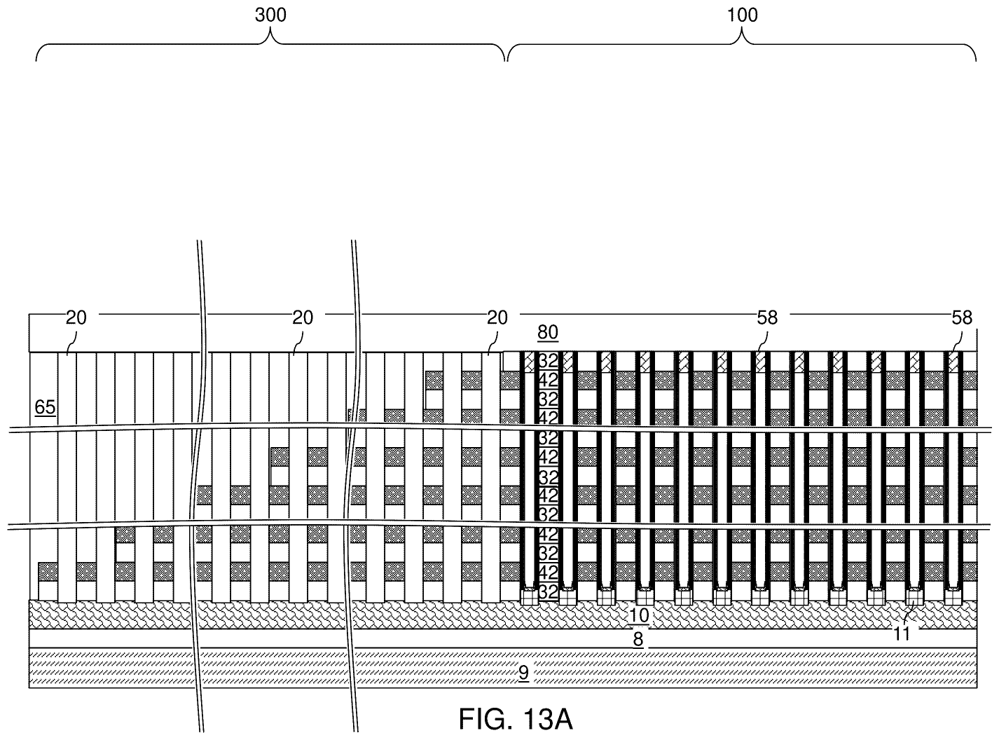

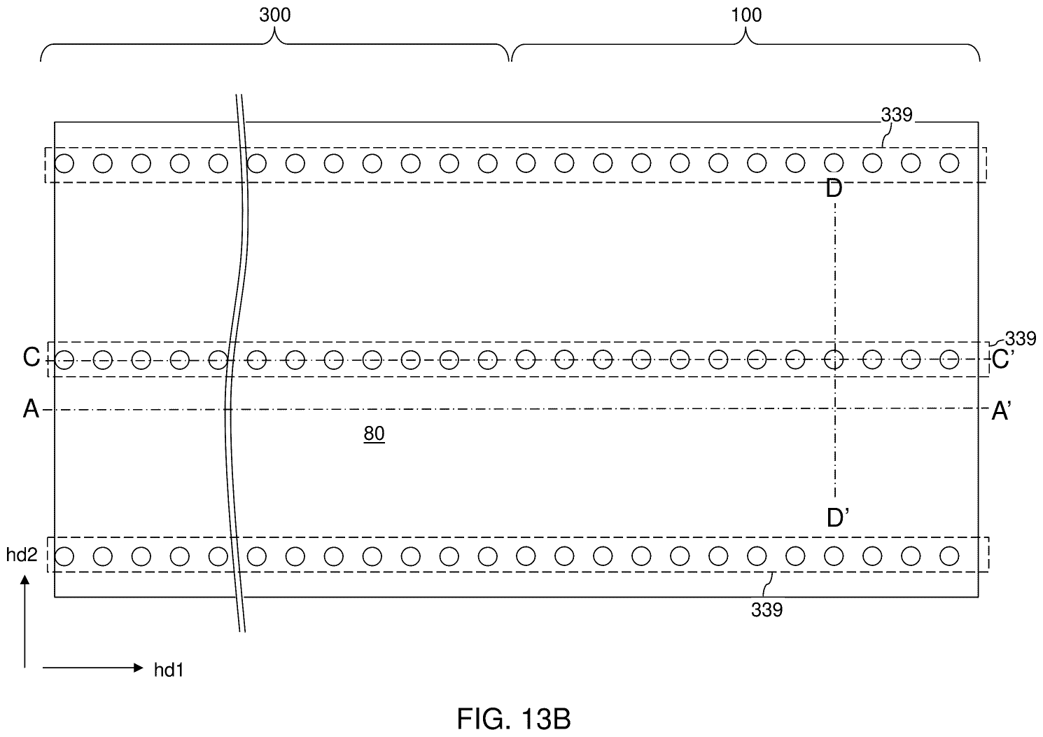

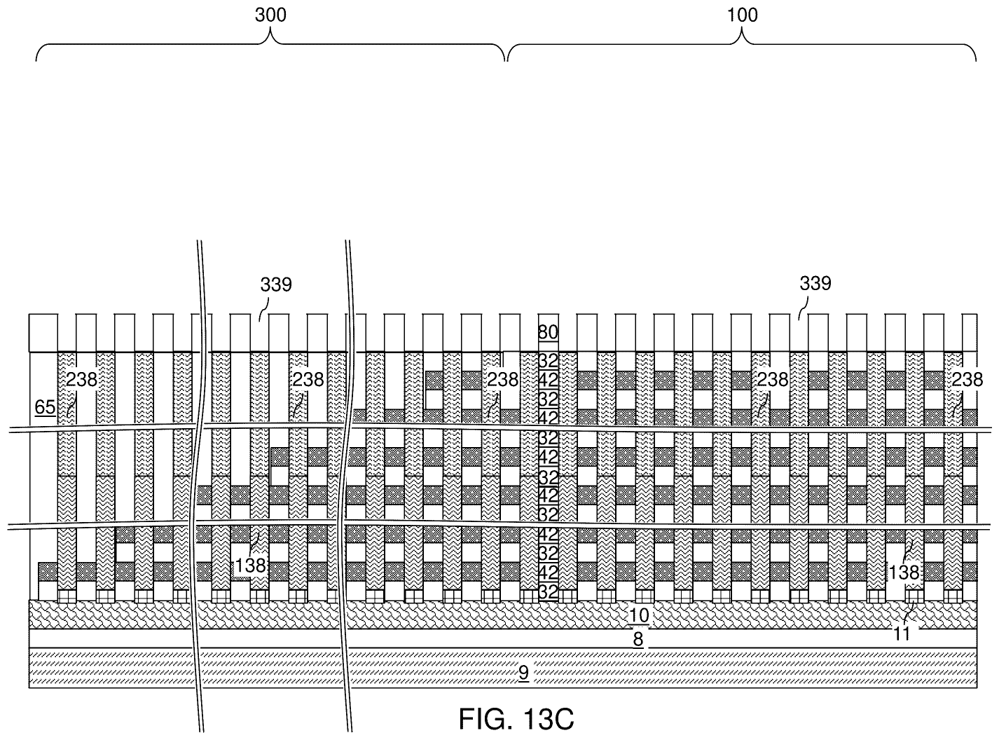

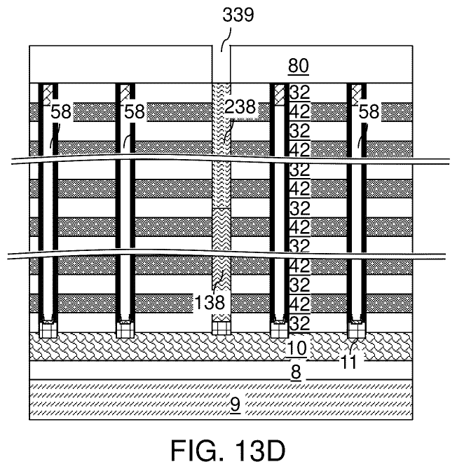

Referring to FIGS. 13A-13D, a photoresist layer (not shown) can be applied over the contact-level dielectric layer 80, and can be lithographically patterned to form openings having the same pattern as the pattern of the sacrificial access opening fill structures (138, 238). An anisotropic etch process can be performed to form rows of openings through the contact-level dielectric layer 80. A top surface of a second-tier sacrificial access opening fill structure 238 can be physically exposed at the bottom of each opening through the contact-level dielectric layer 80. The openings through the contact-level dielectric layer 80 are herein referred to as connection via cavities 339. Generally, the connection via cavities 339 are formed through the contact-level dielectric layer 80 on a top surface of a respective one of the sacrificial access opening fill structures (138, 238). The photoresist layer can be subsequently removed, for example, by ashing.

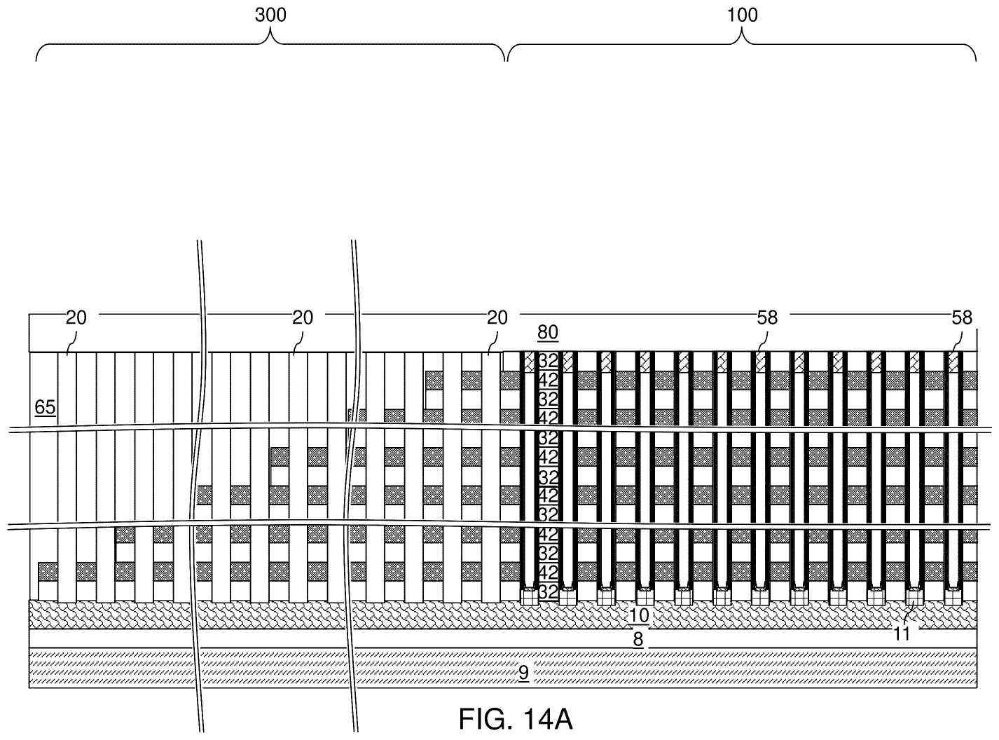

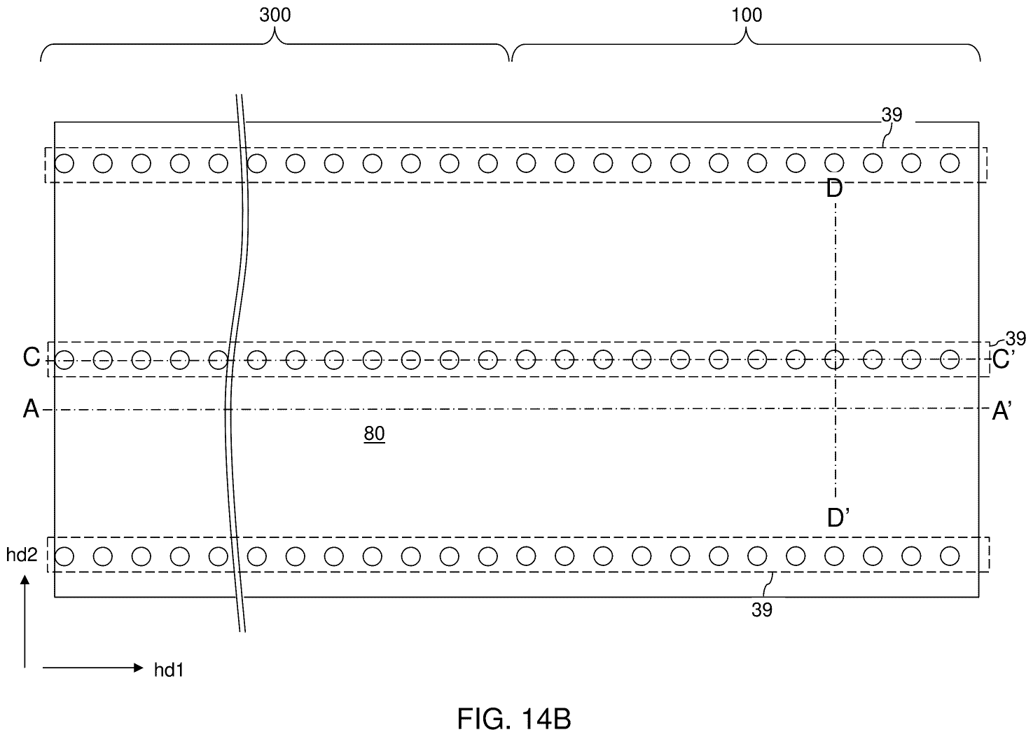

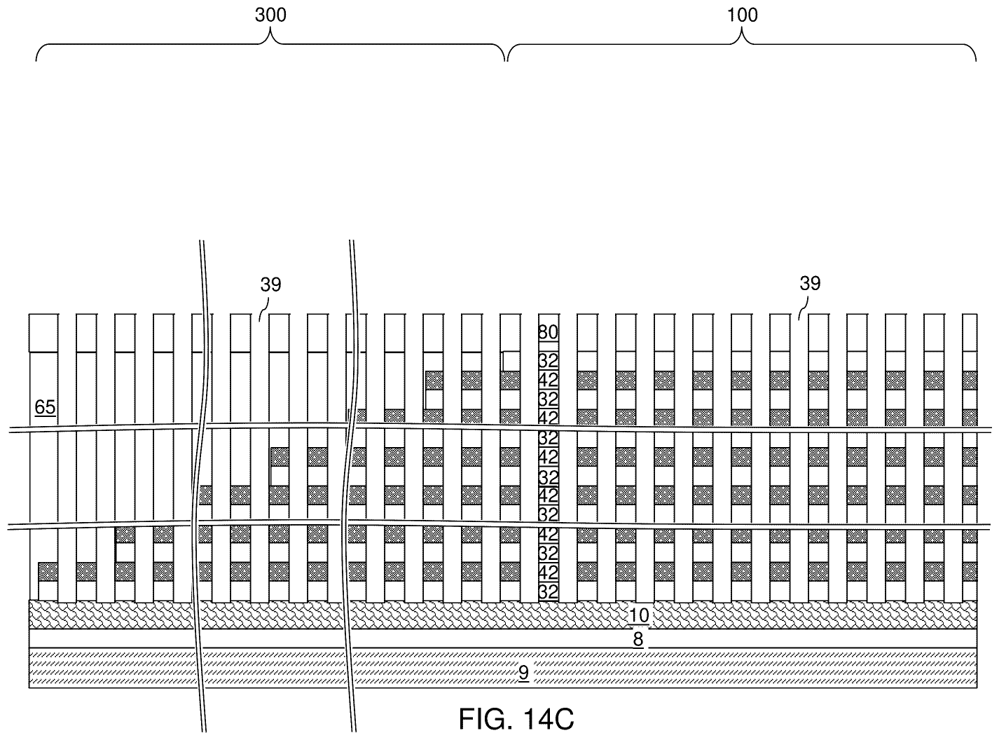

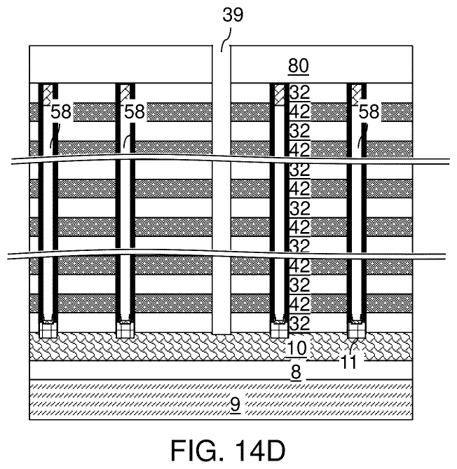

Referring to FIGS. 14A-14D, the sacrificial access opening fill structures (138, 238) can be removed selective to the materials of the alternating stack (32, 42) by performing a selective etch process, which may comprise an anisotropic etch process or an isotropic etch process. If present, then the underlying pedestal channel portions 11 may be subsequently removed by performing an additional etch process. The cavities formed by removal of the sacrificial access opening fill structures (138, 238) and the pedestal channel portions 11 are herein referred to as access openings 39 or inter-tier access openings 39. A top surface of the semiconductor material layer 10 may be physically exposed at the bottom of each of the inter-tier access openings 39.

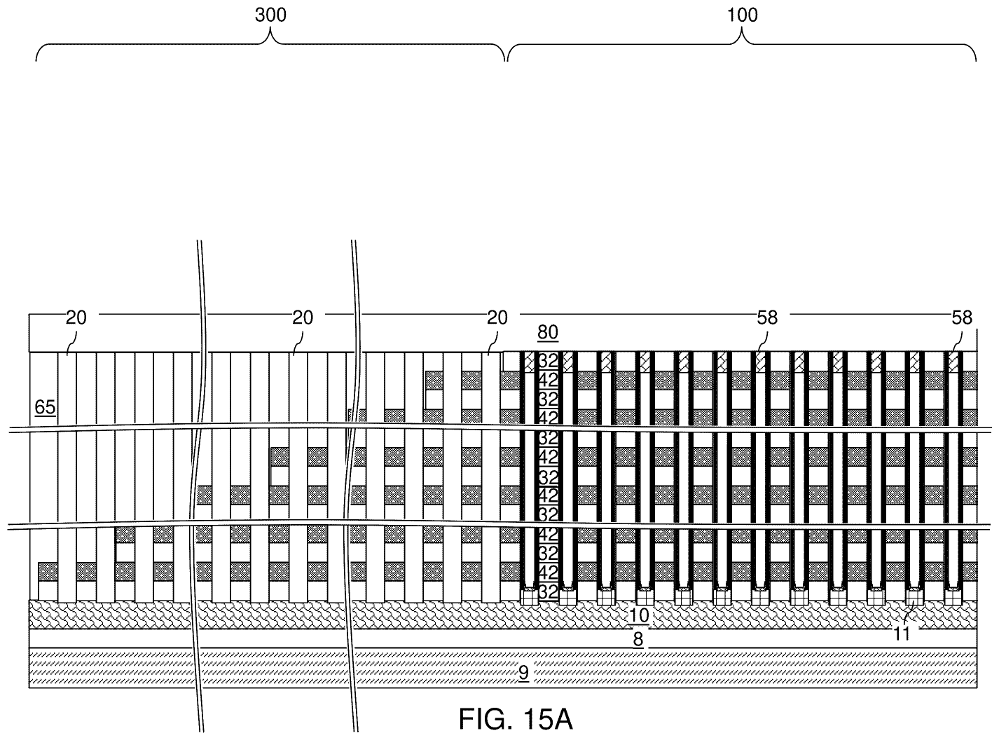

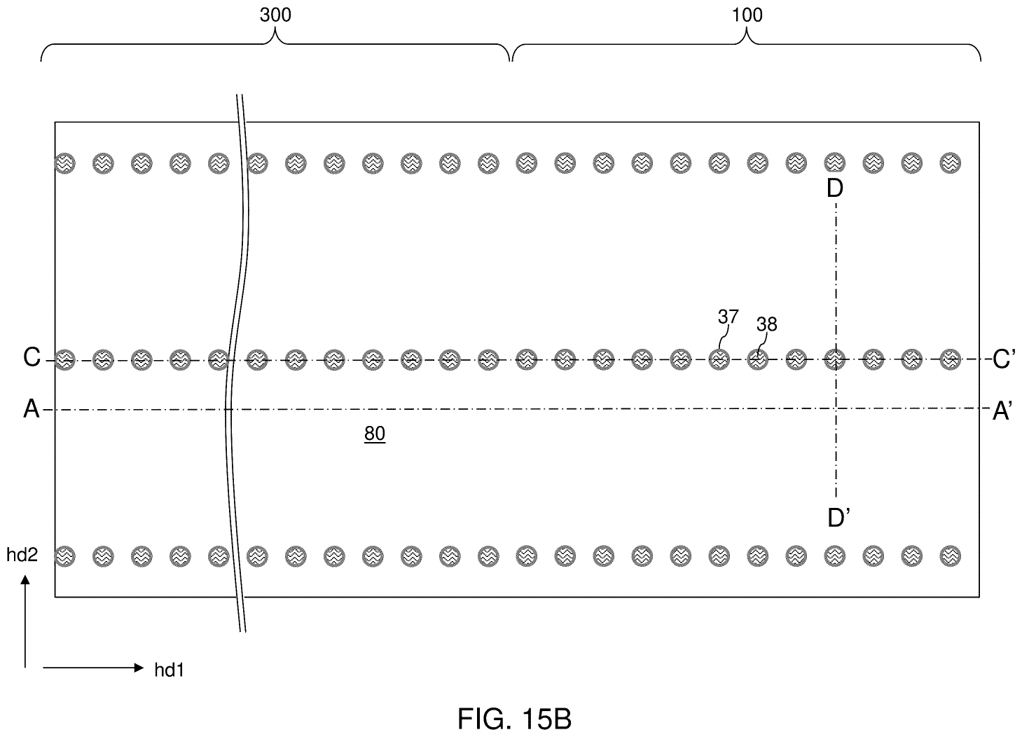

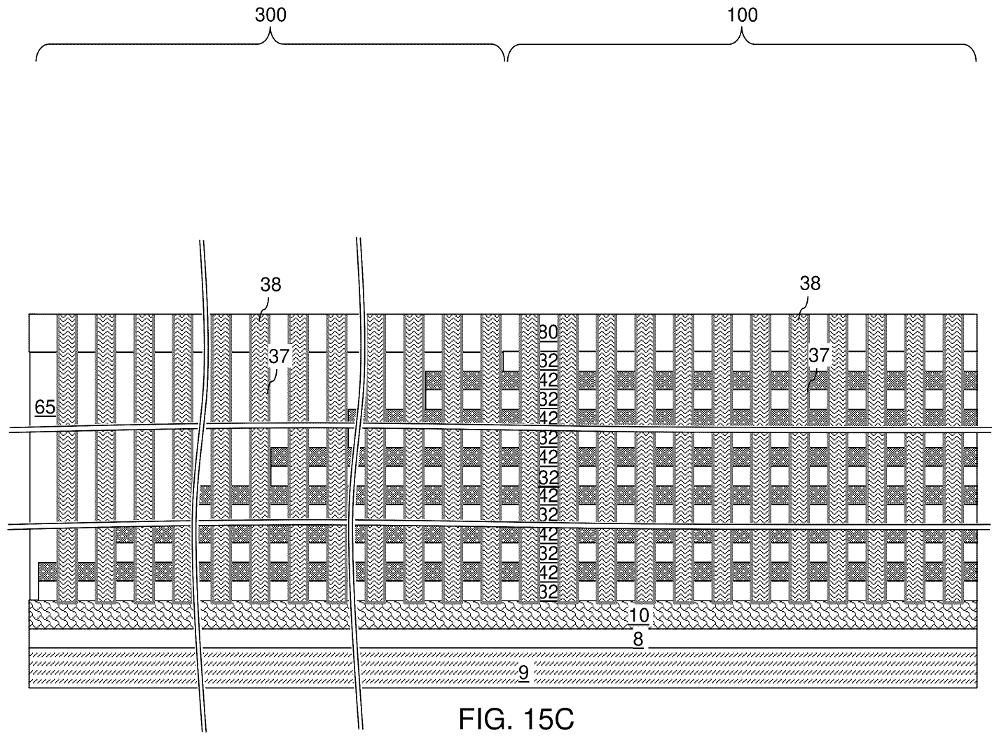

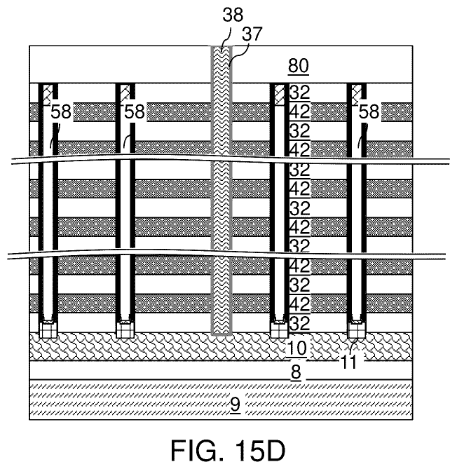

Referring to FIGS. 15A-15D, an optional access opening liner 37 can be deposited by a conformal deposition in each of the inter-tier access openings 39. The access opening liner 37 comprises a dielectric material, such as silicon oxide, and may have a uniform thickness throughout. The thickness of the access opening liner 37 may be in a range from 1 nm to 10 nm, although lesser and greater thicknesses may also be employed. An access opening fill material can be deposited in remaining volumes of the access openings 39. The access opening fill material may comprise carbon (e.g., amorphous carbon or diamond-like carbon), a semiconductor material (e.g., amorphous silicon), organosilicate glass, a polymer material, or any other material that can be subsequently removed selective to the material of the access opening liner 37. A planarization process, such as a chemical mechanical polishing process and/or a recess etch process, can be performed to remove portions of the access opening fill material and the access opening liner 37 from above the horizontal plane including the top surface of the contact-level dielectric layer 80. Each remaining portion of the access opening fill material that remains in a respective one of the inter-tier access openings 39 constitutes an access opening fill material portion 38. Each access opening fill material portion 38 may be laterally surrounded by a respective access opening liner 37. Each contiguous combination of an access opening liner 37 and an access opening fill material portion 38 constitutes an sacrificial access-via-fill structure (37, 38). A row of sacrificial access-via-fill structure (37, 38) may laterally extend through the memory array region 100 between a respective neighboring pair of arrays of memory opening fill structures 58, and may laterally extend through the contact region 300 between a respective neighboring pair of clusters of support pillar structures 20.

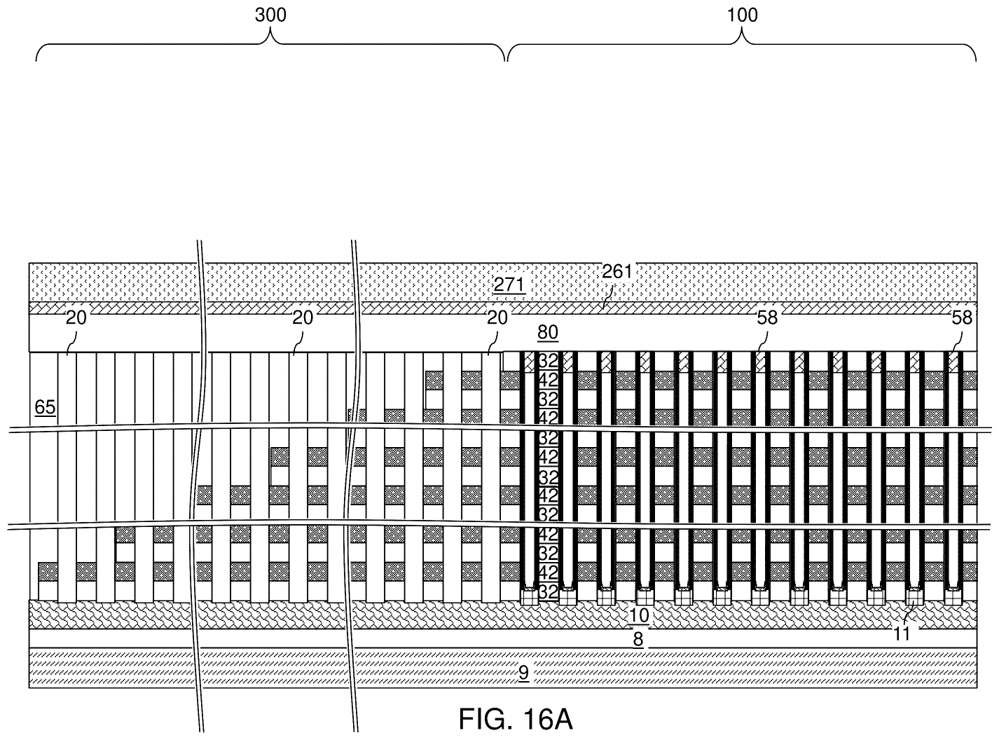

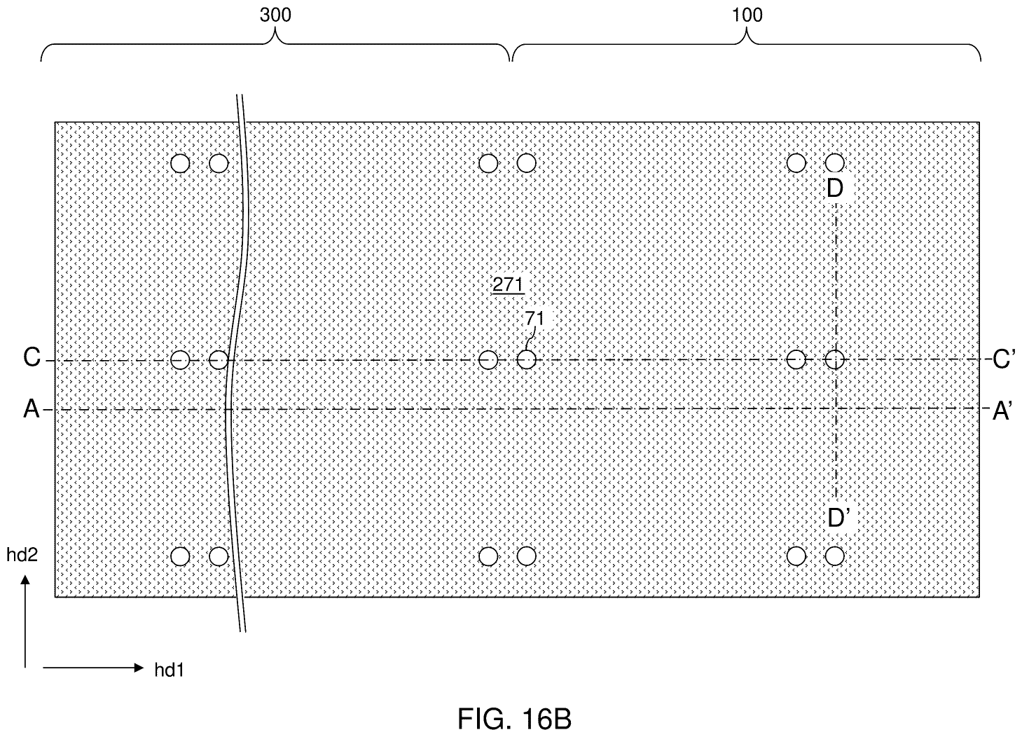

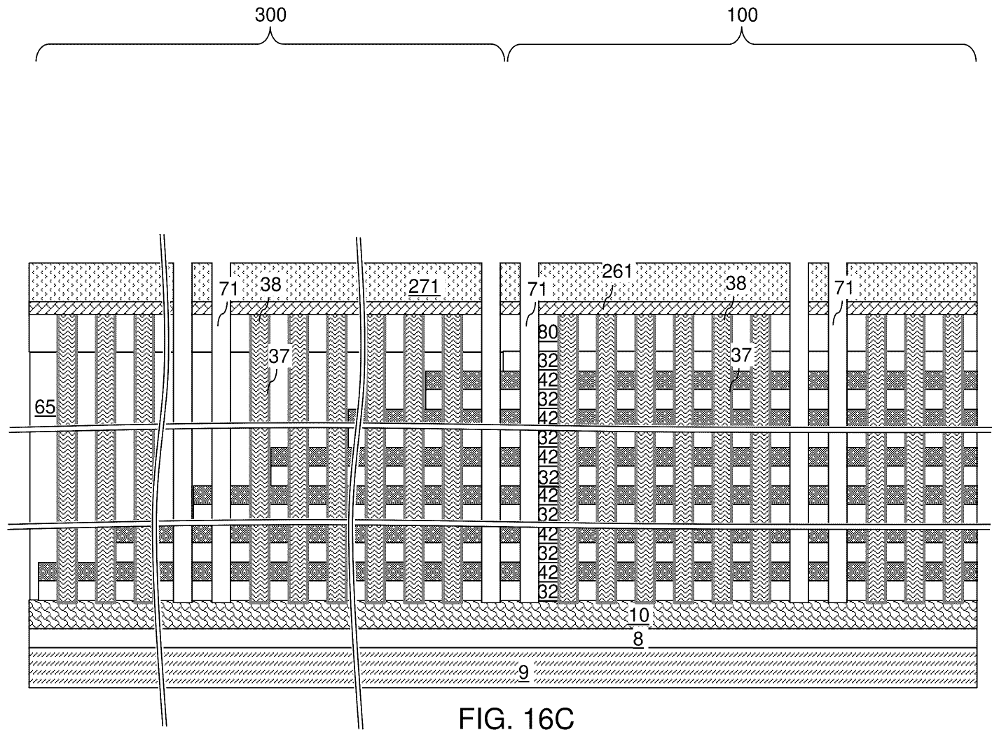

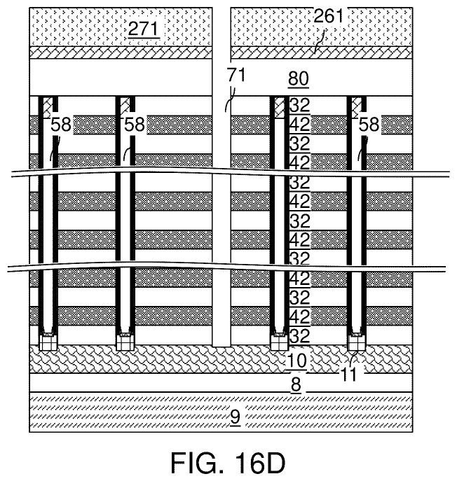

Referring to FIGS. 16A-16D, a first etch mask layer 261 can be formed above the contact-level dielectric layer 80. The first etch mask layer 261 comprises a material that can be subsequently removed selective to materials of the alternating stack (32, 42) and is different from the material of the access opening fill material portion 38. For example, the first etch mask layer 261 may comprise a semiconductor material such as amorphous silicon or polysilicon. The thickness of the first etch mask layer 261 may be in a range from 20 nm to 200 nm, although lesser and greater thicknesses may also be employed. A first photoresist layer 271 can be applied over the first etch mask layer 261, and can be lithographically patterned to form openings in areas that overlap with a first subset of the sacrificial access-via-fill structures (37, 38).

According to an aspect of the present disclosure, the openings through the first photoresist layer 271 can overlie a respective set of N consecutive sacrificial access-via-fill structures (37, 38) that are arranged along the first horizontal direction hd1, in which the integer N is greater than 1. In the illustrated example, the integer N is 2. Generally, the integer N may be 2, or an integer greater than 2, such as 3, 4, 5, 6, etc. The openings through the first photoresist layer 271 does not overlie a complementary set of two or more sacrificial access-via-fill structures (37, 38) that do not belong to the set of N consecutive sacrificial access-via-fill structures (37, 38). Thus, the multiple sets of N consecutive sacrificial access-via-fill structures (37, 38) may belong to different rows of consecutive sacrificial access-via-fill structures (37, 38) and may be laterally spaced apart from each other along the second horizontal direction hd2, or may belong to a same row sacrificial access-via-fill structures (37, 38) and may be laterally spaced from each other along the first horizontal direction hd1.

A first anisotropic etch process can be performed to transfer the pattern of the openings in the first photoresist layer 271 through the first etch mask layer 261. A first subset of the sacrificial access-via-fill structures (37, 38) can be physically exposed underneath the openings in the first etch mask layer 261. At least one etch process may be subsequently performed to remove the first subset of the sacrificial access-via-fill structures (37, 38), which underlies the openings through the first etch mask layer 261. First access via cavities 71 are formed in volumes from which the first subset of the sacrificial access-via-fill structures (37, 38) (i.e., the N consecutive sacrificial access-via-fill structures (37, 38)) is removed. The first photoresist layer 271 may be subsequently removed, for example, by ashing.

The first access via cavities 71 vertically extend through the contact-level dielectric layer 80 and the alternating stack (32, 42). The first access via cavities 71 are formed by removal of the first subset of the sacrificial access opening fill structures (37, 38), and are formed in volumes from which a first subset of the sacrificial access opening fill structures (139, 239) are removed.

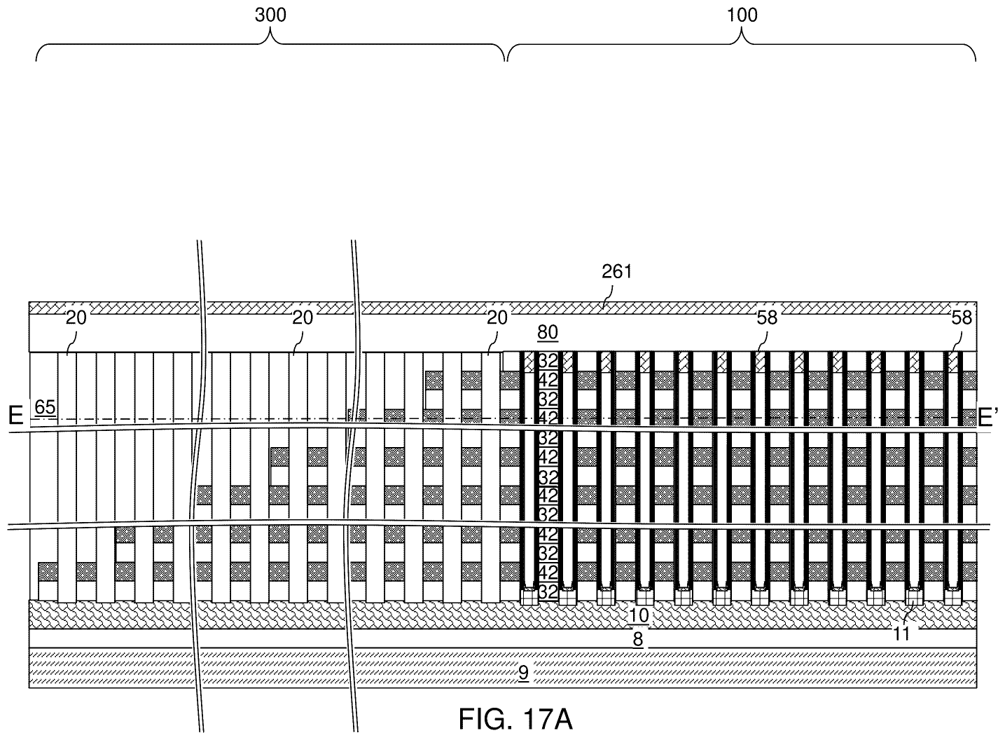

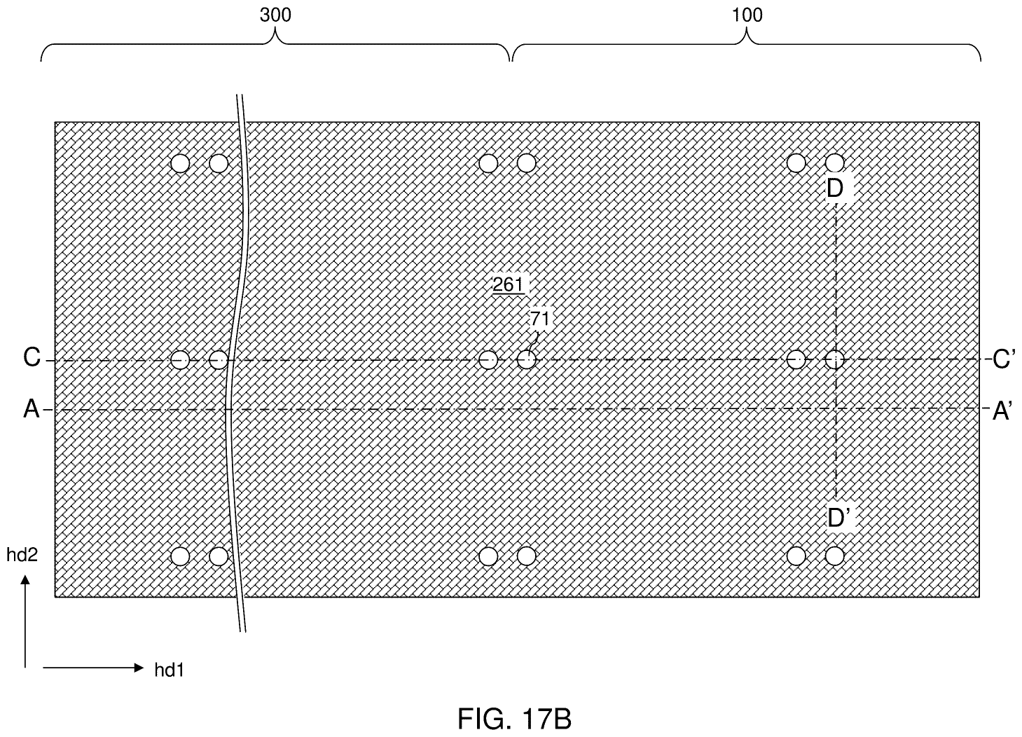

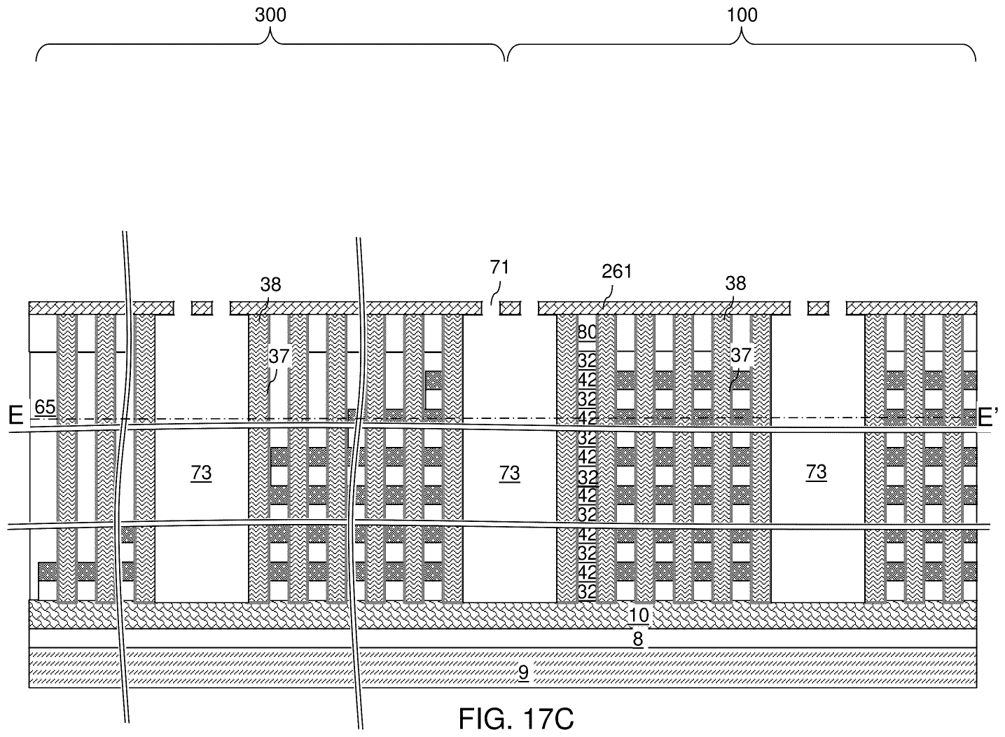

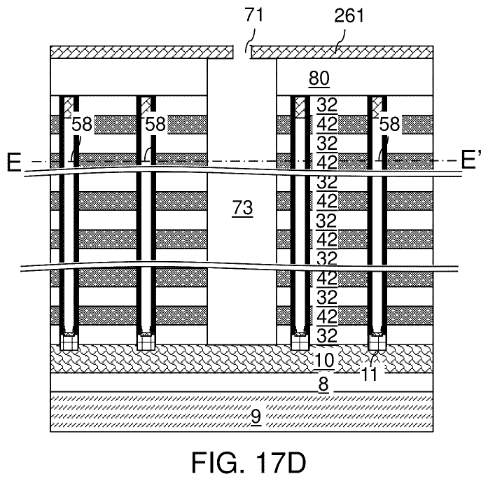

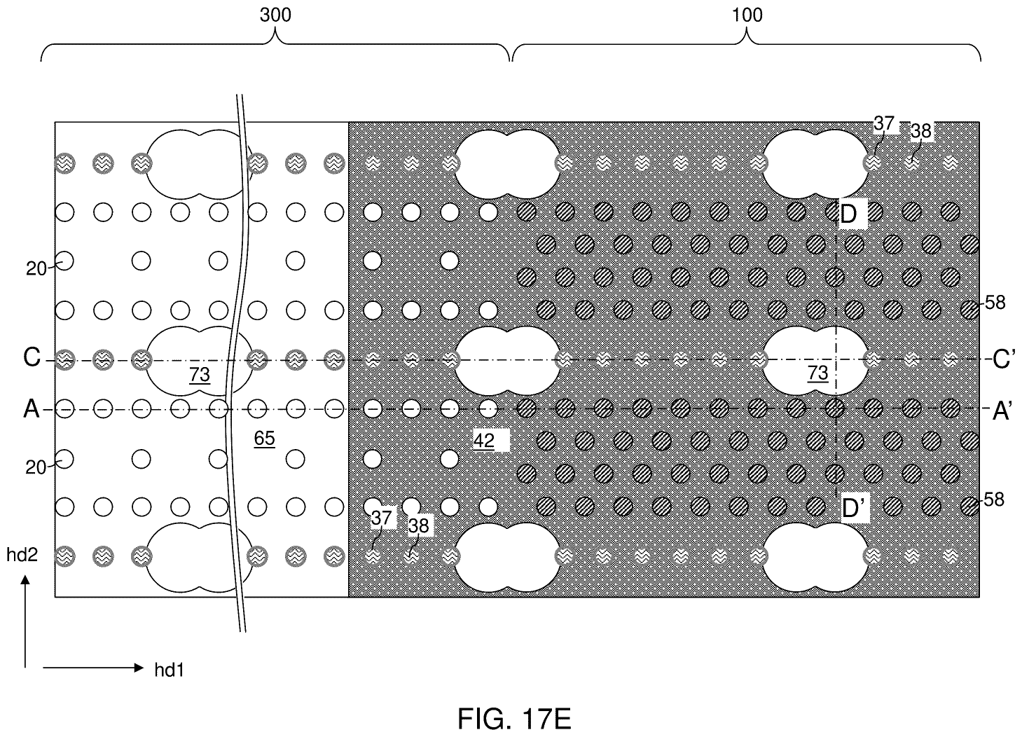

Referring to FIGS. 17A-17E, at least one isotropic etch process can be performed to isotropically laterally expand the first access via cavities 71. For example, an etchant (e.g., dilute hydrofluoric acid) that etches the material of the insulating layers 32 and the sacrificial material layers 42 selective to the patterned first etch mask layer 261 is introduced into the first access via cavities 71. The insulating layers 32 and the sacrificial material layers are etched around each of the first access via cavities 71. The duration of the isotropic etch process can be selected such that the laterally expanded cavities generated from each neighboring set of N first access via cavities 71 merge with each other. Alternatively, separate isotropic etch processes (e.g., dilute hydrofluoric acid and phosphoric acid etch processes) may be used to isotropically etch the insulating layers 32 and the sacrificial material layers 42, respectively.

Generally, the duration of the at least one isotropic etch process can be selected such that each neighboring set of N first access via cavities 71 merge to form a respective continuous cavity having a greater lateral extent than the N first access via cavities 71. Each such merged cavity is herein referred to as a pillar cavity 73. Each pillar cavity 73 vertically extends through the contact-level dielectric layer 80 and the alternating stack (32, 42). Each pillar cavity 73 may optionally contact a respective neighboring pair of sacrificial access opening fill structures (37, 38) within a second subset of the sacrificial access opening fill structures (37, 38) (i.e., a remaining subset of the sacrificial access opening fill structures (37, 38) that is the complementary subset of the first subset of the sacrificial access opening fill structures (37, 38)). In one embodiment shown in FIG. 17E, each pillar cavity 73 may have a respective horizontal cross-sectional shape having a lateral undulation in width along the second horizontal direction (e.g., bit line direction) hd2. In one embodiment, the duration of the at least one isotropic etch process that is employed to form the pillar cavities 73 can be selected such that the pillar cavities 73 do not contact any of the memory opening fill structures 58. In one embodiment, the pillar cavities 73 may be formed in rows that are arranged along the first horizontal direction hd1, and laterally spaced apart along the second horizontal direction hd2. In one embodiment, a two dimensional array of pillar cavities 73 may be provided. In one embodiment, the two-dimensional array of pillar cavities 73 may be a periodic two-dimensional array having a first periodicity along the first horizontal direction hd1 and having a second periodicity along the second horizontal direction hd2. The first etch mask layer 261 can be subsequently removed selective to the materials of the alternating stack (32, 42) and the contact-level dielectric layer 80, for example, by performing an isotropic etch process. For example, a wet etch process employing trimethylaluminum hydroxide (TMAH) or hot trimethyl-2 hydroxyethyl ammonium hydroxide (TMY) may be performed to remove the first etch mask layer 261.

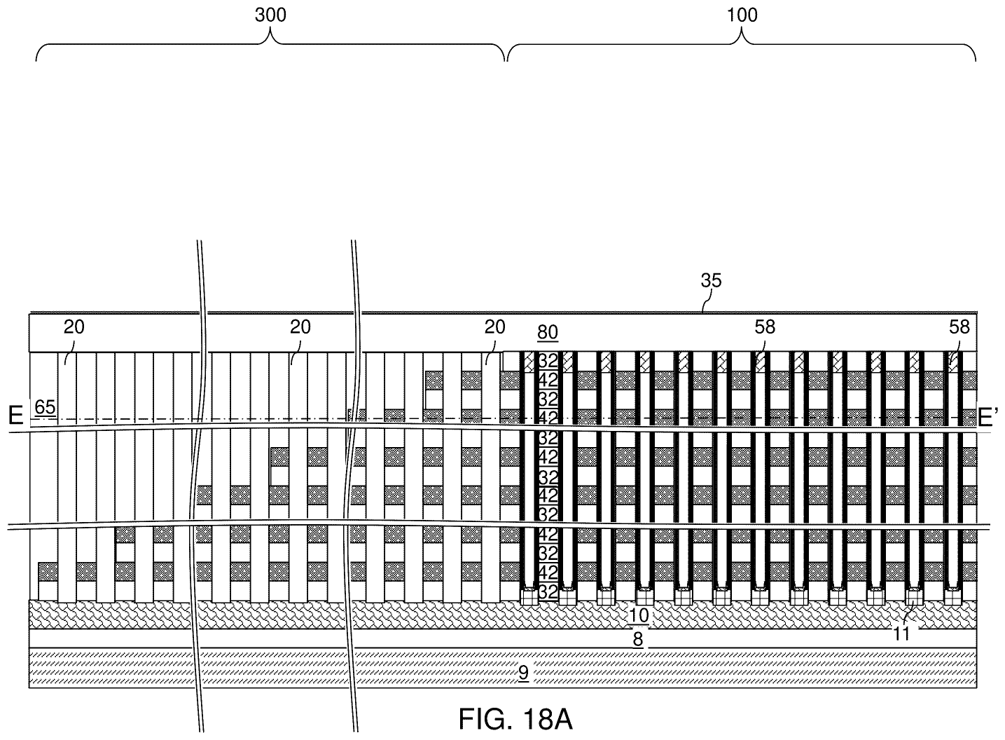

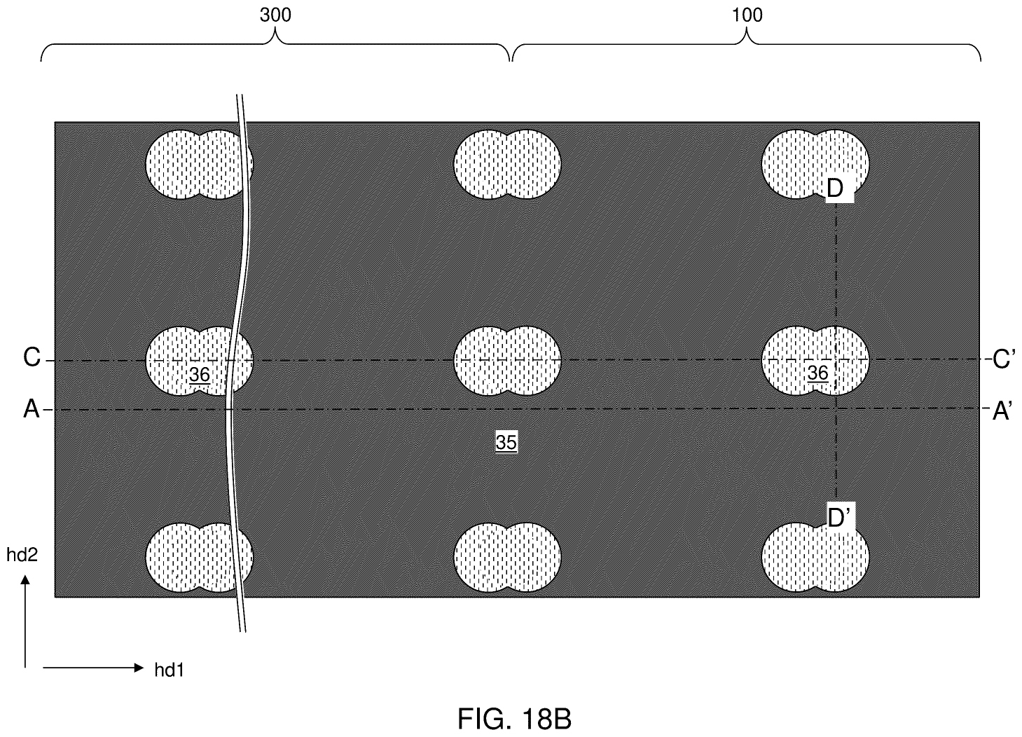

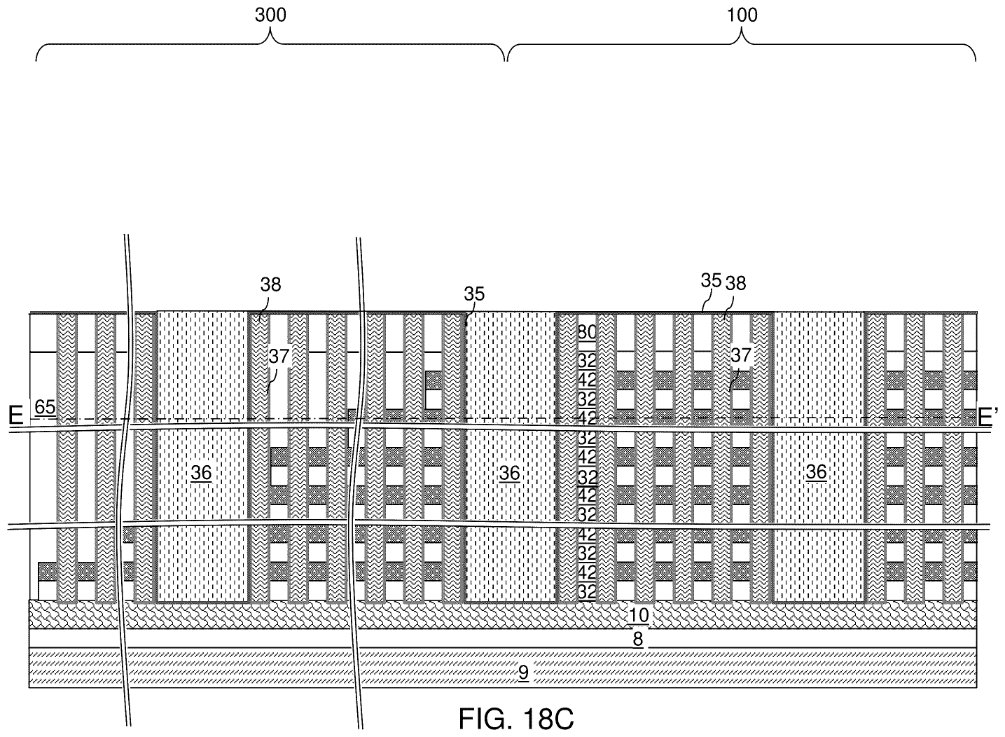

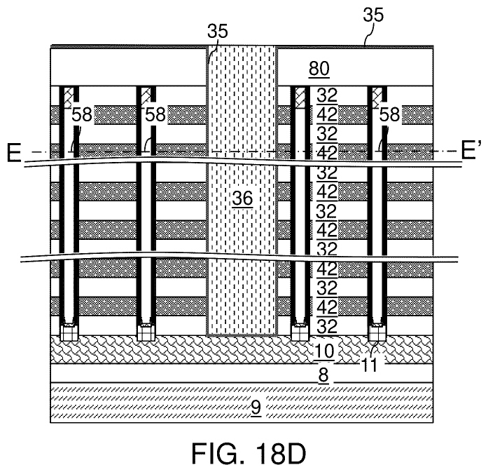

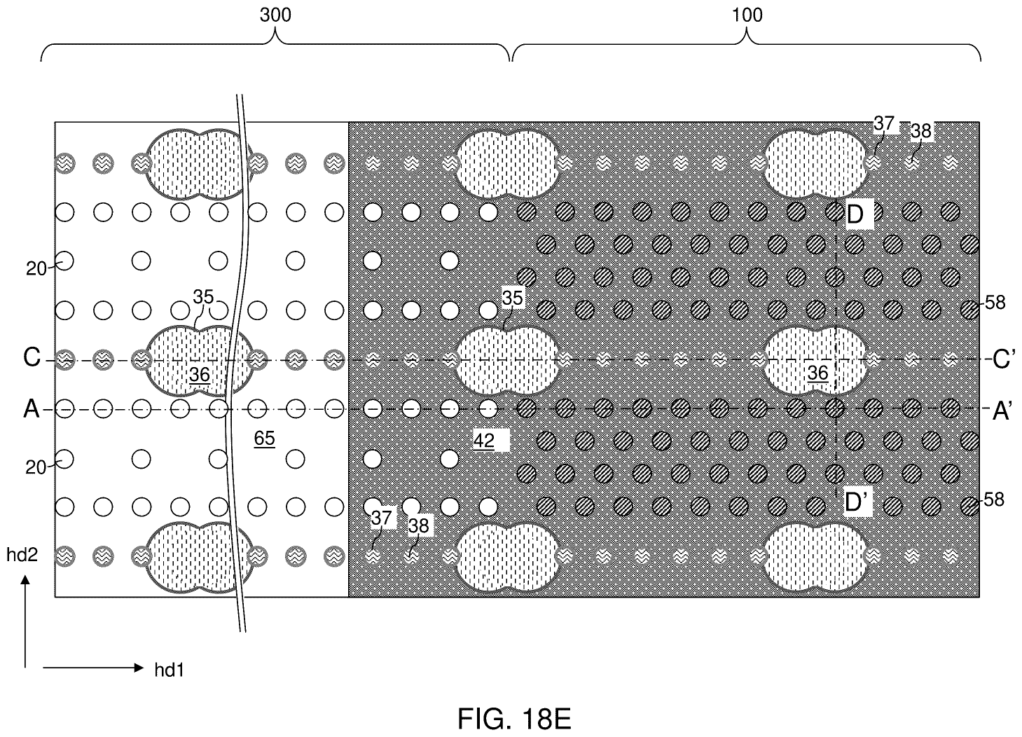

Referring to FIGS. 18A-18E, a dielectric liner 35 can be conformally deposited on the sidewalls of the pillar cavities 73 and on the top surface of the contact-level dielectric layer 80. The dielectric liner 35 comprises a dielectric material such as silicon oxide, and may have a thickness in a range from 3 nm to 60 nm, such as from 6 nm to 30 nm, although lesser and greater thicknesses may also be employed.

A sacrificial fill material can be deposited in remaining volumes of the pillar cavities 73. The sacrificial fill material comprises a material that can be removed selective to the material of the dielectric liner 35. In an illustrative example, the sacrificial fill material may comprise a carbon-based material such as amorphous carbon or diamond-like carbon (DLC). A planarization process, such as an etch back or a chemical mechanical polishing (CMP) process, can be performed to remove portions of the sacrificial fill material from above the horizontal plane including a topmost surface of the dielectric liner 35. Each remaining portion of the sacrificial fill material constitutes a sacrificial material portion having a shape of a pillar, and is hereafter referred to as a sacrificial pillar structure 36. Rows of sacrificial pillar structures 36 can be provided in the exemplary structure. In one embodiment, the rows of sacrificial pillar structures 36 may be arranged as a two-dimensional array of sacrificial pillar structures 36. In one embodiment, the two-dimensional array of sacrificial pillar structures 36 may be a periodic two-dimensional array of sacrificial pillar structures 36 having the first periodicity along the first horizontal direction hd1 and having the second periodicity along the second horizontal direction hd2.

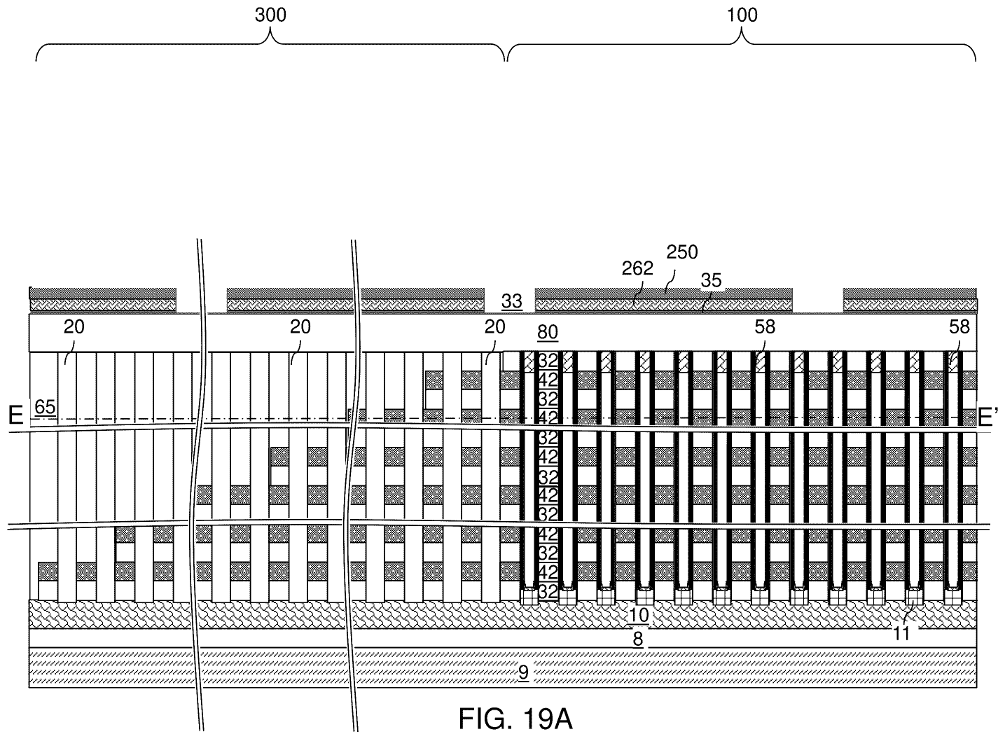

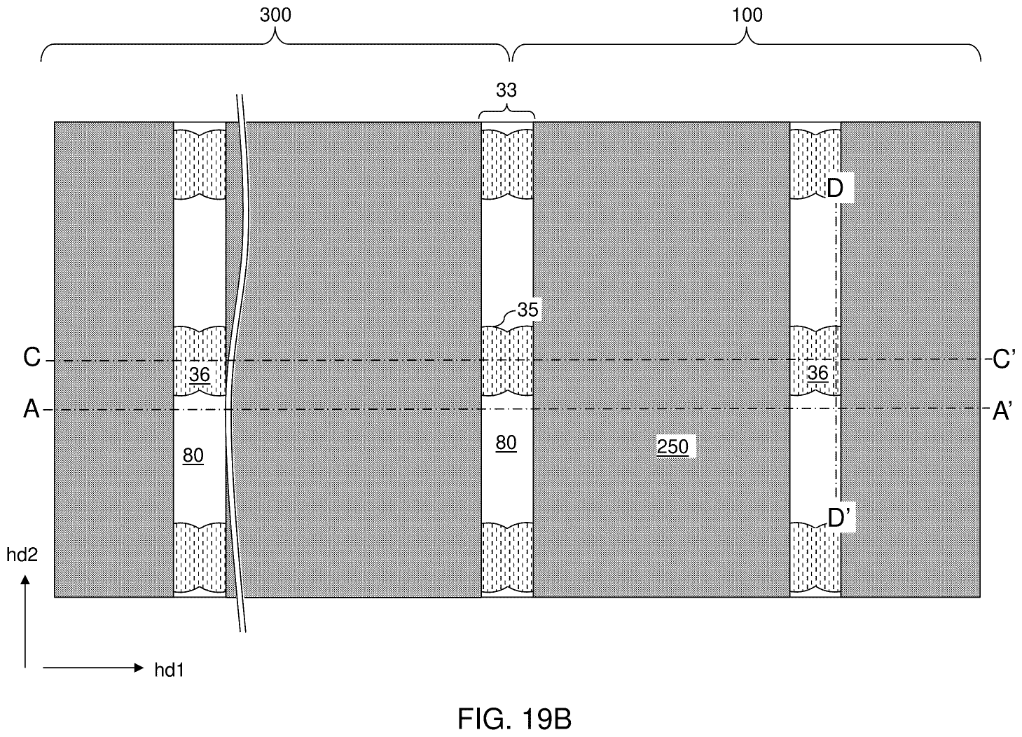

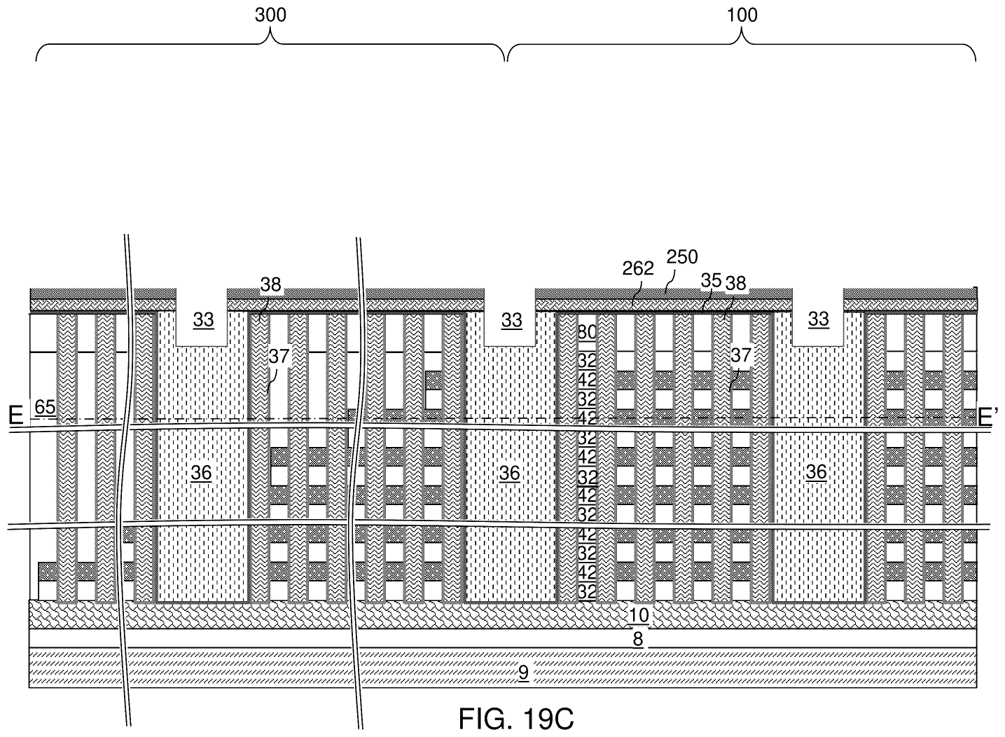

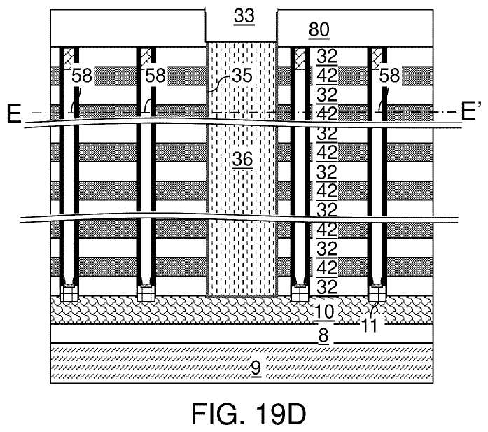

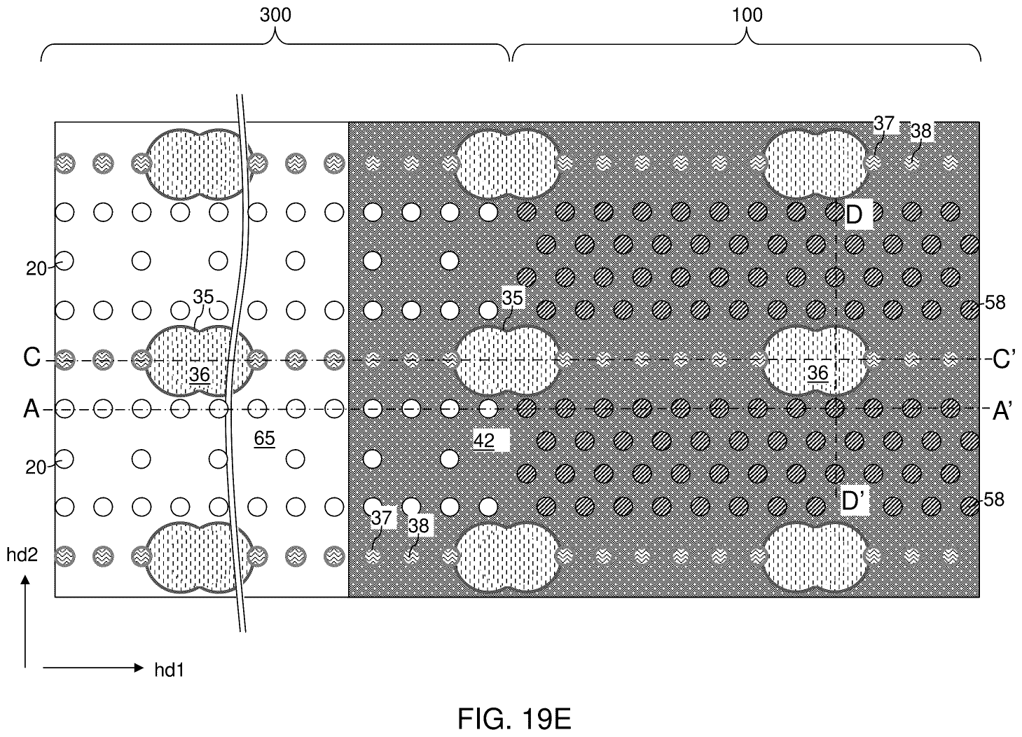

Referring to FIGS. 19A-19E, a second etch mask layer 262, a hard mask layer 250, and a second photoresist layer (not shown) can be applied over the contact-level dielectric layer 80. The second etch mask layer 262 may comprise amorphous silicon and the hard mask layer 250 may comprise silicon nitride. Other materials may also be used. The second photoresist layer can be lithographically patterned with elongated openings that laterally extend along the second horizontal direction hd2 and are laterally spaced apart from each other along the first horizontal direction hd1. In one embodiment, each of the elongated openings in the second photoresist layer may have a uniform width along the first horizontal direction hd1 that is less than the lateral extent of each of the sacrificial pillar structures 36 along the first horizontal direction hd1. In one embodiment, each of the elongated openings in the second photoresist layer may overlie a respective column of sacrificial pillar structures 36 within a two-dimensional array of sacrificial pillar structures 36, which may be a rectangular periodic array of sacrificial pillar structures 36 having the first periodicity along the first horizontal direction hd1 and having the second periodicity along the second horizontal direction hd2. The elongated opening in the second photoresist layer may be arranged as a one-dimensional periodic array of elongated openings having the first periodicity along the first horizontal direction hd1.

An anisotropic etch process can be performed to etch portions of the hard mask layer 250 that are not masked by the second photoresist layer 272. The anisotropic etch process may comprise a first anisotropic etch step that etches unmasked portions of the hard mask layer 250 to form slit-shaped openings (i.e., elongated openings) that laterally extend along the second horizontal direction hd2 over a respective column of the sacrificial pillar structures 36. The second photoresist layer is then removed by ashing.

A second anisotropic etch step that etches unmasked portions of the second etch mask layer 262, and a third anisotropic etch process that etches an upper portion of each of the sacrificial pillar structures 36 that are not masked by the patterned hard mask layer 250 selective to the material(s) of the dielectric liner 35 and/or the contact-level dielectric layer 80. The patterned hard mask layer 250 and the patterned second etch mask layer 262 comprise slit-shaped openings (i.e., elongated openings) that laterally extend along the second horizontal direction hd2 over a respective column of the sacrificial pillar structures 36. A center portion of each of the sacrificial pillar structures 36 is not covered by the patterned second etch mask layer 262, and peripheral portions of each of the sacrificial pillar structures 36 is covered by the patterned second etch mask layer 262.

The third anisotropic etch step vertically recesses portions of the sacrificial pillar structures 36 that are not masked by the patterned second etch mask layer 262. Recess regions 33 are formed in volumes from which the material of the sacrificial pillar structures 36 is removed. The depth of the recess regions 33 may be not greater than the thickness of the contact-level dielectric layer 80. Generally, the bottom surfaces of the recess regions 33 can be formed at, or above, the horizontal plane including the bottom surface of the contact-level dielectric layer 80. The recess regions 33 comprise slit-shaped trenches that laterally extend along the second horizontal direction hd2 partially through the respective column of the sacrificial pillar structures 36, as shown in FIGS. 19C and 19D.

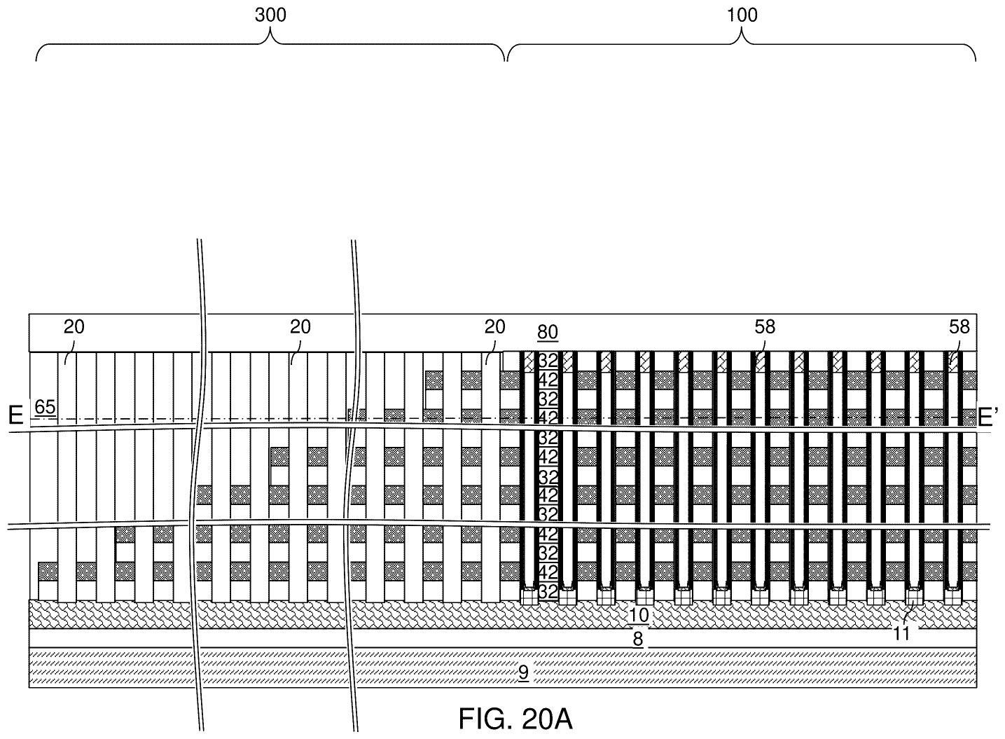

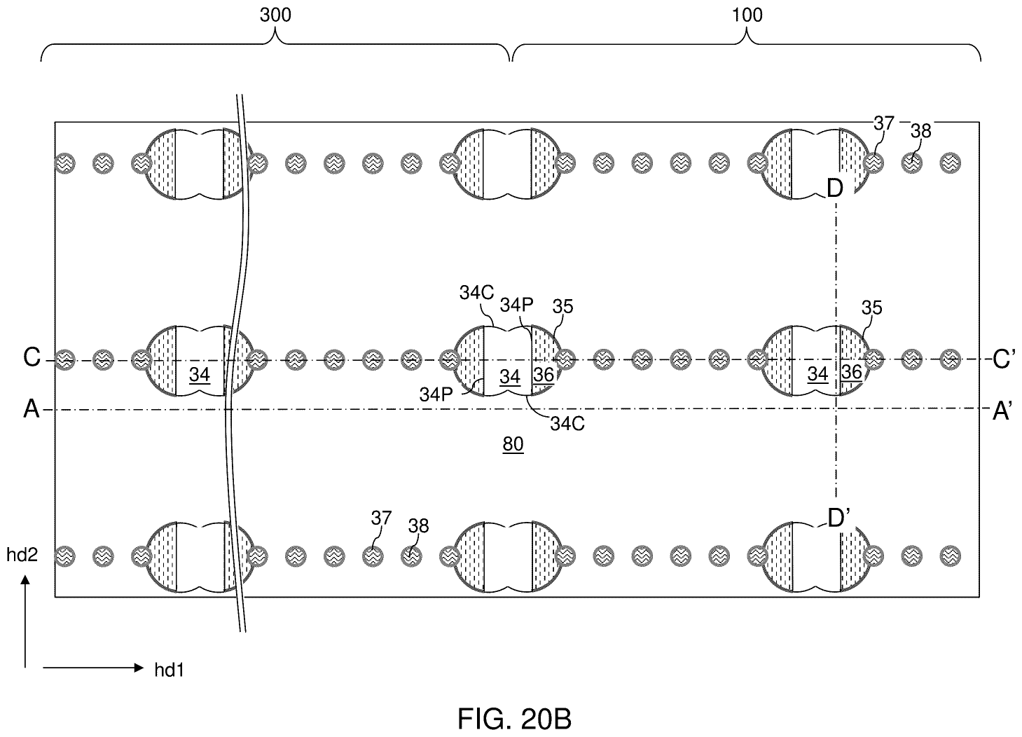

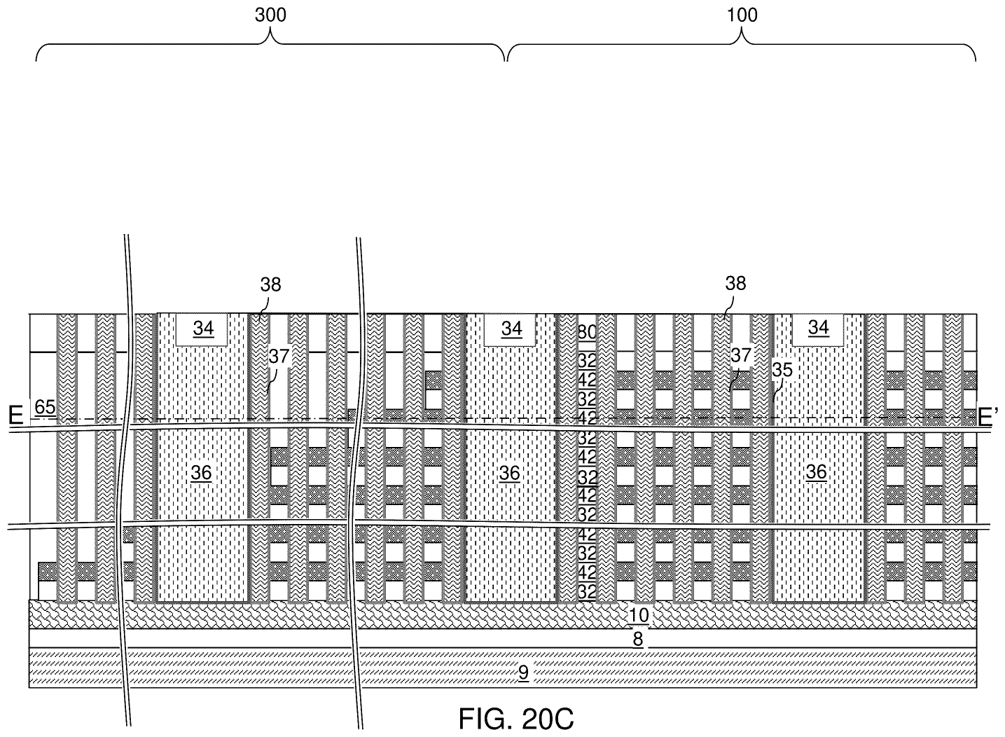

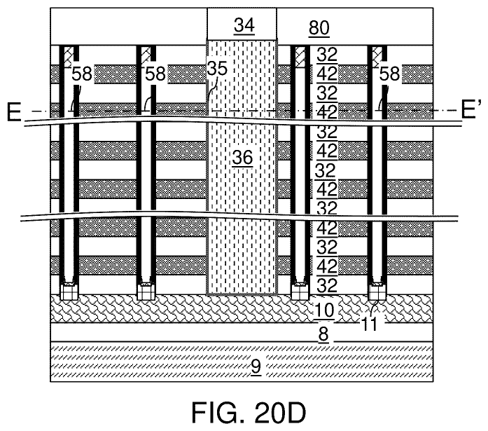

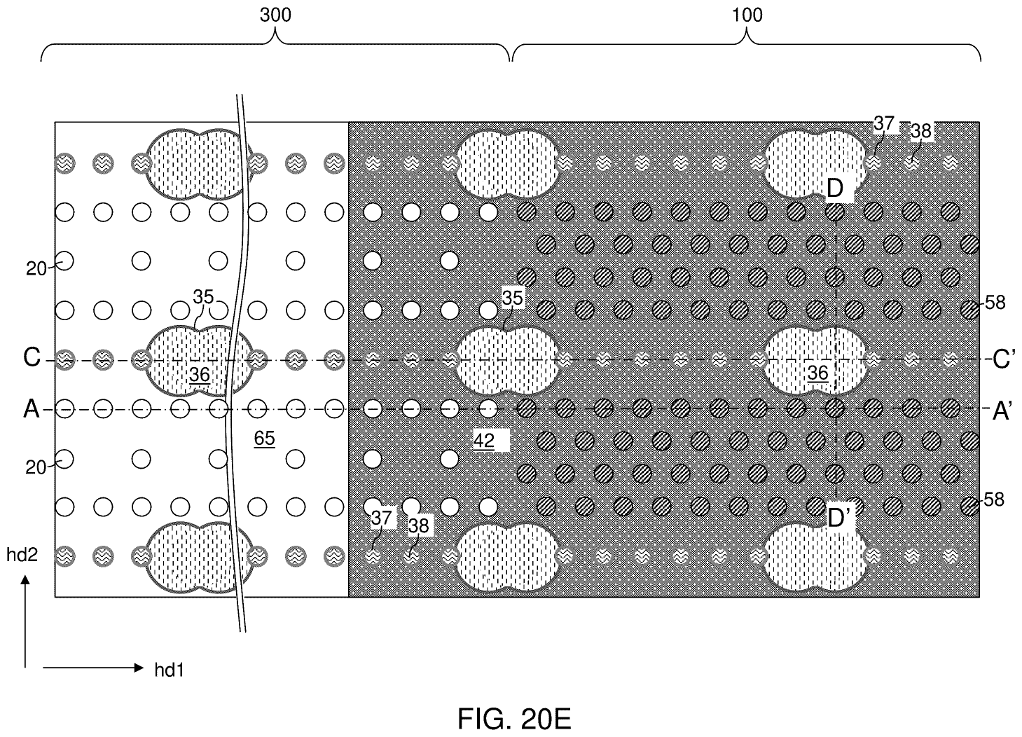

Referring to FIGS. 20A-20E, a dielectric material, such as silicon oxide, can be deposited in the recess regions 33. A planarization process can be performed to remove portions of the dielectric material overlying the top surface of the hard mask layer 250. The planarization process may comprise a chemical mechanical polishing (CMP) process or a recess etch process. Subsequently, top surfaces of remaining portions of the dielectric material can be vertically recessed to the level at or about the horizontal plane including the top surface of the contact-level dielectric layer 80. Each remaining portion of the dielectric material filling a respective one of the recess regions 33 constitutes a dielectric bridge structure 34. The hard mask layer 250 and the second etch mask layer 262 can be subsequently removed by etching selective to the materials of the contact-level dielectric layer 80, the dielectric bridge structures 34, and the sacrificial pillar structures 36.

Generally, the recess regions 33 can be formed by anisotropically etching unmasked portions of the sacrificial pillar structures 36 while a patterned etch mask layer (such as the patterned second etch mask layer 250) is present over the contact-level dielectric layer. The dielectric bridge structures 34 are formed in the recess regions 33 within upper portions of the sacrificial pillar structures 36.

In one embodiment, each of the dielectric bridge structures 34 comprises a respective pair of contoured sidewalls 34C that generally extend along the first horizontal direction hd1 and have lateral undulations along the second horizontal direction hd2, as shown in FIG. 20B. Each pair of contoured sidewalls 34C may comprise laterally-convex sidewall segments that are adjoined to each other at one or more vertically-extending edges. As used herein, a “laterally-convex sidewall segment” refers to a sidewall segment having a convex profile in a horizontal cross-sectional view. Each of the dielectric bridge structures 34 also comprises a respective pair of planar vertical sidewalls 34P that are adjoined to the respective pair of contoured sidewalls 34C and are parallel to the second horizontal direction hd2, as shown in FIG. 20B.

In one embodiment, each of the dielectric bridge structures 34 comprises a respective horizontal bottom surface located at or above a horizontal plane including top surfaces of the alternating stack (32, 42), as shown in FIG. 20C. In one embodiment, each of the dielectric bridge structures 34 may comprise a respective top surface located within a horizontal plane including top surfaces of the contact-level dielectric layers 80, as shown in FIG. 20C. Each of the sacrificial pillar structures 36 may be laterally spaced from the alternating stack (32, 42) and/or the stepped dielectric material portions 65 by a respective dielectric liner 35.

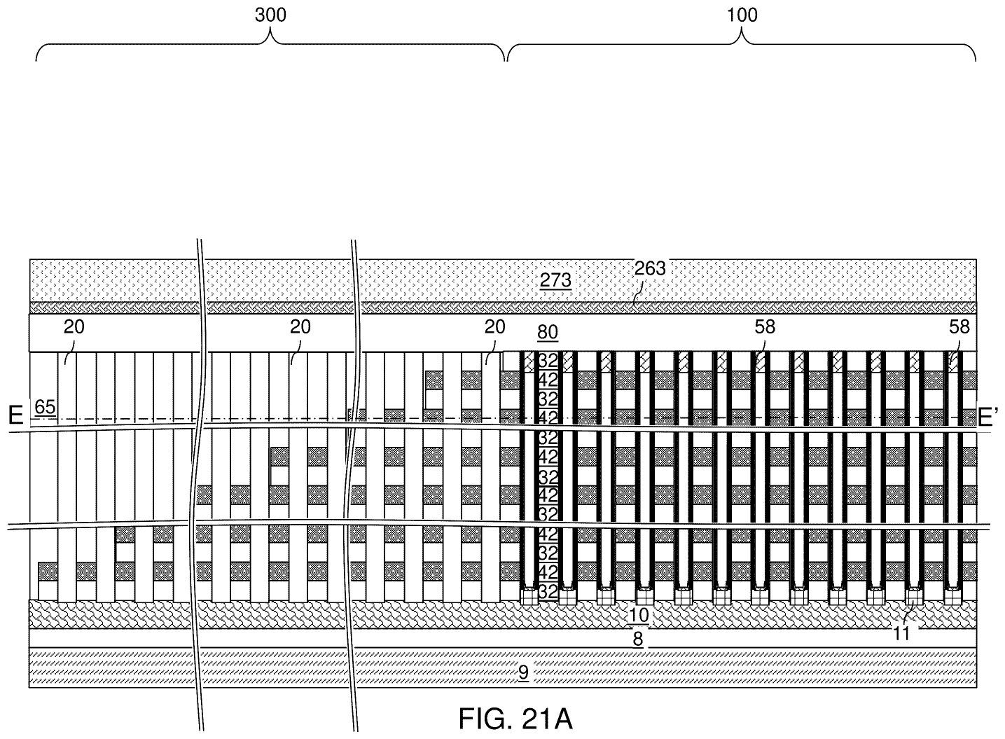

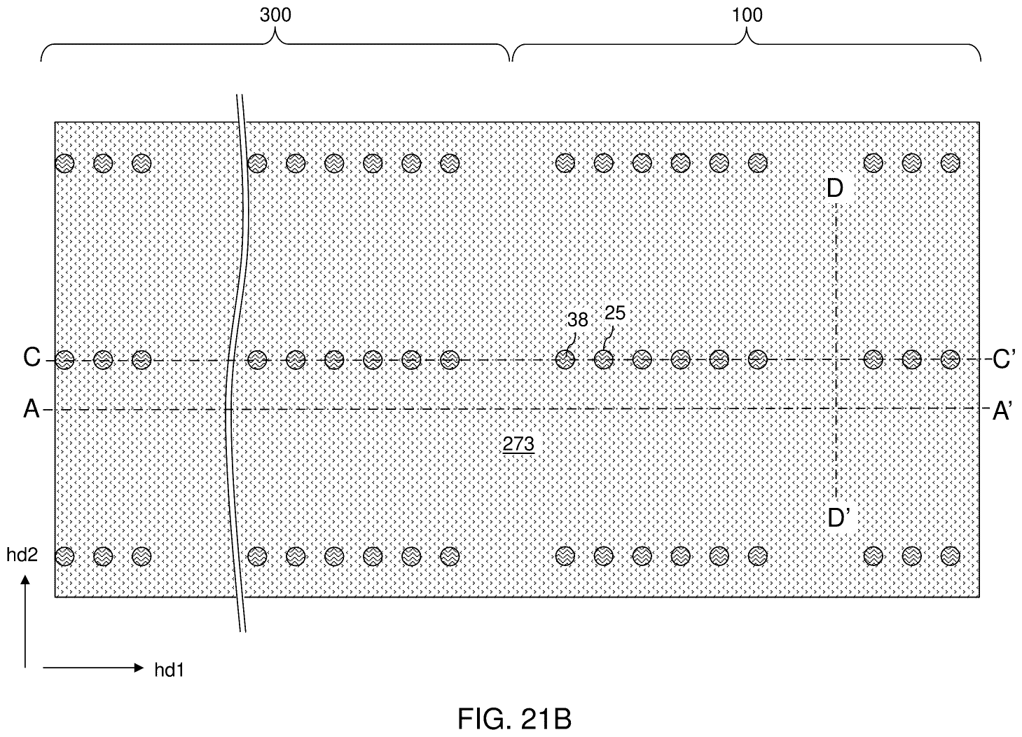

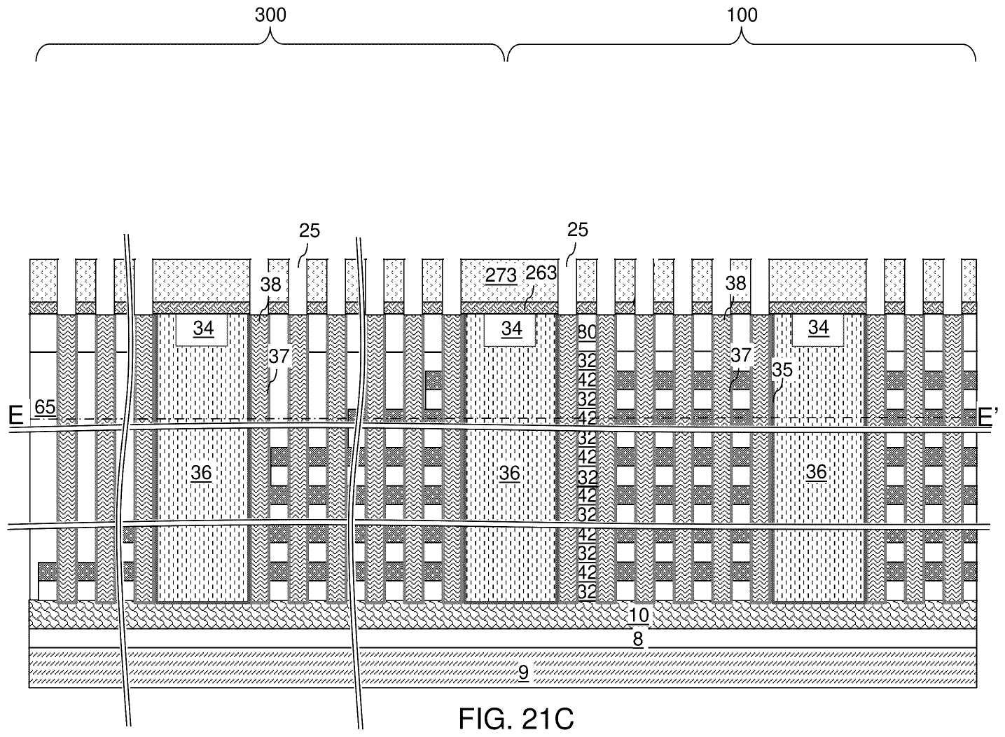

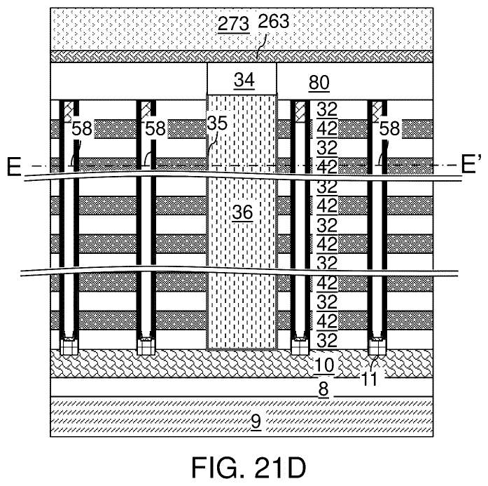

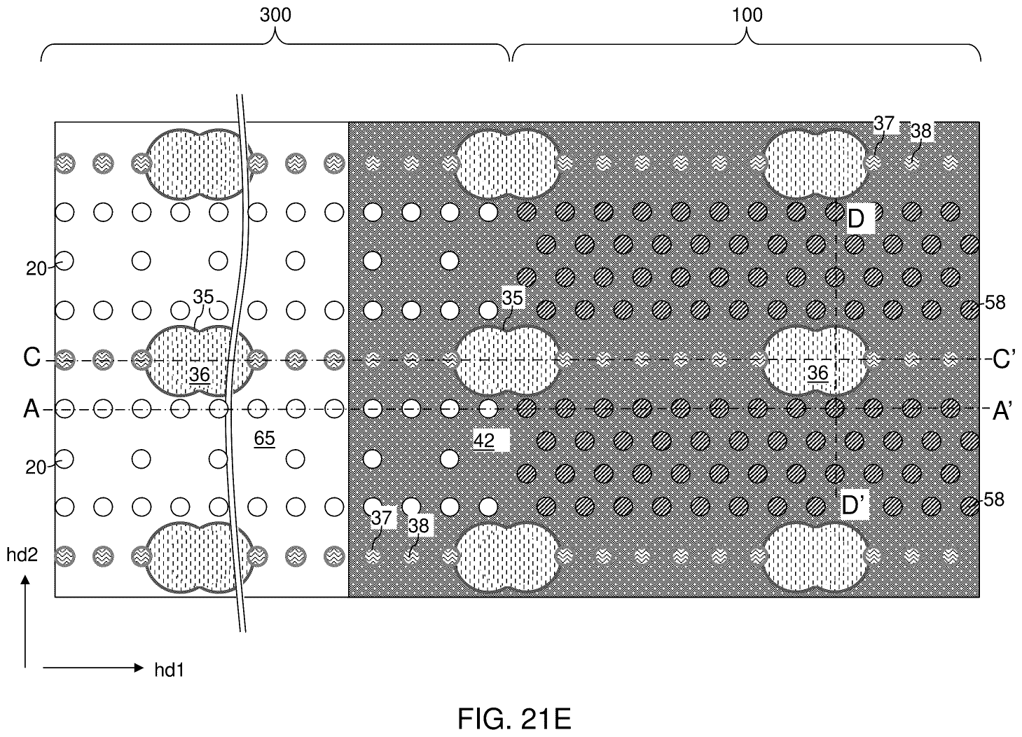

Referring to FIGS. 21A-21E, a third etch mask layer 263 and a third photoresist layer 273 can be formed over the contact-level dielectric layer 80. The third etch mask layer 263 comprises an etch mask material, such as amorphous silicon or polysilicon. The thickness of the third etch mask layer 263 may be in a range from 30 nm to 300 nm, although lesser and greater thicknesses may also be employed. The third photoresist layer 273 can be lithographically patterned to form openings 25 over the areas of the second subset of the sacrificial access-via-fill structures (37, 38), i.e., the remaining subset of the sacrificial access-via-fill structures (37, 38) that is not removed at the processing steps described with reference to FIGS. 16A-16D. The third photoresist layer 273 may cover the areas of the sacrificial pillar structures 36. An anisotropic etch process can be performed to transfer the pattern of the openings 25 in the third photoresist layer 273 through the third etch mask layer 262. Top surfaces of the second subset of the sacrificial access-via-fill structures (37, 38) can be physically exposed underneath the openings 25 in the third etch mask layer 262.

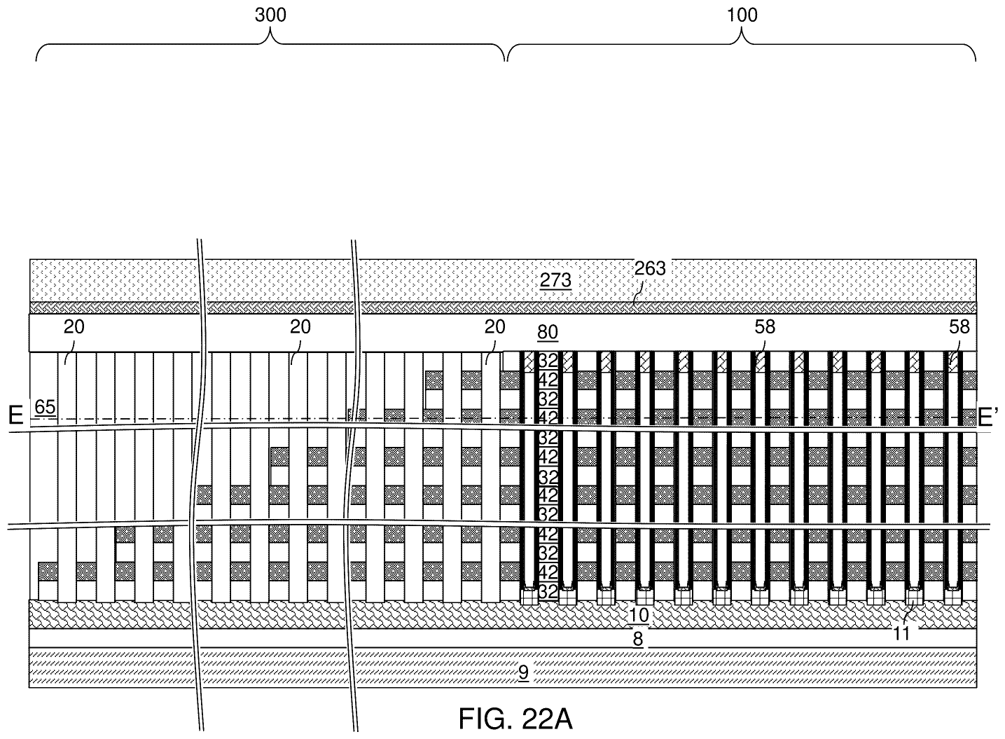

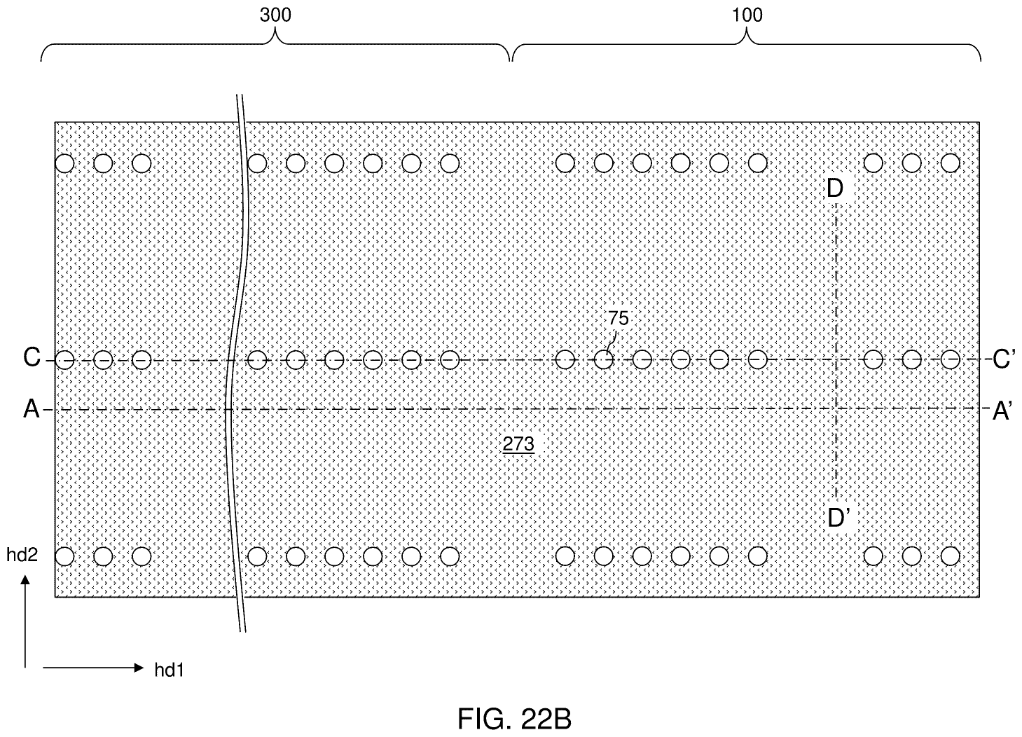

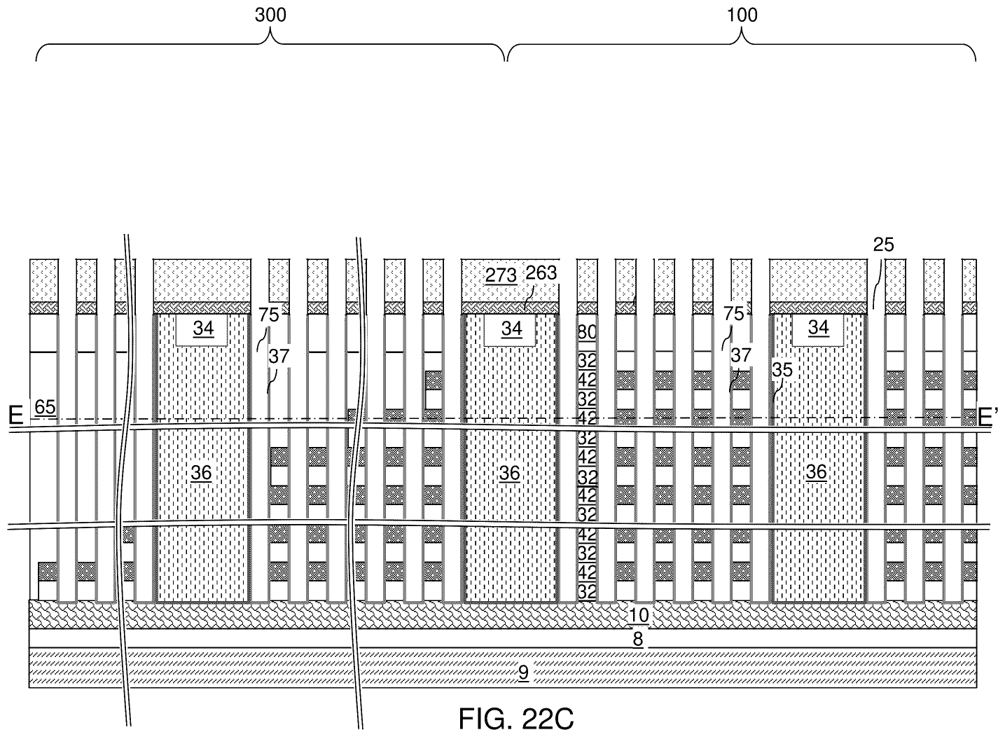

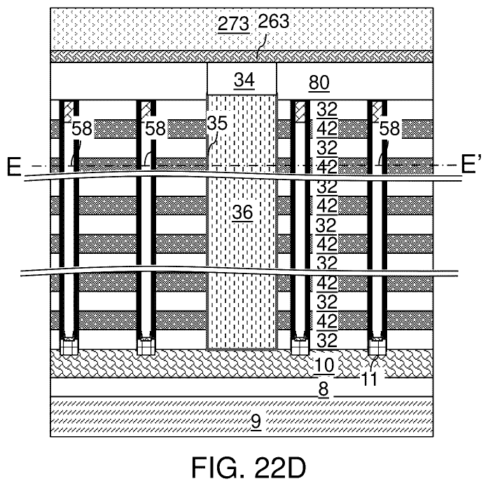

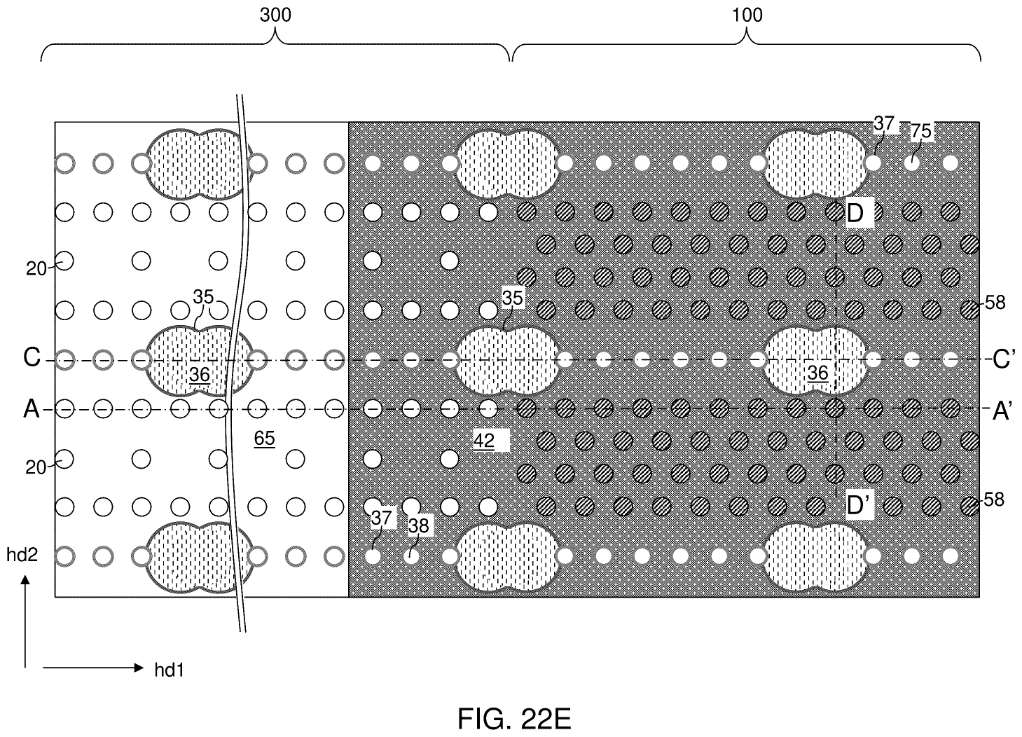

Referring to FIGS. 22A-22E, at least one etch process may be subsequently performed to remove the second subset of the sacrificial access-via-fill structures (37, 38), which underlies the openings through the third etch mask layer 263. Second access via cavities 75 are formed in volumes from which the second subset of the sacrificial access-via-fill structures (37, 38) is removed. The second access via cavities 75 vertically extend through the contact-level dielectric layer 80 and the alternating stack (32, 42). The second access via cavities 75 are formed by removal of the second subset of the sacrificial access opening fill structures (37, 38), and are formed in volumes from which a second subset of the sacrificial access opening fill structures (139, 239) are removed. The third photoresist layer 273 may be subsequently removed, for example, by ashing.

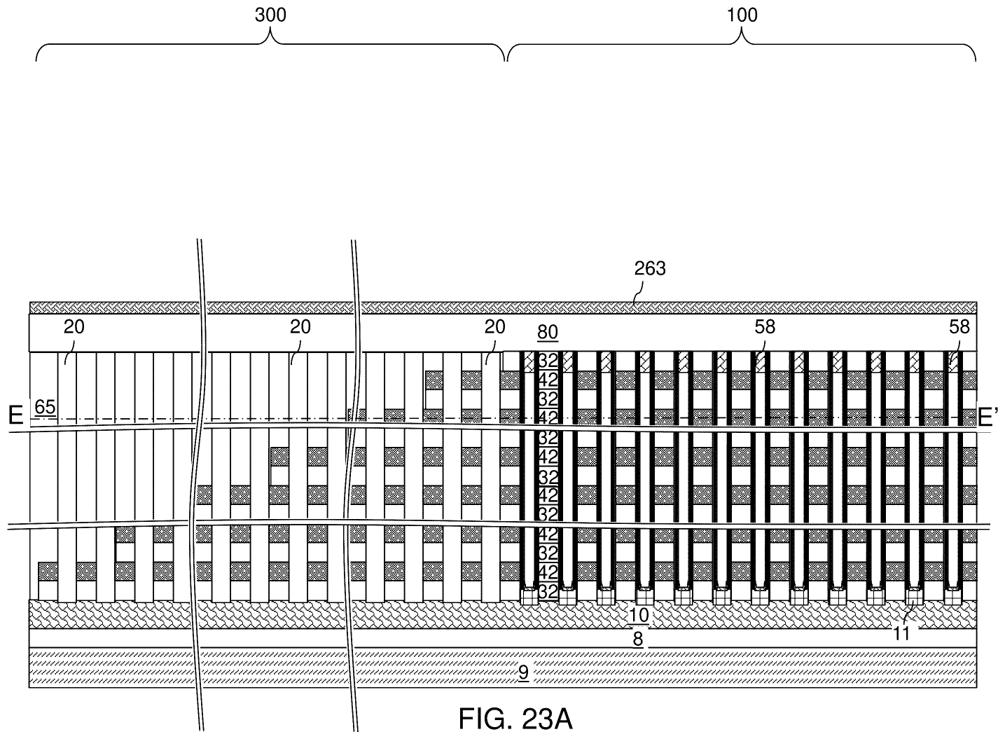

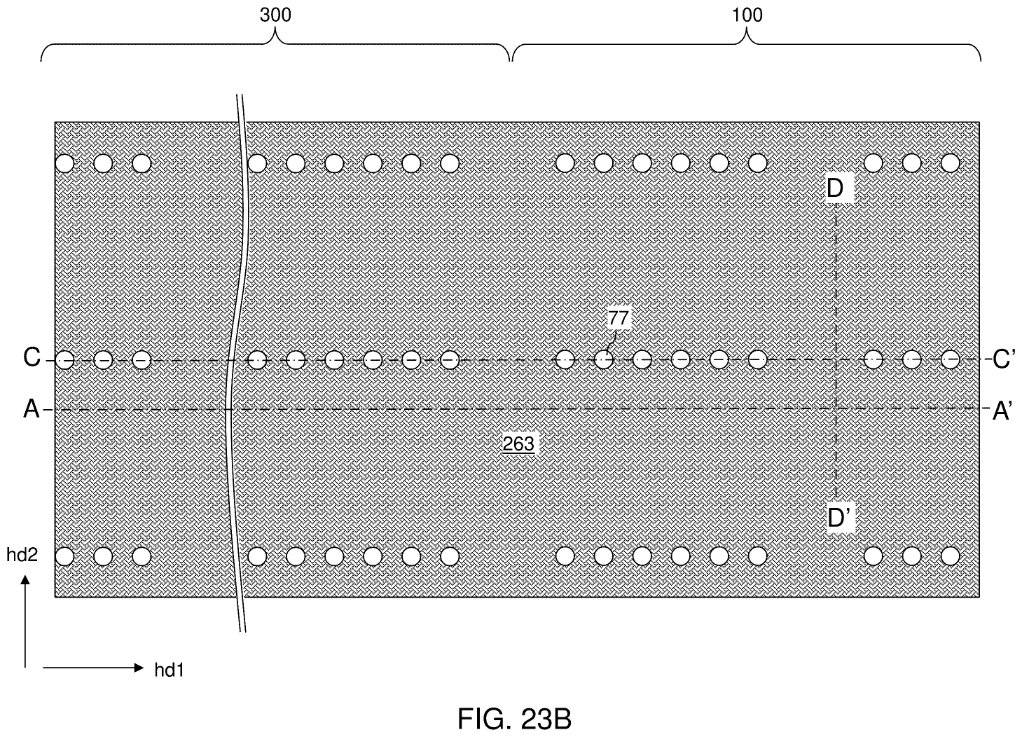

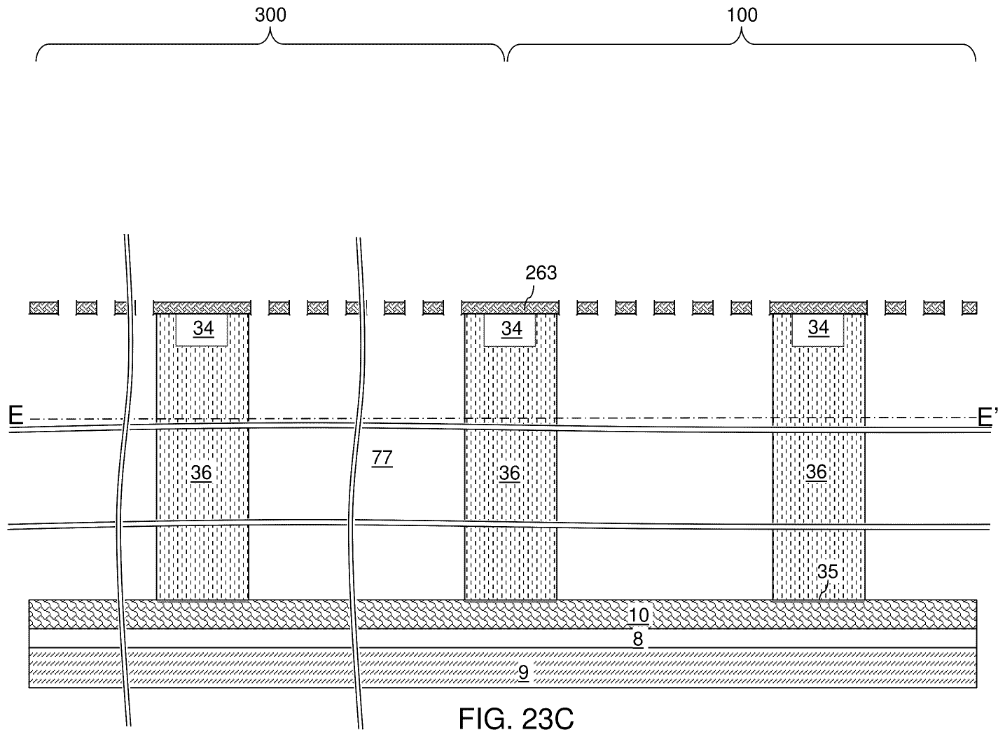

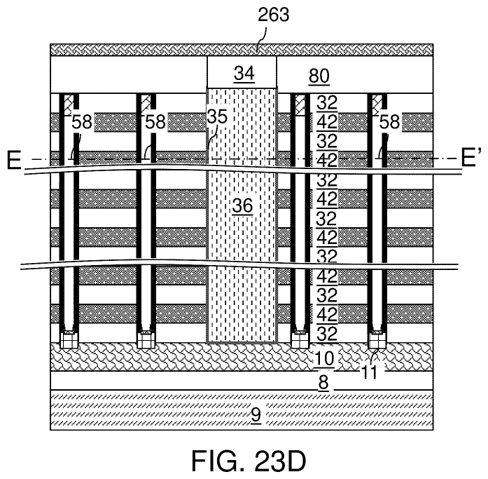

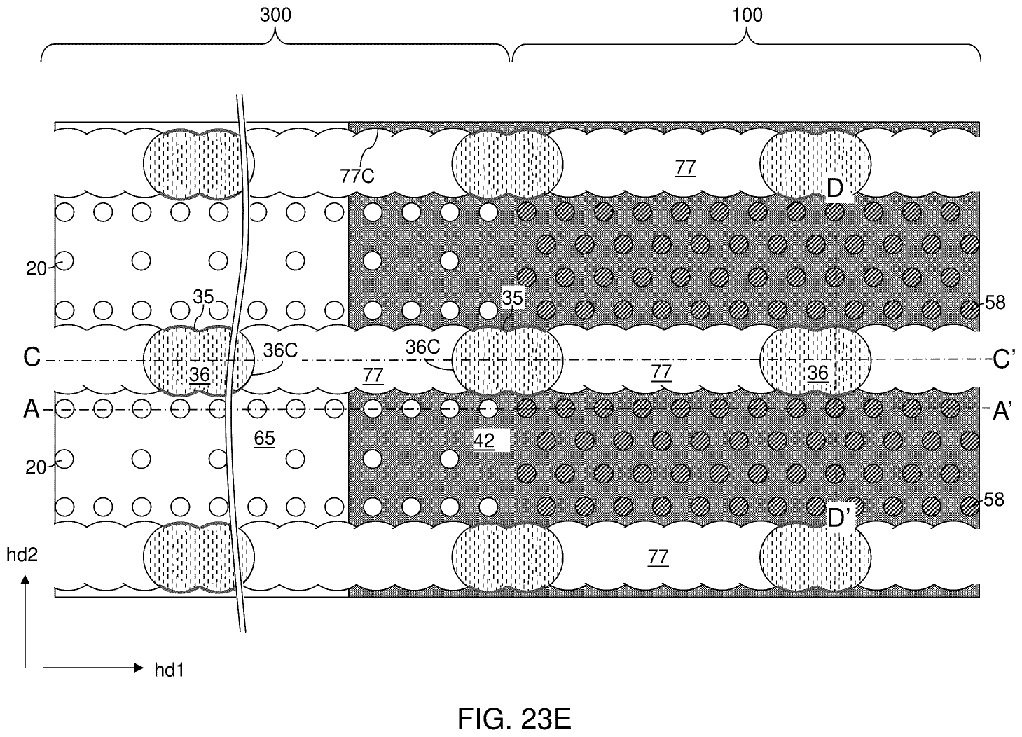

Referring to FIGS. 23A-23E, at least one isotropic etch process can be performed to isotropically laterally expand the second access via cavities 75. For example, an etchant (e.g., dilute hydrofluoric acid) that etches the material of the insulating layers 32 and the sacrificial material layers 42 selective to the patterned third etch mask layer 263 is introduced into the second access via cavities 75. The insulating layers 32 and the sacrificial material layers 42 are etched around each of the second access via cavities 75. The duration of the isotropic etch process can be selected such that the laterally expanded cavities generated from each row of M second access via cavities 75 that merge with each other. Alternatively, separate isotropic etch processes (e.g., dilute hydrofluoric acid and phosphoric acid etch processes) may be used to isotropically etch the insulating layers 32 and the sacrificial material layers 42, respectively. M is an integer representing the total number of second access via cavities 75 located between a neighboring pair of sacrificial pillar structures 36 that are laterally spaced apart from each other along the first horizontal direction hd1. The number M may be in a range from 2 to 128, such as from 4 to 64, and/or from 4 to 32.

Generally, the duration of the at least one isotropic etch process can be selected such that each neighboring set of M second access via cavities 75 merge to form a respective continuous cavity that laterally extends and borders a respective pair of sacrificial pillar structures 36, as shown in FIG. 23E. Each such merged cavity is herein referred to as an in-process access trench 77. Each in-process access trench 77 vertically extends through the contact-level dielectric layer 80 and the alternating stack (32, 42). The at least one isotropic etch process may remove portions of the dielectric liner 35 that are exposed to the in-process access cavities 77. Thus, convex sidewall surface segments of the sacrificial pillar structures 36 may be physically exposed to the in-process access cavities 77. Each in-process access trench 77 may be laterally bounded by a pair of horizontally-convex surface segments (i.e., sidewall surface segments) 36C of a pair of sacrificial pillar structures 36, as shown in FIG. 23E. In one embodiment, each in-process access trench 77 may have a respective horizontal cross-sectional shape having a lateral undulation in width along the second horizontal direction hd2. In one embodiment, the duration of each of isotropic etch process that is employed to form the in-process access trenches 77 can be selected such that the in-process access trenches 77 do not contact any of the memory opening fill structures 58. In one embodiment, the in-process access trenches 77 may be formed in rows that are arranged along the first horizontal direction hd1, and laterally spaced apart along the second horizontal direction hd2. In one embodiment, a two dimensional array of in-process access trenches 77 may be provided. In one embodiment, the two-dimensional array of in-process access trenches 77 may be a periodic two-dimensional array having the first periodicity along the first horizontal direction hd1 and having the second periodicity along the second horizontal direction hd2.

Generally, portions of the alternating stack (32, 42) located between neighboring pairs of the sacrificial pillar structures 36 can be removed by isotropically recessing portions of the alternating stack (32, 42) from around the second access via cavities 75, which include volumes from which the sacrificial access opening fill structures (139, 239) are removed. In-process access trenches 77 are formed by lateral expansion and merging of the second access via cavies 75. In one embodiment, each of the in-process access trenches 77 laterally extends along the first horizontal direction hd1 with a width modulation along the second horizontal direction hd2.

The alternating stack (32, 42) can be divided into a plurality of alternating stacks (32, 42) of respective insulating layers 32 and respective sacrificial material layers 42 that are laterally spaced apart from each other along the second horizontal direction hd2. The contact-level dielectric layer 80 can be divided into a plurality of contact layers 80 that are laterally spaced apart along the second horizontal direction hd2. The third etch mask layer 263 can be subsequently removed selective to the materials of the alternating stacks (32, 42) and the contact-level dielectric layers 80, for example, by performing an isotropic etch process. For example, a wet etch process employing TMY or TMAH may be performed to remove the third etch mask layer 263.

In one embodiment shown in FIG. 23E, each of the in-process access trenches 77 comprises a respective pair of contoured lengthwise sidewalls that generally extend along the first horizontal direction hd1 and have lateral undulations along the second horizontal direction hd2 in a plan view that is perpendicular to top surfaces of the contact-level dielectric layers 80. In one embodiment, each of the contoured lengthwise sidewalls of the in-process access trenches 77 comprises a respective plurality of vertically-straight and horizontally-convex surface segments 77C that are adjoined to each other r at vertically-extending edges. The plurality of vertically-straight and horizontally-convex surface segments 77C include sidewall surface segments of each layer within a respective alternating stack (32, 42), as shown in FIG. 23E.

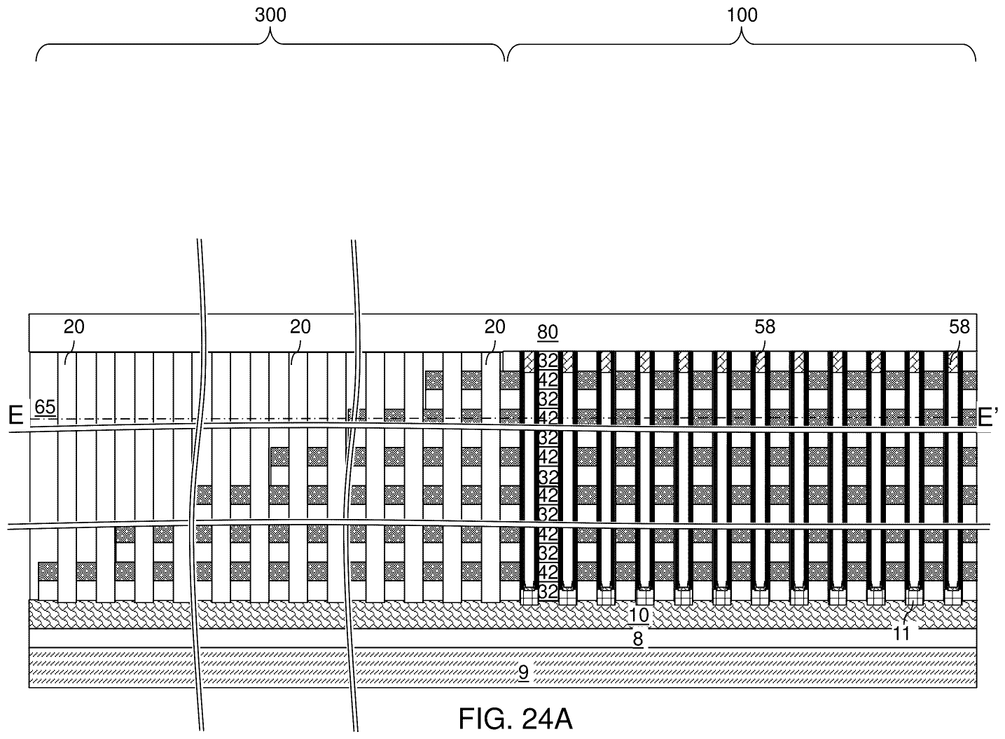

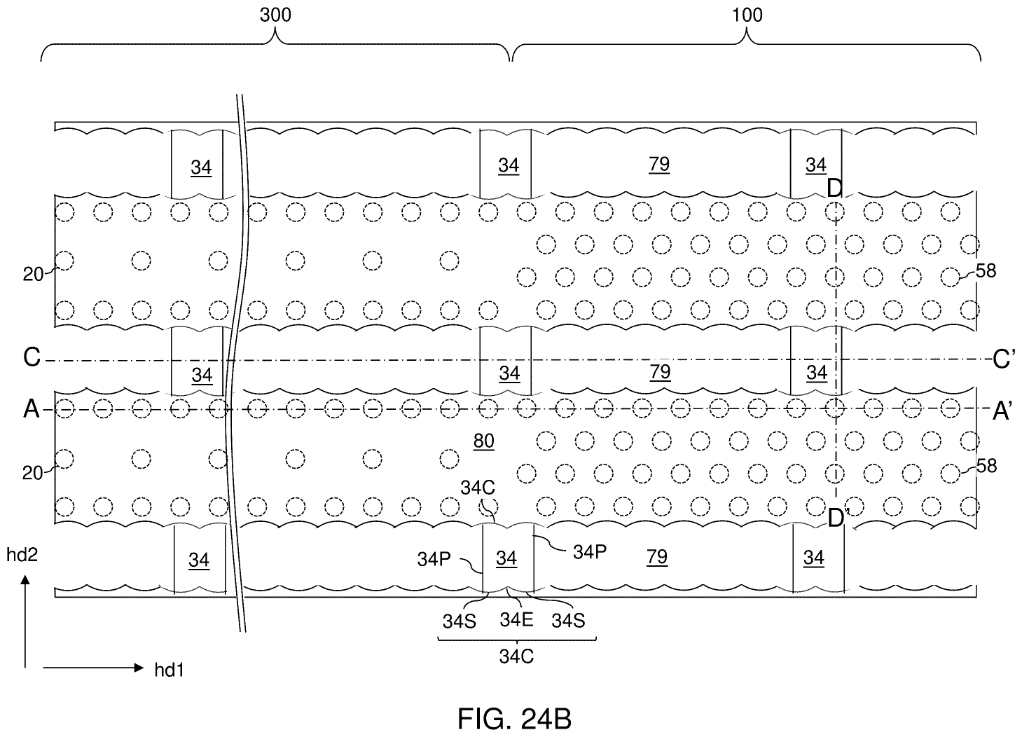

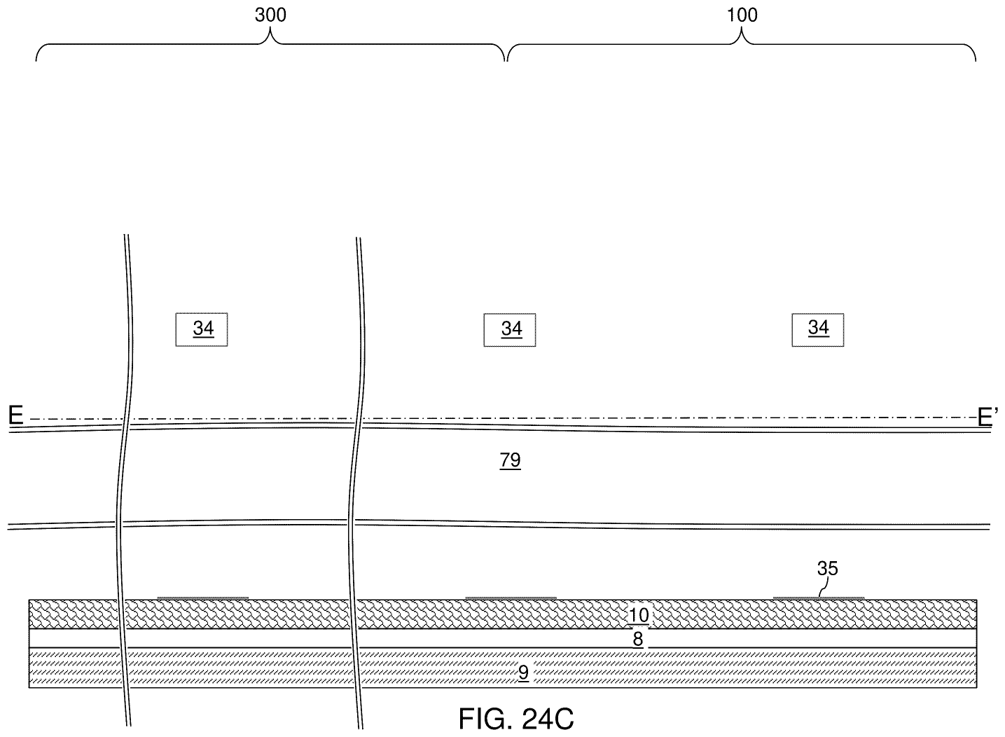

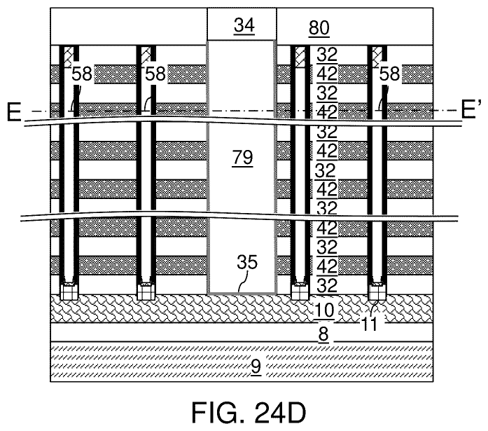

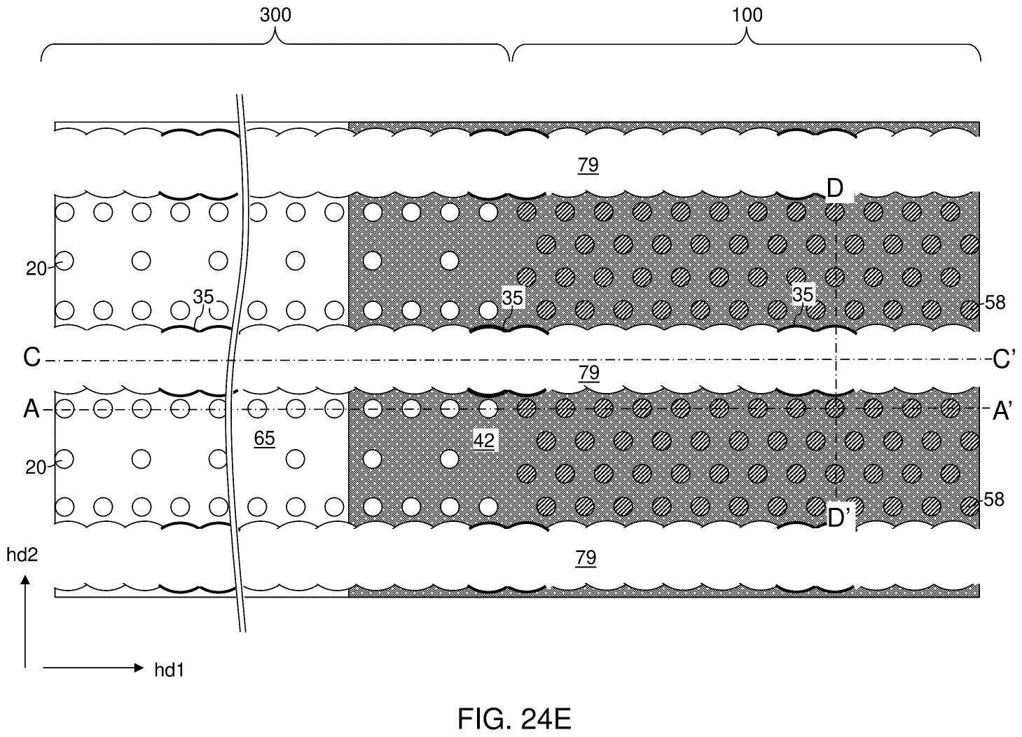

Referring to FIGS. 24A-24E, the sacrificial pillar structures 36 can be subsequently removed selective to the materials of the dielectric bridge structures 34, the alternating stacks (32, 42), the contact-level dielectric layer 80, and the semiconductor material layer 10. For example, if the sacrificial pillar structures 36 comprise a carbon-based material, such as amorphous carbon or diamond-like carbon (DLC), then an ashing process can be performed to remove the sacrificial pillar structures 36. Multiple in-process access cavities 77 located within a same row can be interconnected with each other upon removal of the sacrificial pillar structures 36. Each set of interconnected in-process access cavities 77 which now include volumes from which a row of sacrificial pillar structures 36 is removed constitutes an access trench 79, as shown in FIGS. 24B, 24C and 24E.

Generally, the access trenches 79 can be formed by removing portions of the alternating stack (32, 42) located between neighboring pairs of the sacrificial pillar structures 36 that are laterally spaced apart from each other along the first horizontal direction hd1, followed by removing the sacrificial pillar structures 36. In one embodiment, the sacrificial pillar structures 36 can be removed after formation of the in-process access trenches 77 by removing the sacrificial pillar structures 36 selective to materials of the alternating stacks (32, 42) and selective to a material of the dielectric bridge structures 34. Upon removal of the sacrificial pillar structures 36, multiple in-process access trenches 77 arranged along the first horizontal direction hd1 are interconnected to form the access trenches 79.

In one embodiment, each of the access trenches 79 laterally extends along the first horizontal direction hd1 with a width modulation along the second horizontal direction hd2. Dielectric bridge structures 34 can be located within a respective one of the access trenches 79. In one embodiment shown in FIG. 24B, each of the dielectric bridge structures 34 comprises a respective pair of contoured sidewalls 34C, and each contoured sidewall 34C of the dielectric bridge structures 34 comprises at least two vertically-straight and horizontally-convex surface segments 34S that are adjoined by a vertically-extending edge 34E. In one embodiment, each of the access trenches 79 underlies a respective row of dielectric bridge structures 34 that is a respective subset of the dielectric bridge structures 34.

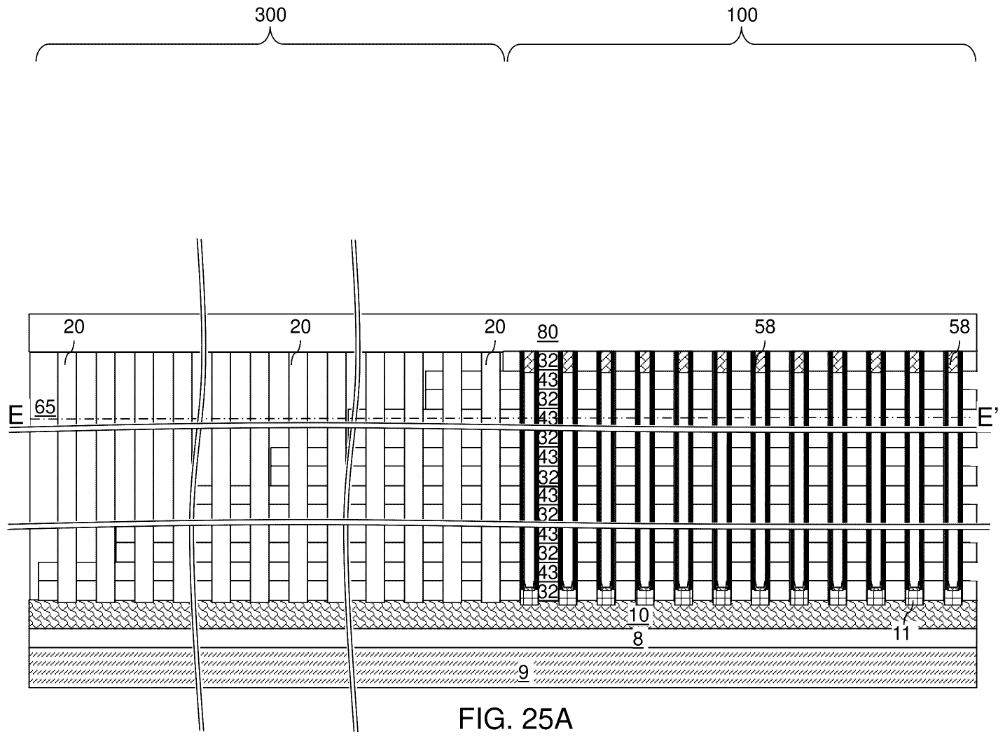

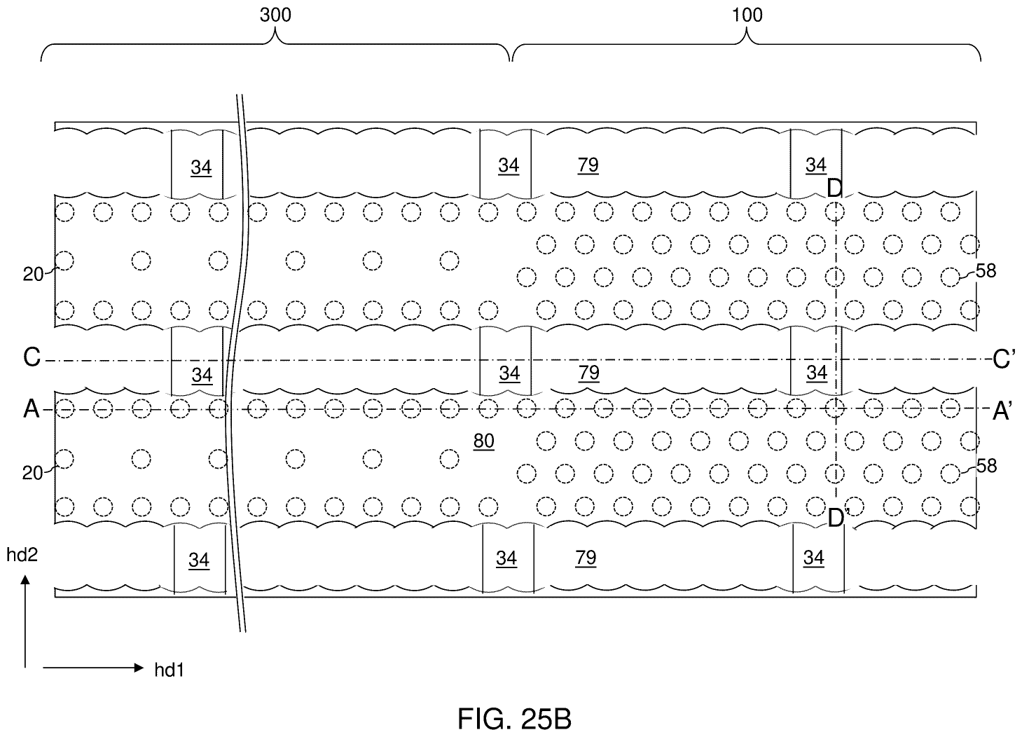

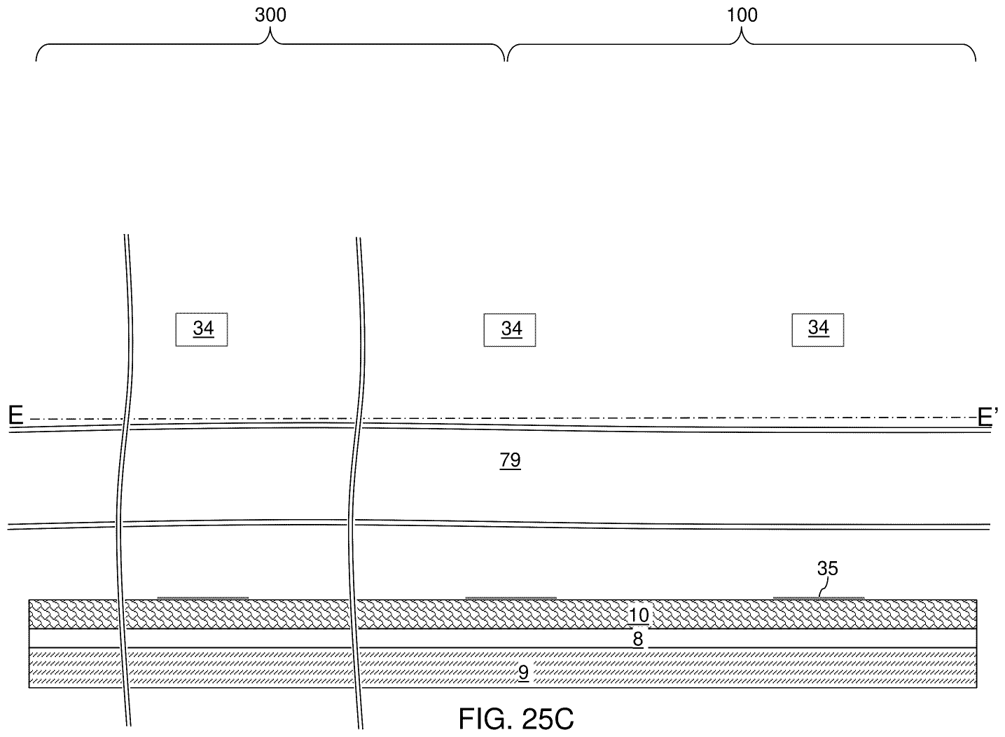

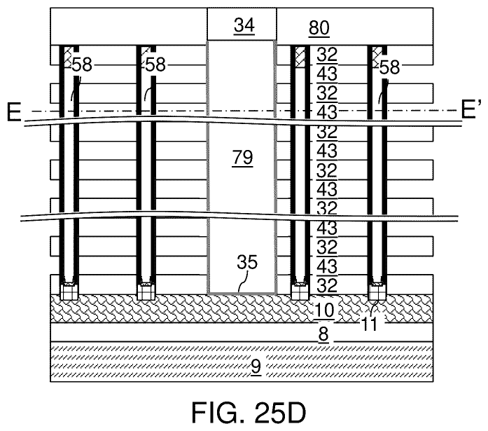

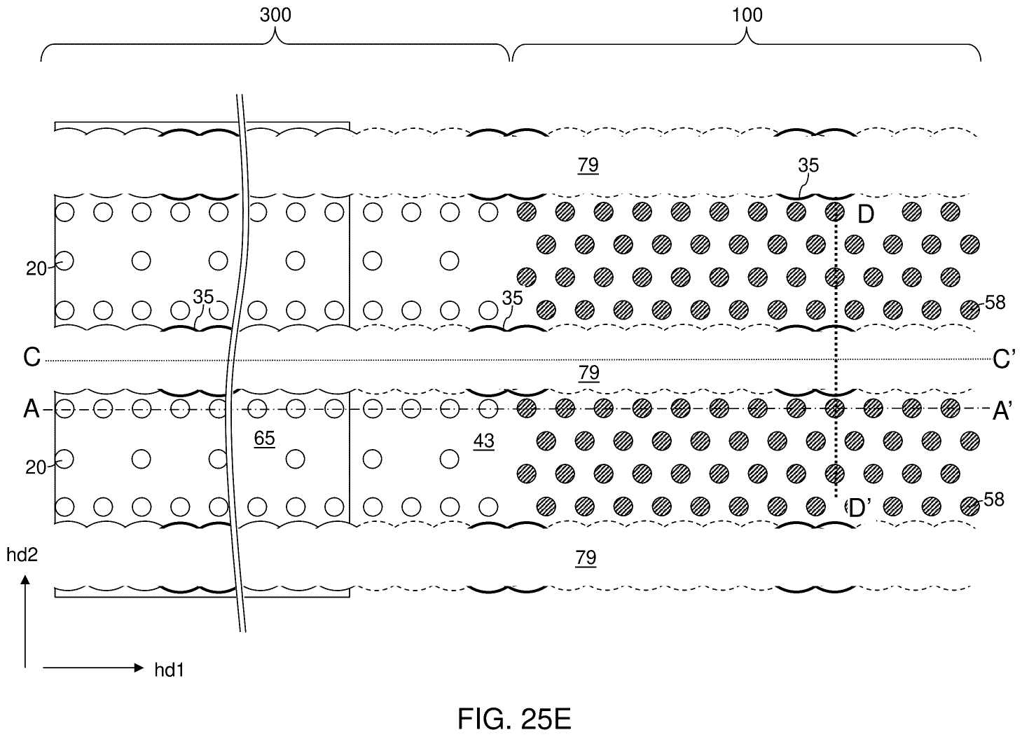

Referring to FIGS. 25A-25E, an etchant that selectively etches the material of the sacrificial material layers 42 with respect to the material of the insulating layers 32 can be introduced into the access trenches 79, for example, employing an isotropic etch process. Lateral recesses 43 are formed in volumes from which the sacrificial material layers 42 are removed. The removal of the sacrificial material layers 42 can be selective to the materials of the insulating layers 32, the stepped dielectric material portion 65, the semiconductor material of the semiconductor material layer 10, and the material of the outermost layer of the memory films 50. In one embodiment, the sacrificial material layers 42 can include silicon nitride, and the materials of the insulating layers 32 and the stepped dielectric material portion 65 can be selected from silicon oxide and dielectric metal oxides.

The etch process that removes the second material selective to the first material and the outermost layer of the memory films 50 can be a wet etch process employing a wet etch solution, or can be a gas phase (dry) etch process in which the etchant is introduced in a vapor phase into the access trenches 79. For example, if the sacrificial material layers 42 include silicon nitride, the etch process can be a wet etch process in which the exemplary structure is immersed within a wet etch tank including phosphoric acid, which etches silicon nitride selective to silicon oxide, silicon, and various other materials employed in the art. The support pillar structure 20, the stepped dielectric material portion 65, and the memory stack structures 55 provide structural support while the lateral recesses 43 are present within volumes previously occupied by the sacrificial material layers 42.

Each lateral recess 43 can be a laterally extending cavity having a lateral dimension that is greater than the vertical extent of the cavity. In other words, the lateral dimension of each lateral recess 43 can be greater than the height of the lateral recess 43. A plurality of lateral recesses 43 can be formed in the volumes from which the second material of the sacrificial material layers 42 is removed. The memory openings in which the memory stack structures 55 are formed are herein referred to as front side openings or front side cavities in contrast with the lateral recesses 43.

Each of the plurality of lateral recesses 43 can extend substantially parallel to the top surface of the semiconductor material layer 10. A lateral recess 43 can be vertically bounded by a top surface of an underlying insulating layer 32 and a bottom surface of an overlying insulating layer 32. In one embodiment, each lateral recess 43 can have a uniform height throughout.

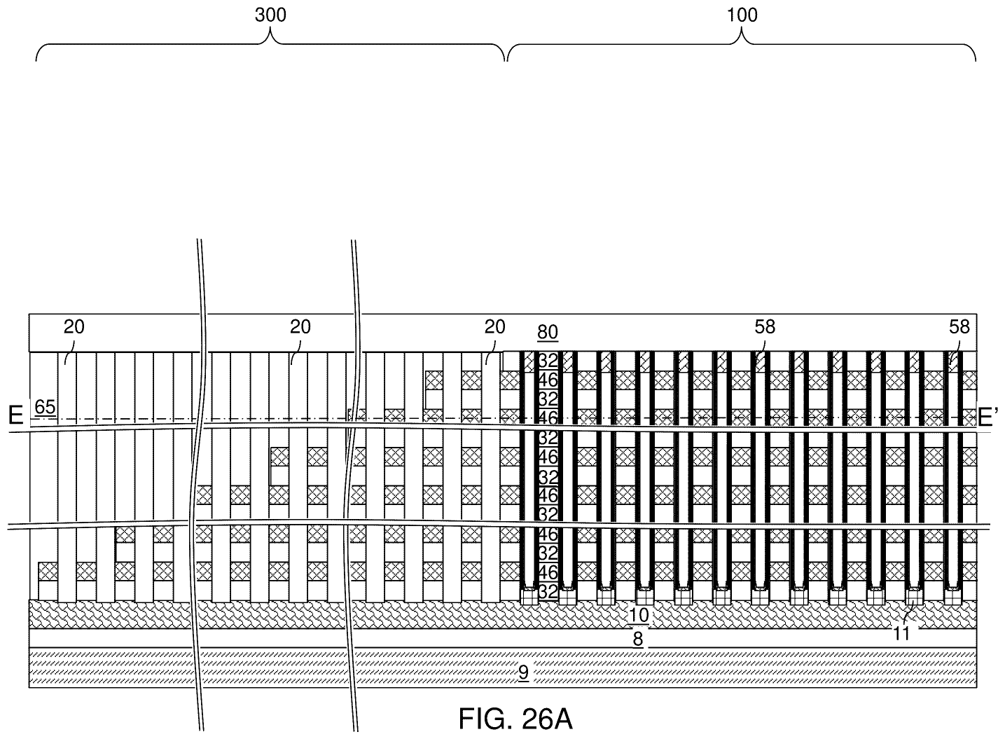

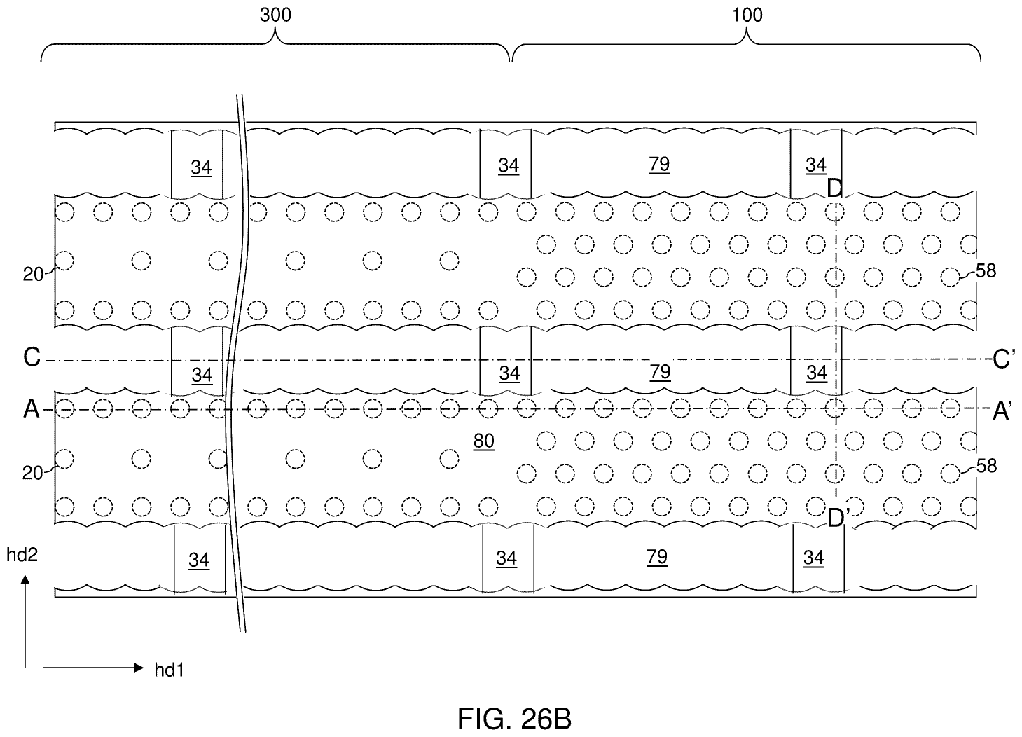

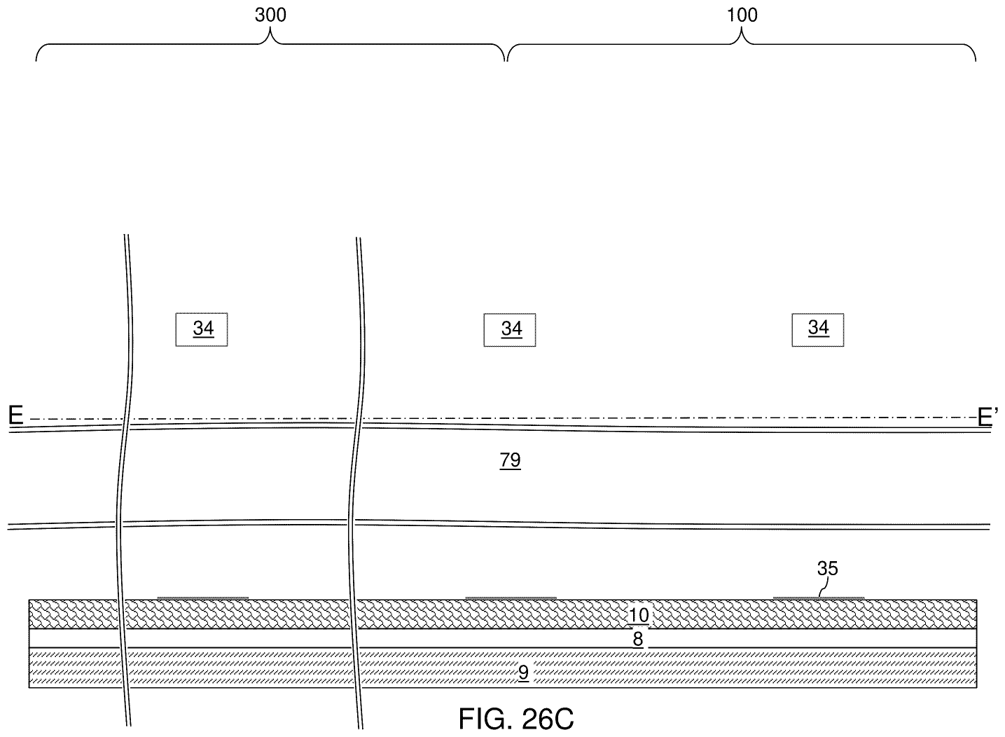

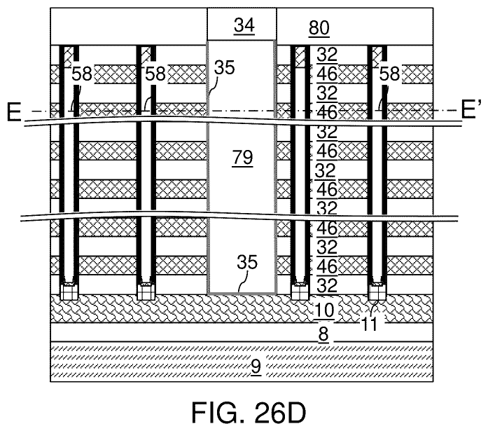

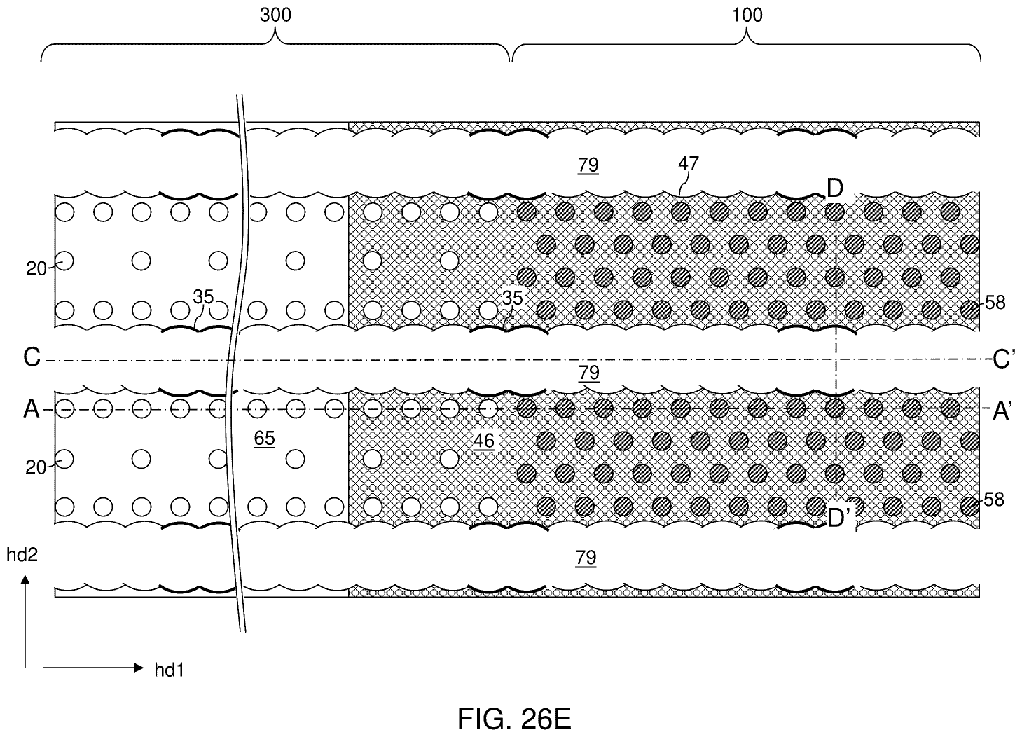

Referring to FIGS. 26A-26E, an outer blocking dielectric layer (not shown) can be optionally formed. The outer blocking dielectric layer, if present, comprises a dielectric material that functions as a control gate dielectric for the control gates to be subsequently formed in the lateral recesses 43. In case the blocking dielectric layer 52 is present within each memory opening, the outer blocking dielectric layer is optional. In case the blocking dielectric layer 52 is omitted, the outer blocking dielectric layer is present.

At least one conductive material can be deposited in the lateral recesses 43 by providing at least one reactant gas into the lateral recesses 43 through the access trenches 79. A metallic barrier layer can be deposited in the lateral recesses 43. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of lateral recesses 43, on the sidewalls of the at least one the access trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of lateral recesses 43, and a continuous metallic material layer can be formed on the sidewalls of each access trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the access trenches 79 or above the contact-level dielectric layer 80.

The deposited metallic material of the continuous electrically conductive material layer is etched back from the sidewalls of each access trench 79 and from above the contact-level dielectric layer 80 by performing an isotropic etch process that etches the at least one conductive material of the continuous electrically conductive material layer. Each remaining portion of the deposited metallic material in the lateral recesses 43 constitutes an electrically conductive layer 46. Each electrically conductive layer 46 can be a conductive line structure. Thus, the sacrificial material layers 42 are replaced with the electrically conductive layers 46.

Each electrically conductive layer 46 can function as a combination of a plurality of control gate electrodes located at a same level and a word line electrically interconnecting, i.e., electrically shorting, the plurality of control gate electrodes located at the same level. The plurality of control gate electrodes within each electrically conductive layer 46 are the control gate electrodes for the vertical memory devices including the memory stack structures 55. In other words, each electrically conductive layer 46 can be a word line that functions as a common control gate electrode for the plurality of vertical memory devices. At least one topmost and at least one bottommost electrically conductive layers 46 function as drain side and source side select gate electrodes for each vertical NAND string.

Generally, remaining portions of the sacrificial material layers 42 can be replaced with electrically conductive layers 46. Layer stacks (32, 46, 80) are formed, which laterally extend along the first horizontal direction hd1 and are laterally spaced apart from each other by the access trenches 79 along the second horizontal direction hd2. Each of the layer stacks (32, 42, 80) comprises a respective alternating stack (32, 46) of respective insulating layers 32 and respective electrically conductive layers 46, and further comprises a respective contact-level dielectric layer 80 that overlies the respective alternating stack (32, 46).

In one embodiment, each of the alternating stacks (32, 46) comprises a respective pair of lengthwise sidewalls in which a plurality of vertically-straight and laterally-concave surface segments 47 are adjoined to each other along the first horizontal direction hd1, as shown in FIG. 26E. Remaining portions of the dielectric liners 35 may be located on a first subset of the vertically-straight and laterally-concave surface segments 47 that were in previous contact with 4 the sacrificial pillar structures 36, as shown in FIG. 26E. The remaining second subset of the vertically-straight and laterally-concave surface segments 47 is exposed to the access trenches 79.

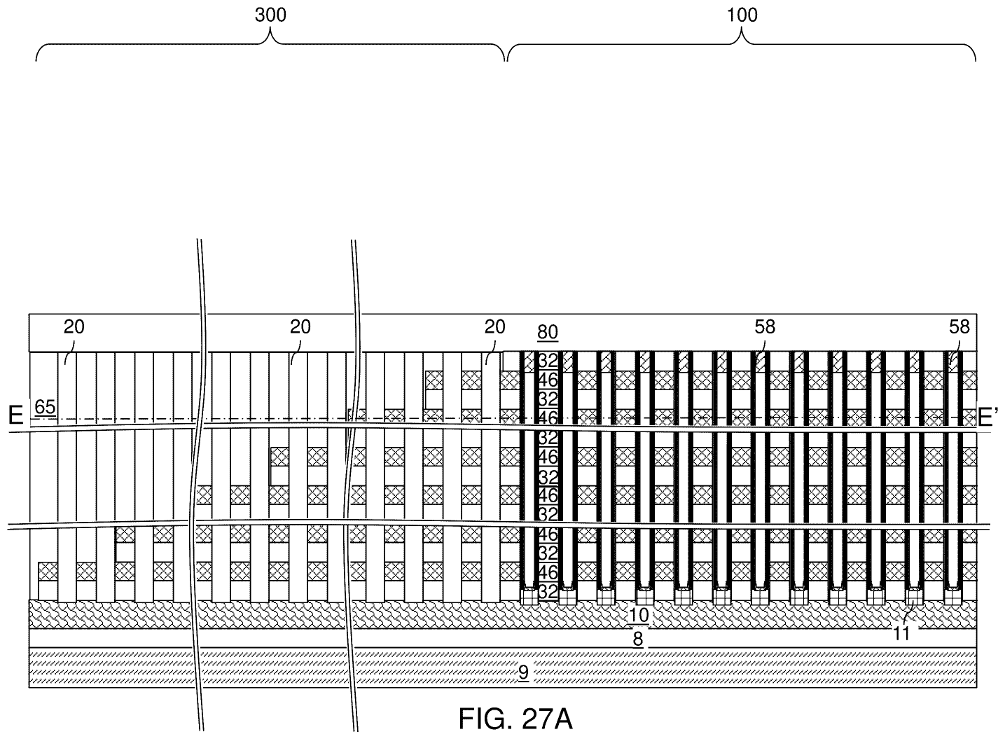

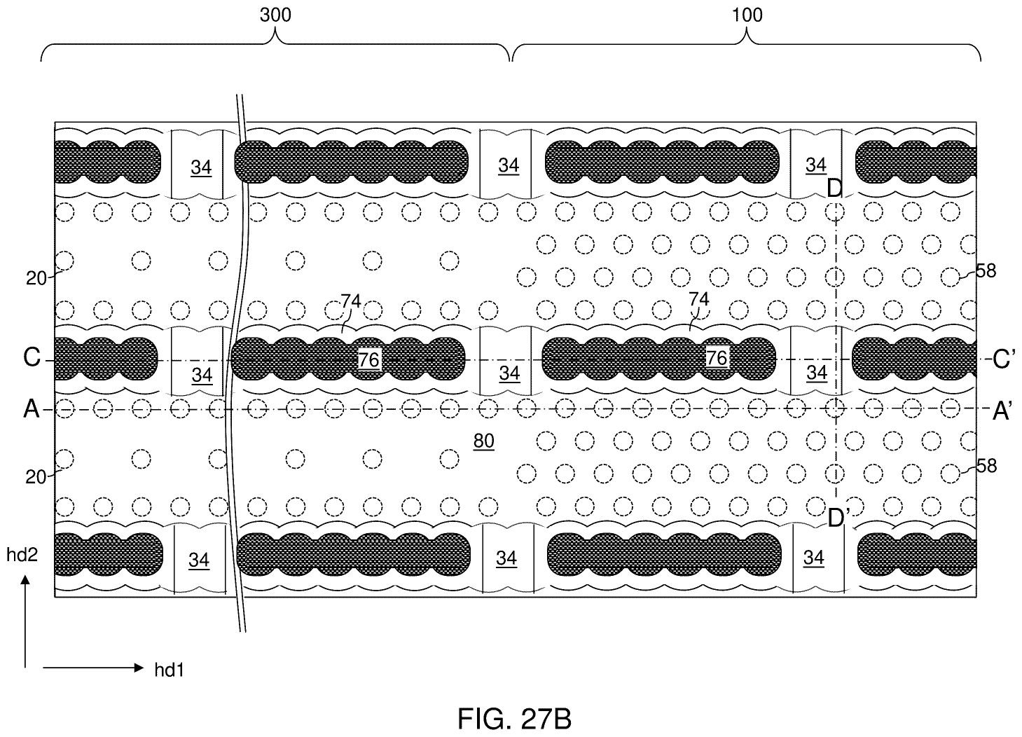

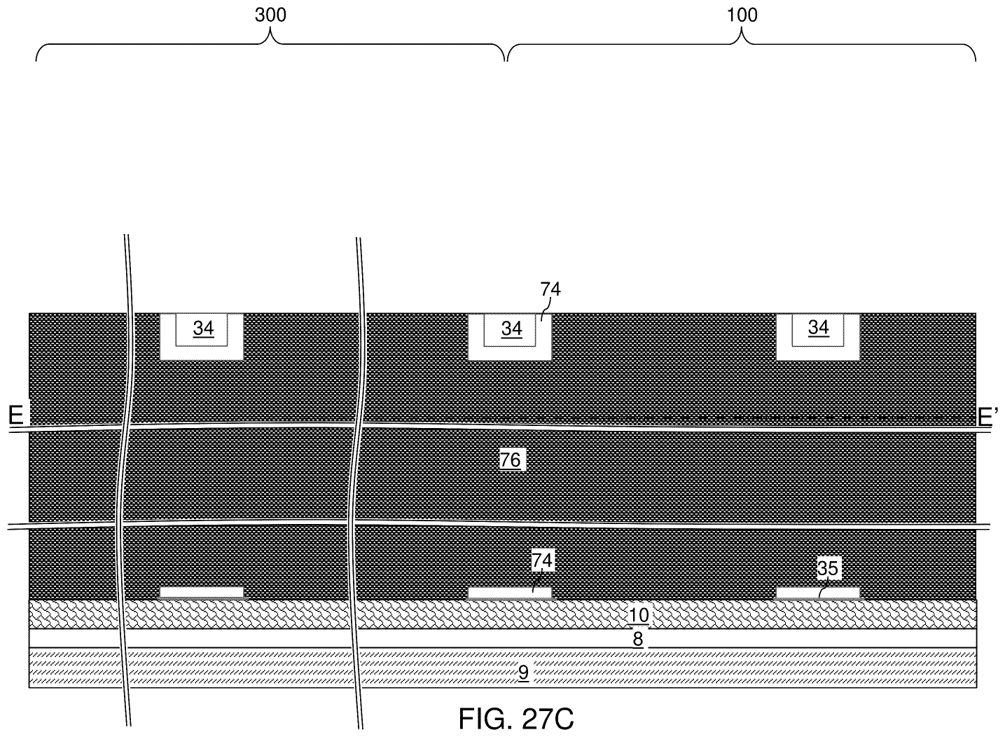

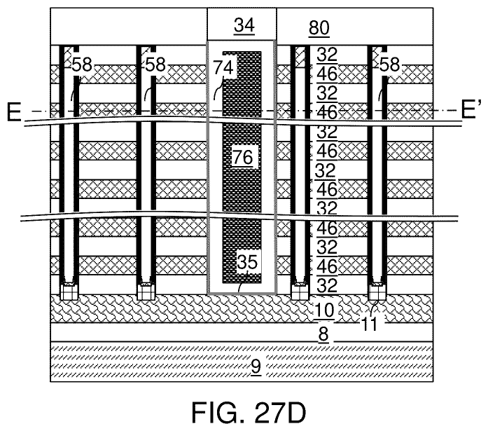

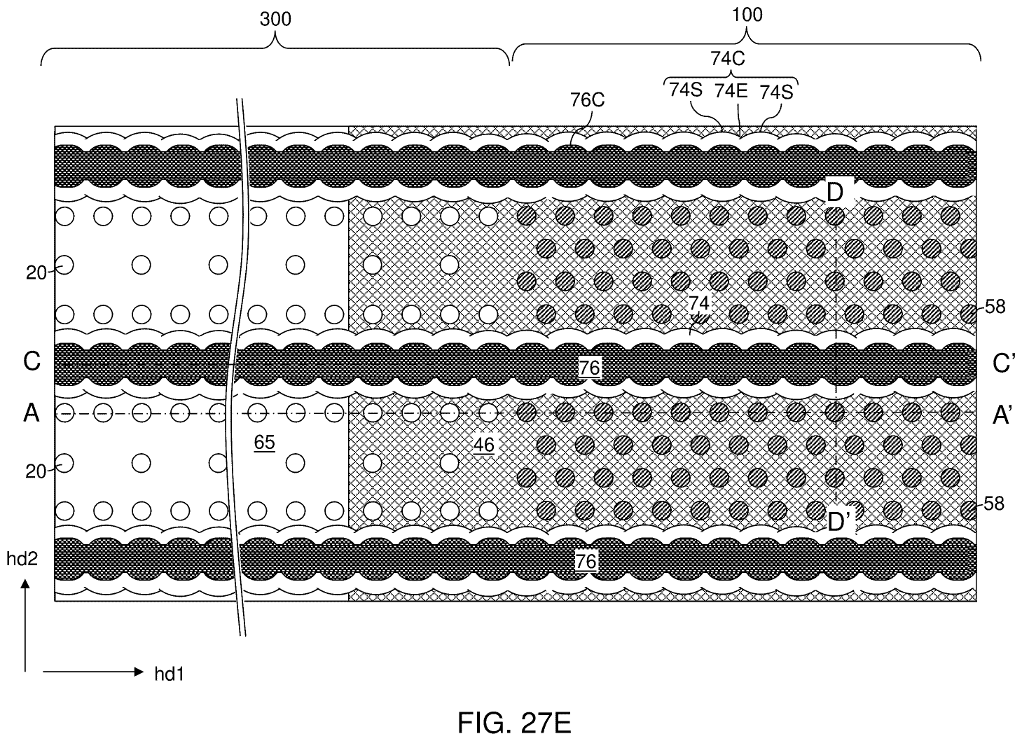

Referring to FIGS. 27A-27E, access trench fill structures (74, 76) can be formed in the access trenches 79 by filling the access trenches 79 with at least one trench fill material. For example, an insulating material such as silicon oxide can be conformally deposited in the access trenches 79 and over the contact-level dielectric layer 80 and the dielectric bridge structures 34. An anisotropic etch process can be performed to remove uncovered horizontally-extending portions of the insulating material. Each remaining portion of the deposited insulating material in the access trenches 79 constitute an insulating spacer 74. At least one conductive material, such at least one metallic material, can optionally be deposited in remaining volumes of the access trenches 79 and over the contact-level dielectric layer 80 and the dielectric bridge structures 34. An anisotropic etch process can be performed to remove uncovered horizontally-extending portions of the at least one conductive material. Each remaining portion of the at least one conductive material constitutes an access-trench contact via structure 76.

In one embodiment, each of the access trench fill structures (74, 76) comprises: a respective insulating spacer 74 in contact with a respective pair of the layer stacks (32, 46, 80), and in contact with a respective row of the dielectric bridge structures 34; and a respective access-trench contact via structure 76 that is laterally surrounded by the respective insulating spacer 74. In one embodiment shown in FIG. 27E, the respective access-trench contact via structure 76 comprises a respective pair of contoured lengthwise sidewalls 76C that generally extend along the first horizontal direction hd1 and have lateral undulations along the second horizontal direction hd2 in a plan view that is perpendicular to top surfaces of the contact-level dielectric layers 80. In one embodiment, each of the contoured lengthwise sidewalls 76S of the access trench fill structures (74, 76) comprises a respective plurality of vertically-straight and horizontally-convex dielectric surface segments 74S that are adjoined to each other at vertically-extending edges 74E and contacting each layer of the respective alternating stack (32, 46). Thus, the access trench fill structures comprise a respective pair of contoured lengthwise sidewalls 74C that generally extend along the first horizontal direction hd1 and have lateral undulations along the second horizontal direction hd2 in a plan view that is perpendicular to top surfaces of the contact-level dielectric layers 80.

In one embodiment, each of the dielectric bridge structures 34 is in direct contact with a pair of sidewalls of a respective one of the access trench fill structures (74, 76) that laterally extends along the second horizontal direction hd2. Each access trench fill structure (74. 76) can be located in a respective access trench 79, and can embed a respective row of the dielectric bridge structures 34.

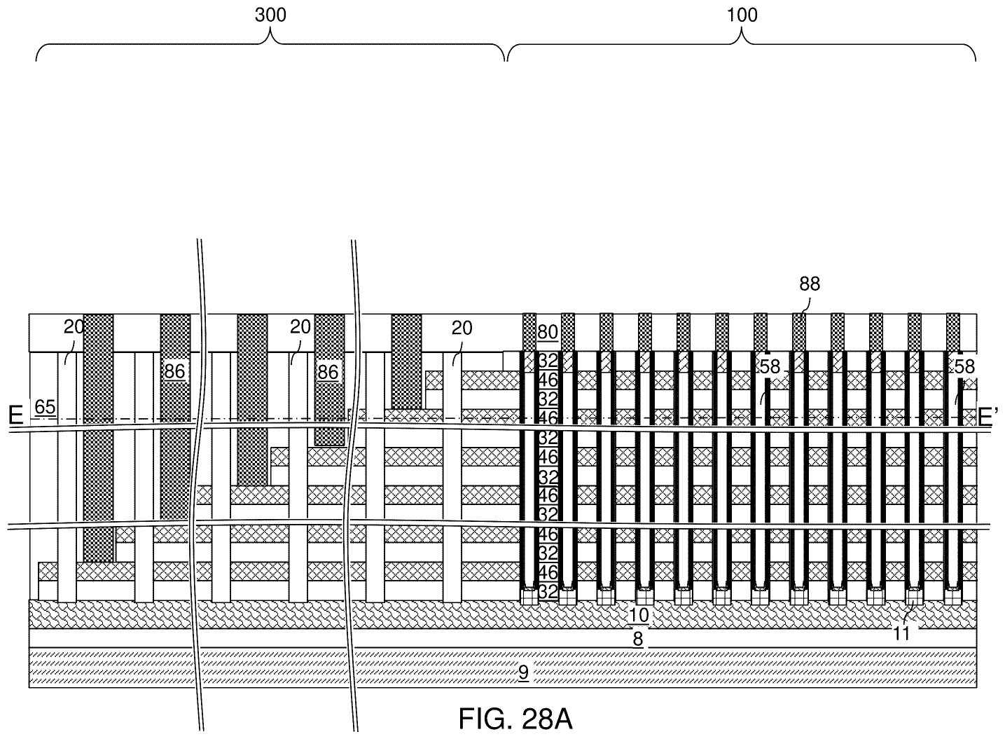

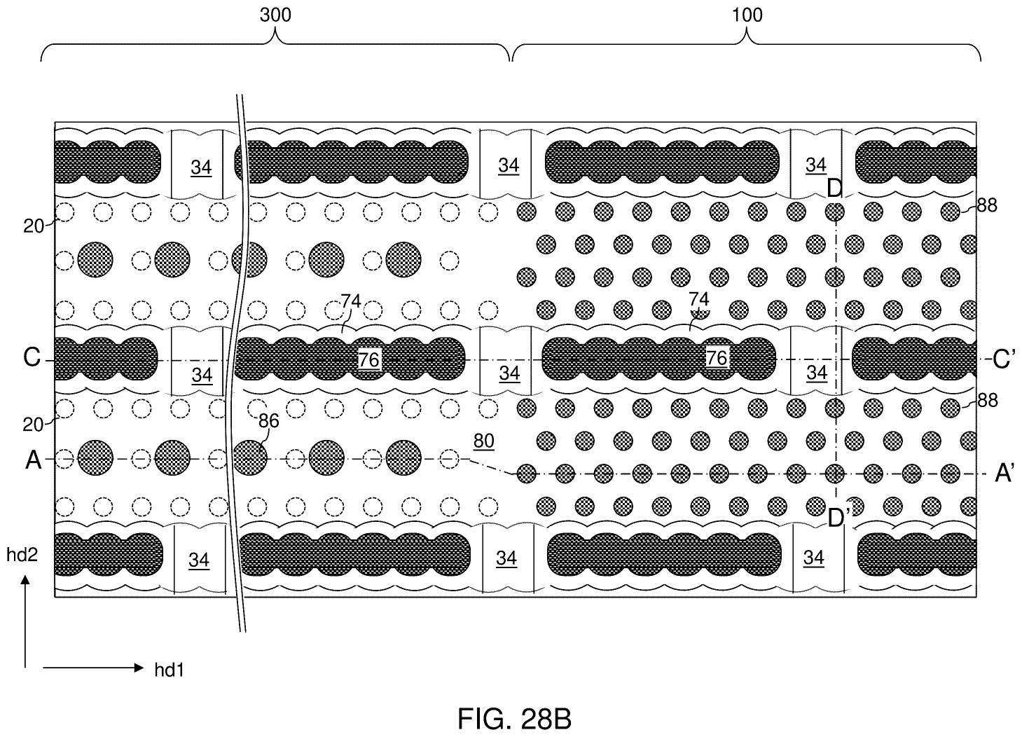

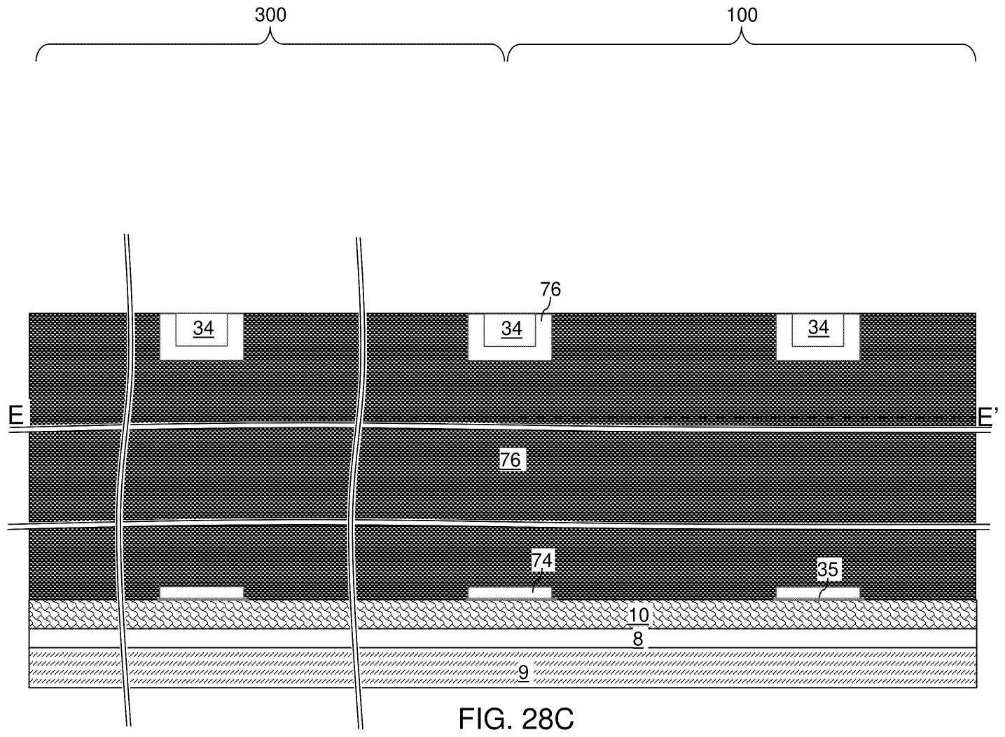

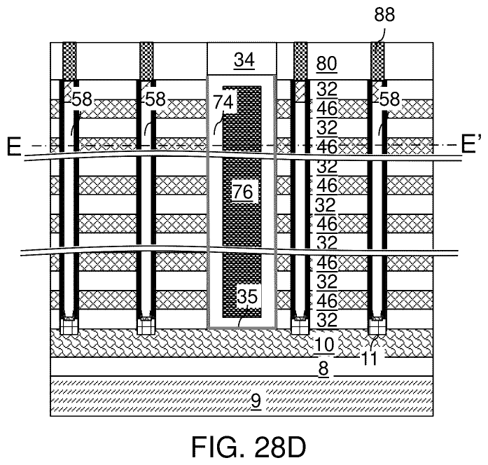

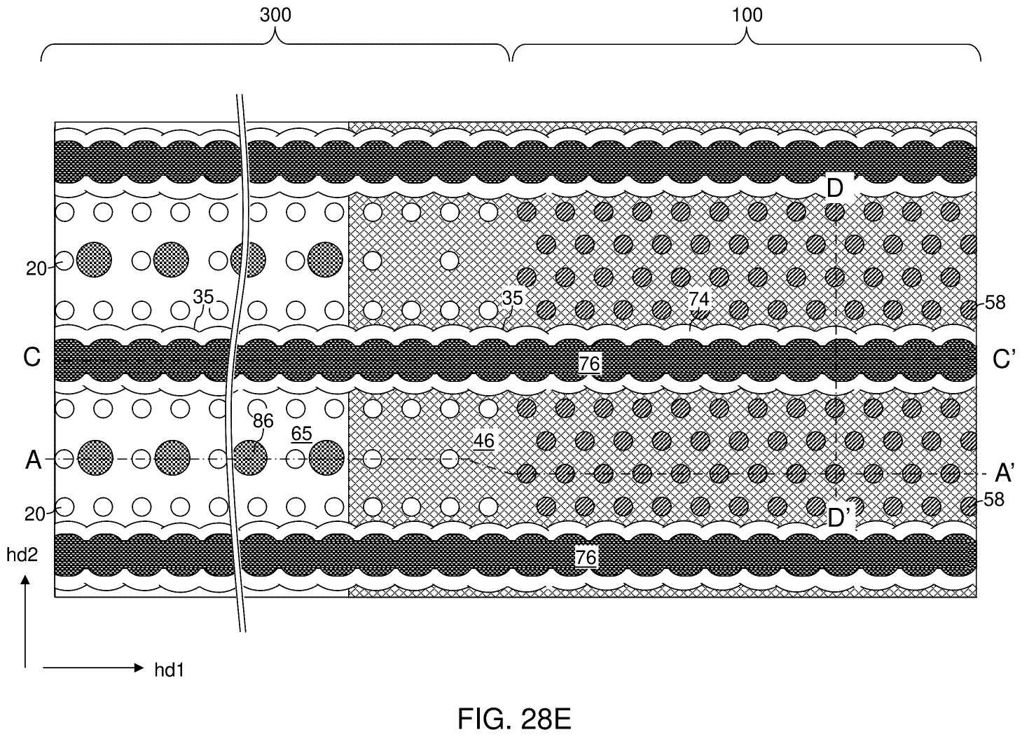

Referring to FIGS. 28A-28E, contact via structures (88, 86) can be formed through the contact-level dielectric layer 80, and optionally through the stepped dielectric material portion 65. For example, drain contact via structures 88 can be formed through the contact-level dielectric layer 80 on each drain region 63. Layer contact via structures 86 can be formed on the electrically conductive layers 46 through the contact-level dielectric layer 80, and through the stepped dielectric material portion 65.

Referring to all drawings and according to various embodiments of the present disclosure, a memory device is provided, which comprises: layer stacks (32, 46, 80) that laterally extend along a first horizontal direction hd1 and laterally spaced apart from each other by access trenches 79, wherein each of the layer stacks comprises a respective alternating stack (32, 46) of respective insulating layers 32 and respective electrically conductive layers 46, and further comprises a respective contact-level dielectric layer 80 that overlies the respective alternating stack (32, 46); memory openings 49 vertically extending through a respective one of the alternating stacks (32, 46); memory opening fill structures 58 located in a respective one of the memory openings 49 and comprising a respective vertical stack of memory elements and a respective vertical semiconductor channel 60; dielectric bridge structures 34 located within a respective one of the access trenches 79, wherein each of the dielectric bridge structures 34 comprises a respective pair of contoured sidewalls 34C, wherein each contoured sidewall 34C of the dielectric bridge structures 34 comprises at least two vertically-straight and horizontally-convex surface segments 34S that are adjoined by a vertically-extending edge 34E; and access trench fill structures (74, 76) located in the access trenches 79 and embedding a respective subset of the dielectric bridge structures 34.

In one embodiment, each of the dielectric bridge structures 34 comprises a respective pair of planar vertical sidewalls 34P that are adjoined to the respective pair of contoured sidewalls 34C and are parallel to the second horizontal direction hd2. In one embodiment, the vertical sidewalls of the dielectric bridge structures 34 are in contact with a respective one of the access trench fill structures (74, 76).

In one embodiment, each of the dielectric bridge structures 34 comprises a respective horizontal bottom surface located at or above a horizontal plane including top surfaces of the alternating stacks (32, 46).

In one embodiment, each of the dielectric bridge structures 34 comprises a respective top surface located within a horizontal plane including top surfaces of the contact-level dielectric layers 80.

In one embodiment, each of the access trench fill structures (74, 76) comprises a respective pair of contoured lengthwise sidewalls 74C that generally extend along the first horizontal direction hd1 and have lateral undulations along the second horizontal direction hd2 in a plan view that is perpendicular to top surfaces of the contact-level dielectric layers 80. In one embodiment, each of the contoured lengthwise sidewalls 74C of the access trench fill structures (74, 76) comprises a respective plurality of vertically-straight and horizontally-convex dielectric surface segments 74S that are adjoined to each other at vertically-extending edges 74E and contacting each layer within a respective alternating stack (32, 46).

In one embodiment, each of the dielectric bridge structures 34 is in direct contact with a pair of sidewalls of a respective one of the access trench fill structures (74, 76).

In one embodiment, each of the access trench fill structures (74, 76) comprises: a respective insulating spacer 74 in contact with a respective pair of the layer stacks, and in contact with a respective row of the dielectric bridge structures 34; and a respective access-trench contact via structure 76 that is laterally surrounded by the respective insulating spacer 74. In one embodiment, the respective access-trench contact via structure 76 comprises a respective pair of contoured lengthwise sidewalls 76C that generally extend along the first horizontal direction hd1 and have lateral undulations along the second horizontal direction hd2 in a plan view that is perpendicular to top surfaces of the contact-level dielectric layers 80.

In one embodiment, each of the access trenches 79 laterally extends along the first horizontal direction hd1 with a width modulation along the second horizontal direction hd2.

In one embodiment, each of the alternating stacks (32, 46) comprises a respective pair of lengthwise sidewalls in which a plurality of vertically-straight and laterally-concave surface segments 47 are adjoined to each other along the first horizontal direction hd1.

The various embodiments of the present disclosure can be employed to form a three-dimensional memory device in which neighboring alternating stacks are laterally supported by dielectric bridge strictures 34 prior to, during and after formation of access trenches 79. The dielectric bridge structures 34 also provide lateral structural support prior to formation of the access trenches 79, for example, during formation of the in-process access trenches 77. Therefore, the dielectric bridge structures 34 are present prior to formation of the access trenches 79, and no continuous, laterally unsupported trenches are present between adjacent layer stacks. Thus, a memory device may be manufactured with enhanced structural support and decreased layer stack tilting into the trenches.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A memory device, comprising:
layer stacks that laterally extend along a first horizontal direction and laterally spaced apart from each other by access trenches, wherein each of the layer stacks comprises a respective alternating stack of respective insulating layers and respective electrically conductive layers, and further comprises a respective contact-level dielectric layer that overlies the respective alternating stack;
memory openings vertically extending through a respective one of the alternating stacks;
memory opening fill structures located in a respective one of the memory openings and comprising a respective vertical stack of memory elements and a respective vertical semiconductor channel;
dielectric bridges structures located within a respective one of the access trenches, wherein each of the dielectric bridge structures comprises a respective pair of contoured sidewalls, wherein each contoured sidewall of the dielectric bridge structures comprises at least two vertically-straight and horizontally-convex surface segments that are adjoined by a vertically-extending edge; and
access trench fill structures located in the access trenches and embedding a respective subset of the dielectric bridge structures.

2. The memory device of claim 1, wherein each of the dielectric bridge structures comprises a respective pair of planar vertical sidewalls that are adjoined to the respective pair of contoured sidewalls and are parallel to the second horizontal direction.

3. The memory device of claim 2, wherein the vertical sidewalls of the dielectric bridge structures are in contact with a respective one of the access trench fill structures.

4. The memory device of claim 1, wherein each of the dielectric bridge structures comprises a respective horizontal bottom surface located at or above a horizontal plane including top surfaces of the alternating stacks.

5. The memory device of claim 1, wherein each of the dielectric bridge structures comprises a respective top surface located within a horizontal plane including top surfaces of the contact-level dielectric layers.

6. The memory device of claim 1, wherein each of the access trench fill structures comprises a respective pair of contoured lengthwise sidewalls that generally extend along the first horizontal direction and have lateral undulations along the second horizontal direction in a plan view that is perpendicular to top surfaces of the contact-level dielectric layers.

7. The memory device of claim 6, wherein each of the contoured lengthwise sidewalls of the access trench fill structures comprises a respective plurality of vertically-straight and horizontally-convex dielectric surface segments that are adjoined to each other at vertically-extending edges and contacting each layer within a respective alternating stack.

8. The memory device of claim 1, wherein each of the dielectric bridge structures is in direct contact with a pair of sidewalls of a respective one of the access trench fill structures.

9. The memory device of claim 1, wherein each of the access trench fill structures comprises:
a respective insulating spacer in contact with a respective pair of the layer stacks, and in contact with a respective row of the dielectric bridge structures; and
a respective access-trench contact via structure that is laterally surrounded by the respective insulating spacer.

10. The memory device of claim 9, wherein the respective contact via structure comprises a respective pair of contoured lengthwise sidewalls that generally extend along the first horizontal direction and have lateral undulations along the second horizontal direction in a plan view that is perpendicular to top surfaces of the contact-level dielectric layers.

11. The memory device of claim 1, wherein each of the access trenches laterally extends along the first horizontal direction with a width modulation along the second horizontal direction.

12. The memory device of claim 1, wherein each of the alternating stacks comprises a respective pair of lengthwise sidewalls in which a plurality of vertically-straight and laterally-concave surface segments are adjoined to each other along the first horizontal direction.

13. A method of forming a semiconductor structure, comprising:
forming an alternating stack of insulating layers and sacrificial material layers over a substrate;
forming memory openings through the alternating stack;
forming memory opening fill structures in the memory openings;
forming a contact-level dielectric layer over the alternating stack and the memory opening fill structures;
forming pillar cavities vertically extending through the contact-level dielectric layer and the alternating stack;
forming sacrificial pillar structures in the pillar cavities;
forming dielectric bridge structures in upper portions of the sacrificial pillar structures;
forming access trenches by removing portions of the alternating stack located between neighboring pairs of the sacrificial pillar structures that are laterally spaced apart from each other along a first horizontal direction and by removing the sacrificial pillar structures;
replacing remaining portions of the sacrificial material layers with electrically conductive layers; and
forming access trench fill structures in the access trenches.

14. The method of claim 13, further comprising:
forming access via cavities vertically extending through the contact-level dielectric layer and the alternating stack; and
laterally expanding and merging the access via cavities form the pillar cavities.

15. The method of claim 14, further comprising:
forming access openings through the alternating stack; and
forming sacrificial access opening fill structures in the access openings, wherein the contact-level dielectric layer is formed over the sacrificial access opening fill structures.

16. The method of claim 15, further comprising:
forming connection via cavities through the contact-level dielectric layer on a top surface of a respective one of the sacrificial access opening fill structures; and
removing the sacrificial access opening fill structures, wherein the access via cavities comprises volumes from which the sacrificial access opening fill structures are removed.

17. The method of claim 13, further comprising:
forming a patterned etch mask layer including slit-shaped openings that laterally extend along a second horizontal direction over the sacrificial pillar structures such that a center portion of each of the sacrificial pillar structures is not covered by the patterned etch mask layer and peripheral portions of each of the sacrificial pillar structures are covered by the patterned etch mask layer; and
forming recess regions by anisotropically etching unmasked portions of the sacrificial pillar structures while the patterned etch mask layer is present, wherein the dielectric bridges structures are formed in the recess regions.

18. The method of claim 13, wherein each of the access trenches underlies a respective row of the dielectric bridge structures.

19. The method of claim 13, further comprising:
forming access openings concurrently with formation of the memory openings;
forming sacrificial access opening fill structures in the access openings; and
forming in-process access trenches by isotropically recessing portions of the alternating stack from around volumes from which the sacrificial access opening fill structures are removed to remove the portions of the alternating stack located between the neighboring pairs of the sacrificial pillar structures are removed.

20. The method of claim 19, wherein:
the sacrificial pillar structures are removed after formation of the in-process access trenches by removing the sacrificial pillar structures selective to materials of the alternating stack and selective to a material of the dielectric bridge structures; and
multiple in-process access trenches arranged along the first horizontal direction are interconnected to form the access trenches upon removal of the sacrificial pillar structures.
